(19) United States
(12) Patent Application Publication
(10) Pub. No.: US 2025/0212598 A1
(43) Pub. Date: Jun. 26, 2025

(54) ORGANIC LIGHT-EMITTING DEVICE, AND DISPLAY APPARATUS, IMAGE PICKUP APPARATUS, LIGHTING APPARATUS, AND MOVING OBJECT INCLUDING THE SAME

(71) Applicant: CANON KABUSHIKI KAISHA, Tokyo (JP)

(72) Inventors: HIROKAZU MIYASHITA, Miyagi (JP); HITOSHI NAGASHIMA, Kanagawa (JP); YOSUKE NISHIDE, Kanagawa (JP); NAOKI YAMADA, Tokyo (JP)

(21) Appl. No.: 19/059,119

(22) Filed: Feb. 20, 2025

Related U.S. Application Data
(63) Continuation of application No. PCT/JP2023/030005, filed on Aug. 21, 2023.

(30) Foreign Application Priority Data
Aug. 23, 2022 (JP) 2022-132554
Jul. 31, 2023 (JP) 2023-124957

(51) Int. Cl. H10K 50/13; G03G 15/04; H04N 23/53; H10K 50/15; H10K 50/16; H10K 59/123; H10K 85/30; H10K 85/40; H10K 85/60; H10K 101/40

(52) U.S. Cl. CPC H10K 50/13; H10K 50/15; H10K 50/16; H10K 85/324; H10K 85/342; H10K 85/346; H10K 85/40; H10K 85/622; H10K 85/623; H10K 85/624; H10K 85/633; H10K 85/636; H10K 85/654; H10K 85/656; H10K 85/6572; H10K 85/6574; H10K 85/6576; H10K 85/658; G03G 15/04054; H04N 23/53; H10K 59/123; H10K 2101/40

(57) ABSTRACT

An organic light-emitting device including, in sequence, an anode, a first light-emitting layer, a second light-emitting layer, and a cathode. The first light-emitting layer and the second light-emitting layer are in contact with each other. The first light-emitting layer contains a first organic compound and a first metal complex. The second light-emitting layer contains a second organic compound, a third organic compound, and a second metal complex. The third organic compound is not a metal complex. The following relationships (a) to (c) satisfy:

$$HOMO ( D 1 ) > HOMO ( H 1 ) \qquad ( a )$$

$$LUMO ( H 2 ) > LUMO ( H 3 ) \qquad ( b )$$

$$HOMO ( D 1 ) - HOMO ( H 1 ) > LUMO ( H 2 ) - LUMO ( H 3 ) . \qquad ( c )$$

### CROSS-REFERENCE TO RELATED APPLICATIONS

This application is a Continuation of International Patent Application No. PCT/JP2023/030005, filed Aug. 21, 2023, which claims the benefit of Japanese Patent Application No. 2022-132554, filed Aug. 23, 2022, and Japanese Patent Application No. 2023-124957, filed Jul. 31, 2023, all of which are hereby incorporated by reference herein in their entirety.

### TECHNICAL FIELD

The present invention relates to an organic light-emitting device, and a display apparatus, an electronic apparatus, an image pickup apparatus, a lighting apparatus, and a moving object that include the organic light-emitting device.

### BACKGROUND ART

An organic electroluminescent device (hereinafter, also referred to as an “organic EL device” or an “organic light-emitting device”) is a device that emits light by energizing an anode, a cathode, and an organic compound layer disposed between these electrodes, the organic compound layer including a light-emitting layer.

In recent years, research and development of full-color displays including organic light-emitting devices has been vigorously pursued. Organic light-emitting devices are known to be broadly classified into fluorescent devices and phosphorescent devices in accordance with the type of compound contained in light-emitting layers, and device designs suitable for each type are required. Here, phosphorescent devices contain metal complexes, as typified by Ir complexes. Among metal complexes, some compounds have excited states associated with transitions from d-orbitals of metal atoms to ligands (metal-to-ligand charge-transfer (MLCT) transitions). Highest occupied molecular orbital (HOMO) levels derived from d-orbitals of metal atoms are formed, and therefore these compounds tend to have high HOMO levels.

Patent Literature 1 discloses an organic light-emitting device in which two light-emitting layers each composed of an exciplex host material and a light-emitting material are stacked. Patent Literature 2 discloses an organic light-emitting device having a light-emitting layer composed of a host material, a light-emitting material, and a metal complex that is an electron-trapping material. Patent Literature 3 discloses an organic light-emitting device in which two light-emitting layers each composed of a host material and a light-emitting material are stacked.

### CITATION LIST

### Patent Literature

PTL 1 Japanese Patent Laid-Open No. 2018-182345
PTL 2 Japanese Patent Laid-Open No. 2011-171269
PTL 3: PCT Japanese Translation Patent Publication No. 2008-509565

However, in each of the organic light-emitting devices described in Patent Literatures 1 to 3, the light-emitting layer is not configured in consideration of the fact that the light-emitting layer having a metal complex described therein is a hole-trapping light-emitting layer, and thus the organic light-emitting device has a localized recombination zone in the light-emitting layer. In such an organic light-emitting device, the adjustment of the carrier balance is insufficient, and thus there is room for improvement in the durability of the organic light-emitting device.

### SUMMARY OF INVENTION

The present invention has been made in view of the above problems, and it is an object of the present invention to provide an organic light-emitting device having excellent durability.

An organic light-emitting device according to the present invention includes, in sequence, an anode, a first light-emitting layer, a second light-emitting layer, and a cathode, in which the first light-emitting layer and the second light-emitting layer are in contact with each other, the first light-emitting layer contains a first organic compound and a first metal complex, the second light-emitting layer contains a second organic compound, a third organic compound, and a second metal complex, the third organic compound is not a metal complex, and the following relationships (a) to (c) satisfy:

$$HOMO ( D 1 ) > HOMO ( H 1 ) \qquad ( a )$$

$$LUMO ( H 2 ) > LUMO ( H 3 ) \qquad ( b )$$

$$HOMO ( D 1 ) - HOMO ( H 1 ) > LUMO ( H 2 ) - LUMO ( H 3 ) . \qquad ( c )$$

HOMO (D1), HOMO (H1), LUMO (H2), and LUMO (H3) represent the HOMO energy level of the first metal complex, the HOMO energy level of the first organic compound, the LUMO energy level of the second organic compound, and the LUMO energy level of the third organic compound, respectively.

Further features of the present invention will become apparent from the following description of exemplary embodiments with reference to the attached drawings.

### BRIEF DESCRIPTION OF DRAWINGS

FIG. 1 is a schematic cross-sectional view illustrating an example of an organic light-emitting device according to an embodiment of the present invention.

FIG. 2 is an energy diagram illustrating schematic energy levels around light-emitting layers included in an organic light-emitting device according to an embodiment of the present invention.

FIG. 3A is a schematic cross-sectional view of an example of a pixel of a display apparatus according to an embodiment of the present invention.

FIG. 3B is a schematic cross-sectional view of an example of a display apparatus including organic light-emitting devices according to an embodiment of the present invention.

FIG. 4 is a schematic view of an example of a display apparatus including an organic light-emitting device according to an embodiment of the present invention.

FIG. 5A is a schematic view of an example of an image pickup apparatus according to an embodiment of the present invention.

FIG. 5B is a schematic view of an example of an electronic apparatus according to an embodiment of the present invention.

FIG. 6A is a schematic view of an example of a display apparatus according to an embodiment of the present invention.

FIG. 6B is a schematic view of an example of a foldable display apparatus.

FIG. 7A is a schematic view illustrating an example of a lighting apparatus according to an embodiment of the present invention.

FIG. 7B is a schematic view of an example of an automobile including an automotive lighting unit according to an embodiment of the present invention.

FIG. 8A is a schematic view of an example of a wearable device according to an embodiment of the present invention.

FIG. 8B is a schematic view of an example of a wearable device according to an embodiment of the present invention, the wearable device including an image pickup apparatus.

FIG. 9A is a schematic view of an example of an image-forming apparatus according to an embodiment of the present invention.

FIG. 9B is a schematic view of an example of an exposure light source of an image-forming apparatus according to an embodiment of the present invention.

FIG. 9C is a schematic view of an example of an exposure light source of an image-forming apparatus according to an embodiment of the present invention.

### DESCRIPTION OF EMBODIMENTS

In this specification, examples of a halogen atom include, but are not limited to, fluorine, chlorine, bromine, and iodine. Among these, a fluorine atom is preferred.

An alkyl group may be an alkyl group having 1 to 20 carbon atoms. Examples thereof include, but are not limited to, a methyl group, an ethyl group, a n-propyl group, an isopropyl group, a n-butyl group, a tert-butyl group, a sec-butyl group, an octyl group, a cyclohexyl group, a 1-adamantyl group, a 2-adamantyl group.

An alkoxy group may be an alkoxy group having 1 to 10 carbon atoms. Examples thereof include, but are not limited to, a methoxy group, an ethoxy group, a propoxy group, a 2-ethyloctyloxy group, and a benzyloxy group.

An aryl group may be an aryl group having 6 to 20 carbon atoms. Examples thereof include, but are not limited to, a phenyl group, a naphthyl group, an indenyl group, a biphenyl group, a terphenyl group, a fluorenyl group, a phenanthryl group, a fluoranthenyl group, and a triphenylenyl group.

A heterocyclic group may be a heterocyclic group having 3 to 20 carbon atoms. Examples thereof include, but are not limited to, a pyridyl group, a pyrimidinyl group, a pyrazinyl group, a triazolyl group, an oxazolyl group, an oxadiazolyl group, a thiazolyl group, a thiadiazolyl group, a carbazolyl group, an acridinyl group, a phenanthrolinyl group, a dibenzofuranyl group, and a dibenzothiophenyl group.

Examples of an amino group include, but are not limited to, an N-methylamino group, an N-ethylamino group, an N, N-dimethylamino group, an N, N-diethylamino group, an N-methyl-N-ethylamino group, an N-benzylamino group, an N-methyl-N-benzylamino group, an N, N-dibenzylamino group, an anilino group, an N, N-diphenylamino group, an N, N-dinaphthylamino group, an N, N-difluorenylamino group, an N-phenyl-N-tolylamino group, an N, N-ditolylamino group, an N-methyl-N-phenylamino group, an N, N-dianisolylamino group, an N-mesityl-N-phenylamino group, an N, N-dimesitylamino group, an N-phenyl-N-(4-tert-butylphenyl)amino group, an N-phenyl-N-(4-trifluoromethylphenyl)amino group, an N-piperidyl group, and a carbazolyl group.

An example of an aryloxy group is, but not limited to, a phenoxy group.

Examples of a silyl group include, but are not limited to, a trimethylsilyl group and a triphenylsilyl group.

Examples of substituents that may be further contained in the alkyl group, the alkoxy group, the aryl group, the heterocyclic group, the amino group, the aryloxy group, and the silyl group include, but are not limited to, a deuterium atom; halogen atoms, such as fluorine, chlorine, bromine, and iodine; alkyl groups, such as a methyl group, an ethyl group, a n-propyl group, an isopropyl group, a n-butyl group, and a tert-butyl group; alkoxy groups, such as a methoxy group, an ethoxy group, and a propoxy group; amino groups, such as a dimethylamino group, a diethylamino group, a dibenzylamino group, a diphenylamino group, and a ditolylamino group; aryloxy groups, such as a phenoxy group; aromatic hydrocarbon groups, such as a phenyl group and a biphenyl group; heteroaryl groups, such as a pyridyl group and a pyrrolyl group; and a cyano group, a hydroxy group, and a thiol group.

HOMO (H1), HOMO (H2), HOMO (H3), HOMO (D1), HOMO (D2), and HOMO (D3) represent the respective highest occupied molecular orbital (HOMO) levels of a first organic compound, a second organic compound, a third organic compound, a first metal complex, a second metal complex, and a third metal complex.

LUMO (H1), LUMO (H2), LUMO (H3), LUMO (D1), LUMO (D2), and LUMO (D3) represent the respective lowest unoccupied molecular orbital (LUMO) levels of the first organic compound, the second organic compound, the third organic compound, the first metal complex, the second metal complex, and the third metal complex.

C1 (H1), C1 (D1), and C1 (D3) represent the respective concentrations of the first organic compound in the first light-emitting layer, the first metal complex in the first light-emitting layer, and the third metal complex in the first light-emitting layer. The concentration is expressed as a ratio by weight.

C2 (H2), C2 (H3), and C2 (D2) represent the respective concentrations of the second organic compound in the second light-emitting layer, the third organic compound in the second light-emitting layer, and the second metal complex in the second light-emitting layer. The concentration is expressed as a ratio by weight.

Carriers refer to positive holes (holes), electrons, or holes and electrons.

The durability of the organic light-emitting device can also be described as the durability of a light-emitting layer, and can be evaluated based on a deterioration in the luminance of emission light.

### (1) Organic Light-Emitting Device

An organic light-emitting device according to the present invention includes, in sequence, an anode, a first light-emitting layer, a second light-emitting layer, and a cathode, in which the first light-emitting layer and the second light-emitting layer are in contact with each other, the first light-emitting layer contains a first organic compound and a first metal complex, the second light-emitting layer contains a second organic compound, a third organic compound, and a second metal complex, the third organic compound is not a metal complex, and the following relationships (a) to (c) satisfies:

$$HOMO ( D 1 ) > HOMO ( H 1 ) \qquad ( a )$$

$$LUMO ( H 2 ) > LUMO ( H 3 ) \qquad ( b )$$

$$HOMO ( D 1 ) - HOMO ( H 1 ) > LUMO ( H 2 ) - LUMO ( H 3 ) . \qquad ( c )$$

The relationship (a) indicates that the HOMO level of the first metal complex contained in the first light-emitting layer is higher (closer to the vacuum level) than the HOMO level of the first organic compound contained in the first light-emitting layer. In other words, the first light-emitting layer is a hole-trapping light-emitting layer.

The relationship (b) indicates that the LUMO level of the second organic compound contained in the second light-emitting layer is lower (further from the vacuum level) than the LUMO level of the third organic compound contained in the second light-emitting layer. In other words, the second light-emitting layer is an electron-trapping light-emitting layer.

The relationship (c) indicates that a difference in HOMO levels between the first organic compound and the first metal complex contained in the first light-emitting layer is larger than a difference in LUMO levels between the second organic compound and the third organic compound contained in the second light-emitting layer. In other words, the hole-trapping property of the first light-emitting layer is greater than the electron-trapping property of the second light-emitting layer.

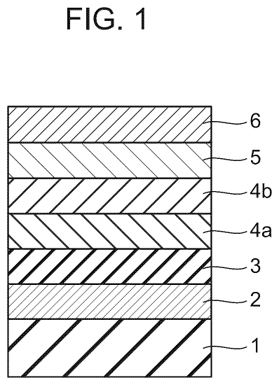

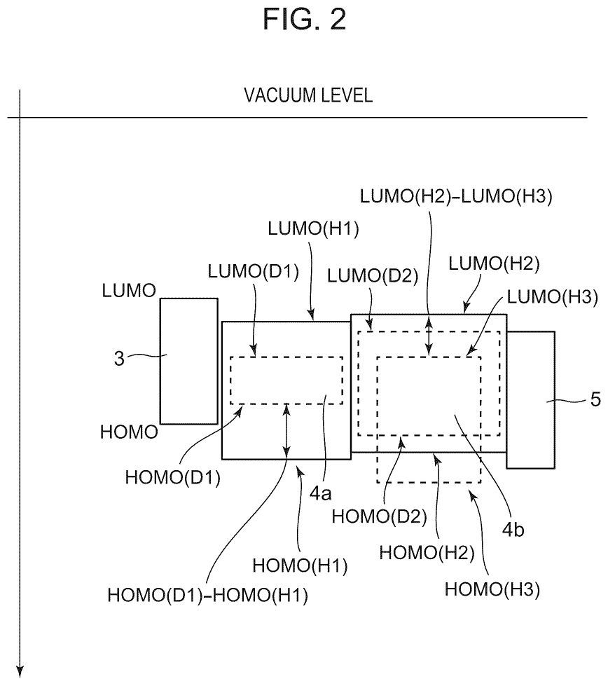

Hereinafter, the organic light-emitting device according to the present invention will be described in more detail with reference to FIGS. 1 and 2.

FIG. 1 is a schematic cross-sectional view of an organic light-emitting device according to the present embodiment. The organic light-emitting device in FIG. 1 includes an anode 2, a hole transport layer 3, a first light-emitting layer 4a, a second light-emitting layer 4b, an electron transport layer 5, and a cathode 6 disposed in this order over an insulating layer 1.

In this specification, a light-emitting layer refers to a layer that emits light among organic compound layers provided between an anode and a cathode. The first light-emitting layer includes the first organic compound and the first metal complex, and the second light-emitting layer includes the second organic compound, the third organic compound, and the second metal complex. The first light-emitting layer may also contain the third metal complex. In the first light-emitting layer, the ratio by weight of the first organic compound may be greater than the ratio by weight of the first metal complex. In the second light-emitting layer, the ratio by weight of the second organic compound may be greater than the ratio by weight of the third organic compound and may be greater than the ratio by weight of the second metal complex.

Among the compounds contained in the light-emitting layer, a compound having the largest ratio by weight may be referred to as a “host material” or “host”. More specifically, the host material is a material whose ratio by weight in the light-emitting layer is more than 50% by weight among the materials contained in the light-emitting layer. In the first light-emitting layer, the host material may be the first organic compound. In the second light-emitting layer, the host material may be the second organic compound.

Among the compounds contained in the light-emitting layer, a compound that contributes to the main emission of light may be referred to as a “guest (dopant) material” or a “guest (dopant)”. More specifically, the guest material is a material whose ratio by weight in the light-emitting layer is less than 50% by weight among the materials contained in the light-emitting layer. The concentration of the guest material in the light-emitting layer is preferably 0.1% or more by weight and 40% or less by weight, more preferably 30% or less by weight in order to inhibit concentration quenching. In the first light-emitting layer, the guest material may be the first metal complex. In the second light-emitting layer, the guest material may be the second metal complex.

Among the compounds contained in the light-emitting layer, a compound that assists the light emission of the guest material may be referred to as an “assist material” or “assist”. More specifically, the assist material is a compound that has a smaller ratio by weight than the host among the compounds constituting the light-emitting layer and that assists the light emission of the guest material. In the first light-emitting layer, the assist material may be the third metal complex. In the second light-emitting layer, the assist material may be the third organic compound.

FIG. 2 is an energy diagram illustrating schematic energy levels around the light-emitting layers included in the organic EL device of the present invention.

As illustrated in FIG. 2, in the present invention, the above relationships (a) to (c) satisfies among the first organic compound, the first metal complex, which are contained in the first light-emitting layer 4a, the second organic compound, the second metal complex, and the third organic compound, which are contained in the second light-emitting layer 4b.

As the HOMO levels and LUMO levels of the first organic compound, the second organic compound, the third organic compound, the first metal complex, the second metal complex, and the third metal complex, actual values may be used, or values determined by molecular orbital calculations may be used. In this specification, the molecular orbital calculations were performed using the density functional theory (DFT), which is now widely used. In the molecular orbital calculations, the B3LYP functional and the 6-31G* basis function were used. More specifically, the molecular orbital calculations were performed by Gaussian09 (Gaussian09, RevisionC.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010). A method for measuring an actual value will be described in the examples described below.

The organic light-emitting device according to the present invention has the following features.
(1-1) Two light-emitting layers are in contact with each other, the light-emitting layer disposed adjacent to the anode is a hole-trapping light-emitting layer, and the light-emitting layer disposed adjacent to the cathode is an electron-trapping light-emitting layer.
(1-2) The hole-trapping property of the first light-emitting layer is greater than the electron-trapping property of the second light-emitting layer.

The features will be described below.
(1-1) Two light-emitting layers are in contact with each other, the light-emitting layer disposed adjacent to the anode is a hole-trapping light-emitting layer, and the light-emitting layer disposed adjacent to the cathode is an electron-trapping light-emitting layer.

The organic light-emitting device according to the present invention has the above-mentioned configuration. Specifically, satisfying the relationships (a) and (b) allows holes injected from the anode to be easily trapped in the first light-emitting layer and allows electrons injected from the cathode to be easily trapped in the second light-emitting layer. Thus, the recombination zone of electrons and holes is less likely to concentrate in the first light-emitting layer, and the deterioration of the materials in the light-emitting layer can be reduced. As a result, the organic light-emitting device according to the present invention is an organic light-emitting device having excellent durability.

The organic light-emitting device according to the present invention has the two light-emitting layers in contact with each other. Each of the light-emitting layers contains the metal complex as a light-emitting material. Metal complexes tend to have high HOMO levels (close to the vacuum level). Thus, light-emitting layers containing metal complexes tend to be hole-trapping light-emitting layers. Thus, when two light-emitting layers of an organic light-emitting device are formed of only hole-trapping light-emitting layers, the recombination zone of electrons and holes is easily localized in the light-emitting layer disposed adjacent to the anode.

The inventors have found that by disposing an electron-trapping light-emitting layer adjacent to the cathode, the recombination zone of electrons and holes is less likely to be localized in a single light-emitting layer. Specifically, the second light-emitting layer disposed adjacent to the cathode contains the third organic compound that exhibits an electron-trapping property. As described above, metal complexes tend to have high HOMO levels (close to the vacuum level) and thus are less likely to exhibit electron-trapping properties. This is because compounds having high HOMO levels also tend to have high LUMO levels. Therefore, the third organic compound is not a metal complex but an organic compound. The LUMO level of the third organic compound is lower (further from the vacuum level) than the LUMO level of the second organic compound contained in the second light-emitting layer. The organic light-emitting device according to the present invention has the above-mentioned configuration and thus is an organic light-emitting device having excellent durability.
(1-2) The hole-trapping property of the first light-emitting layer is greater than the electron-trapping property of the second light-emitting layer.

In the organic light-emitting device according to the present invention, the hole-trapping property of the first light-emitting layer is greater than the electron-trapping property of the second light-emitting layer. Specifically, the organic light-emitting device according to the present invention is an organic light-emitting device that satisfies the relationship (c):
(c) HOMO (D1)−HOMO (H1)>LUMO (H2)−LUMO (H3).

In the organic light-emitting device according to the present invention, the first light-emitting layer has a high hole-trapping property, so that the injection or transport of excess holes into the second light-emitting layer can be inhibited. Thus, the organic light-emitting device of the present invention has excellent durability because the carrier balance in the light-emitting layers is controlled.

In the organic light-emitting devices disclosed in Patent Literatures 1 to 3, organic compounds having carbazole skeletons as host materials for the light-emitting layers located adjacent to the anodes are used. However, since organic compounds having carbazole skeletons have excellent hole-transporting properties, holes are easily injected or transported to the adjacent second light-emitting layer. For this reason, holes are excessively present in the second light-emitting layer to disrupt the carrier balance of the light-emitting layer, which is not preferred from the viewpoint of durability of the organic light-emitting device.

The organic light-emitting device according to the present invention preferably further has the following configurations. Only one of the following configurations may be satisfied, or multiple configurations may be satisfied simultaneously.
(1-3) The first light-emitting layer and the second light-emitting layer further satisfy the following relationship (d):

$$C 2 ( H 3 ) > C 1 ( D 1 ) . \qquad ( d )$$

(1-4) The second light-emitting layer further satisfies the following relationship (e):

$$HOMO ( H 2 ) > HOMO ( H 3 ) . \qquad ( e )$$

(1-5) The second light-emitting layer further satisfies the following relationship (f):

$$LUMO ( D 2 ) > LUMO ( H 3 ) . \qquad ( f )$$

(1-6) The first light-emitting layer further contains the third metal complex, and at least one ligand contained in the third metal complex is identical to a ligand contained in the second metal complex.
(1-7) The first light-emitting layer satisfies the following relationship (h):

$$C 1 ( D 3 ) > C 1 ( D 1 ) . \qquad ( h )$$

(1-8) The first light-emitting layer and the second light-emitting layer further satisfy the following relationships (i) and (j):

$$\vert LUMO ( D 3 ) - LUMO ( D 2 ) \vert \leq 0.2 eV \qquad ( i )$$

$$\vert HOMO ( D 3 ) - HOMO ( D 2 ) \vert \leq 0.2 eV . \qquad ( j )$$

(1-9) The first light-emitting layer and the second light-emitting layer further satisfy the following relationship (k):

$$HOMO ( D 3 ) > HOMO ( H 1 ) . \qquad ( k )$$

(1-10) The emission wavelength of the first metal complex is longer than the emission wavelength of the second metal complex.
(1-11) The thickness of the first light-emitting layer is smaller than the thickness of the second light-emitting layer.
(1-12) The second metal complex and the third metal complex are the same compound.
(1-13) The first organic compound and the second organic compound are the same compound.
(1-14) The first light-emitting layer and the second light-emitting layer further satisfy the following relationship (n):

$$HOMO ( D 1 ) - HOMO ( H 1 ) > LUMO ( H 2 ) - LUMO ( H 3 ) \geq 0.1 eV . \qquad ( n )$$

These configurations will be described below.
(1-3) The first light-emitting layer and the second light-emitting layer further satisfy the following relationship (d):

$$C 2 ( H 3 ) > C 1 ( D 1 ) . \qquad ( d )$$

When the organic light-emitting device according to the present invention further satisfies the relationship (d), it is possible to provide the organic light-emitting device having superior durability.

As described in (1-2), the organic light-emitting device according to the present invention satisfies the relationship (c) and thus has a configuration in which holes can be more easily trapped in the light-emitting layers. The inventors have found that the balance of trapped carriers can be more preferably adjusted by lowering the concentration of the first metal complex, which mainly contributes to the expression of the hole-trapping property, below the concentration of the third organic compound, which mainly contributes to the expression of electron-trapping property. Specifically, the first metal complex and the third organic compound satisfy the relationship (d). With this configuration, the first light-emitting layer and the second light-emitting layer trap holes and electrons in a well-balanced manner, so that the carrier balance in the light-emitting layers is adjusted. As a result, the organic light-emitting device according to the present invention has superior durability.
(1-4) The second light-emitting layer further satisfies the following relationship (e):

$$HOMO ( H 2 ) > HOMO ( H 3 ) . \qquad ( e )$$

As described in (1-1), the first light-emitting layer disposed adjacent to the anode has the hole-trapping property, and the second light-emitting layer disposed adjacent to the cathode has the electron-trapping property. Here, the second light-emitting layer preferably has a low hole-trapping property. Specifically, the second organic compound and the third organic compound preferably satisfy the relationship (e). The reason for this is as follows: When the second light-emitting layer has a high hole-trapping property, the second light-emitting layer has both the electron-trapping property and the hole-trapping property. In this case, the recombination zone of electrons and holes tends to concentrate in the second light-emitting layer, thereby possibly causing the deterioration of the materials of the light-emitting layer. Thus, the HOMO level of the third organic compound is preferably lower (further from the vacuum level) than the HOMO level of the second organic compound. When the above relationship is satisfied, the organic light-emitting device according to the present invention has superior durability.
(1-5) The second light-emitting layer further satisfies the following relationship (f):

$$LUMO ( D 2 ) > LUMO ( H 3 ) . \qquad ( f )$$

As described in (1-1), the second light-emitting layer disposed adjacent to the cathode has the electron-trapping property. Here, the third organic compound preferably has a LUMO level lower (further from the vacuum level) than the second metal complex. Specifically, the second metal complex and the third organic compound preferably satisfy the relationship (f). When the above relationship is satisfied, electron trapping by the second metal complex serving as a light-emitting material is reduced, so that the deterioration of the second metal complex can be reduced. Therefore, when the above relationship is satisfied, the organic light-emitting device according to the present invention has superior durability.

More preferably, the relationship (g) is satisfied:

$$C 2 ( H 3 ) > C 2 ( D 2 ) . \qquad ( g )$$

In the second light-emitting layer, the third organic compound having a lower LUMO level (further from the vacuum level) is contained in a larger amount than the second metal complex, so that electron trapping by the second metal complex can be further reduced. As a result, the organic light-emitting device according to the present invention has superior durability.
(1-6) The first light-emitting layer further contains the third metal complex, and at least one ligand contained in the third metal complex is identical to a ligand contained in the second metal complex.

The organic light-emitting device according to the present invention preferably further contains a material that promotes carrier transfer between the light-emitting layers. Specifically, the first light-emitting layer preferably further contains the third metal complex having the same ligand as the ligand contained in the second metal complex. When the above structure is used, ligands having the same structure can easily approach each other. This reduces the intermolecular distance between the second metal complex and the third metal complex. In the case of the above-described structure, carrier transfer between the first light-emitting layer and the second light-emitting layer is promoted via the second metal complex and the third metal complex, so that the organic light-emitting device according to the present invention has excellent luminous efficiency.

Furthermore, at least one ligand contained in the first metal complex is preferably identical to a ligand in the third metal complex. In this case, the compatibility between the first metal complex and the third metal complex is improved. Thus, the transfer of carriers between the first light-emitting layer and the second light-emitting layer is further promoted. Therefore, the organic light-emitting device according to the present invention has excellent luminous efficiency.

Specific examples of the ligands contained in the first to third metal complexes are illustrated below. However, the present invention is not limited to these. The following examples include examples using a phenylpyridine skeleton, which is a typical skeleton of a bidentate ligand. Ligands having fused-ring structures, monodentate ligands, tridentate ligands, and tetradentate ligands can be used. In each of the following structural formulae, although the two bonds between the ligand and the Ir metal are both represented by dotted lines, one of the dotted lines is a covalent bond, and the other is a coordinate bond.

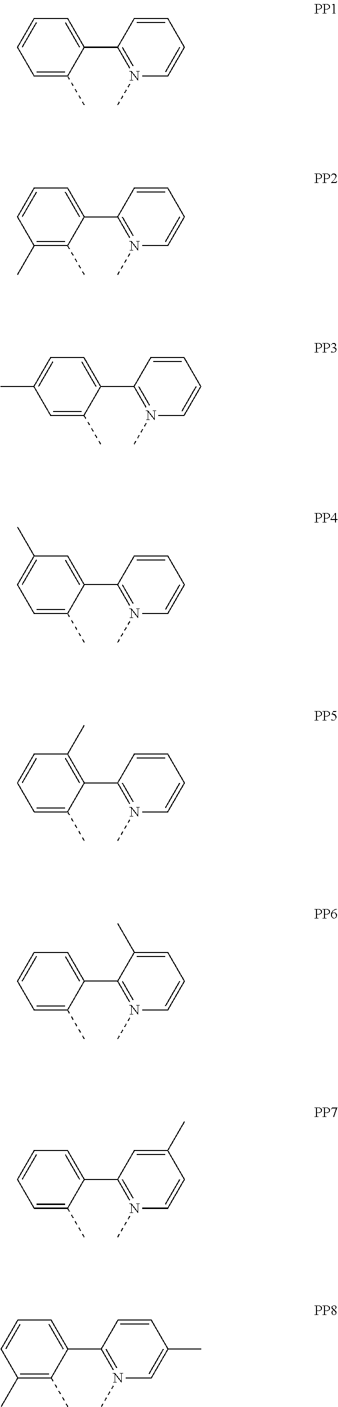

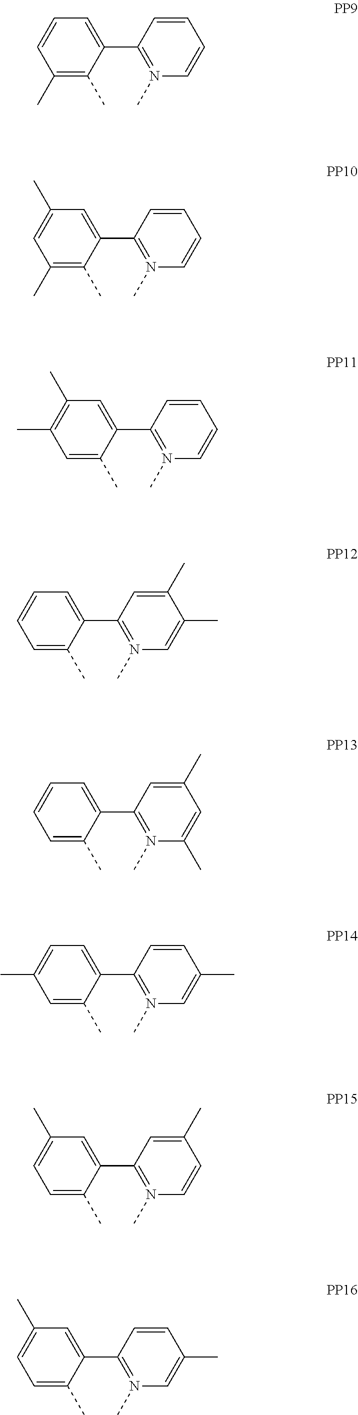

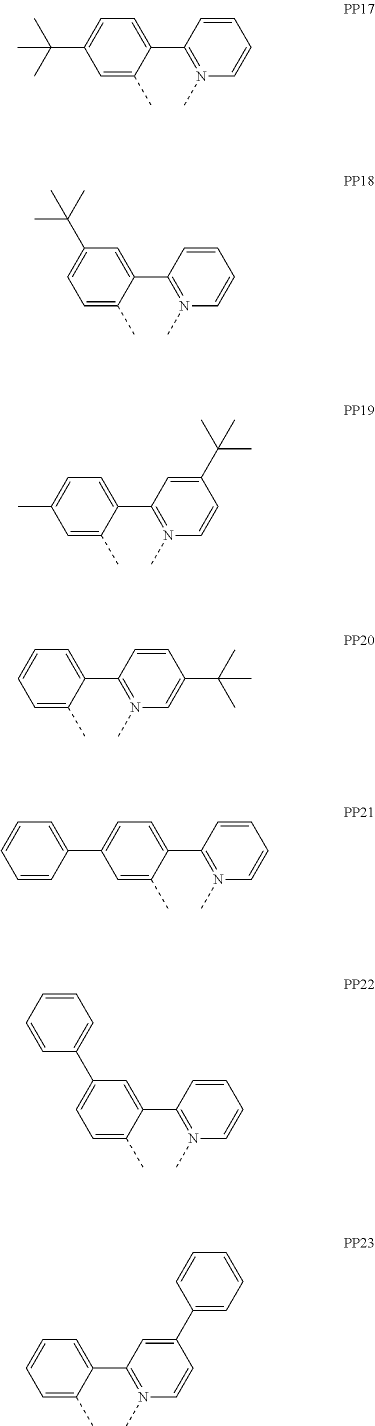

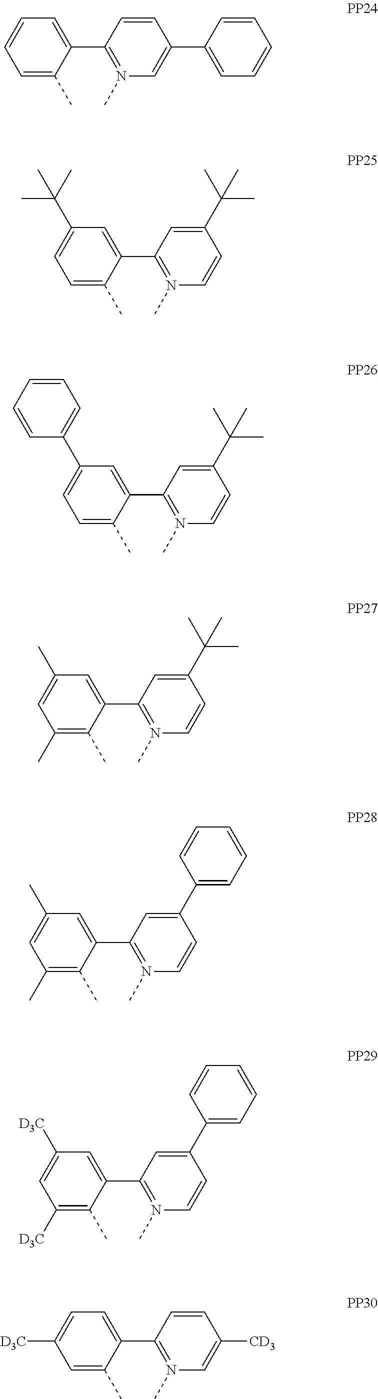

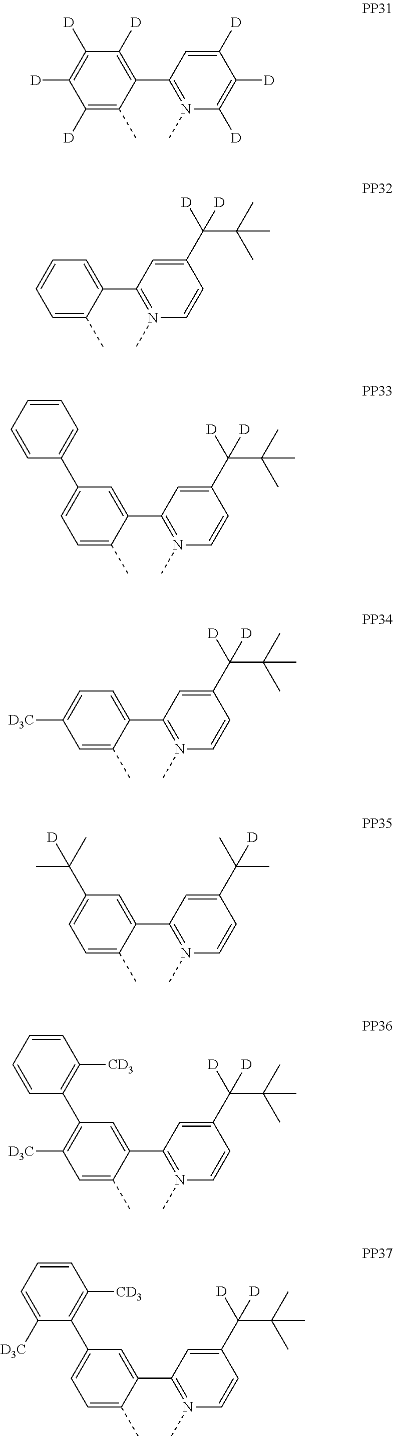

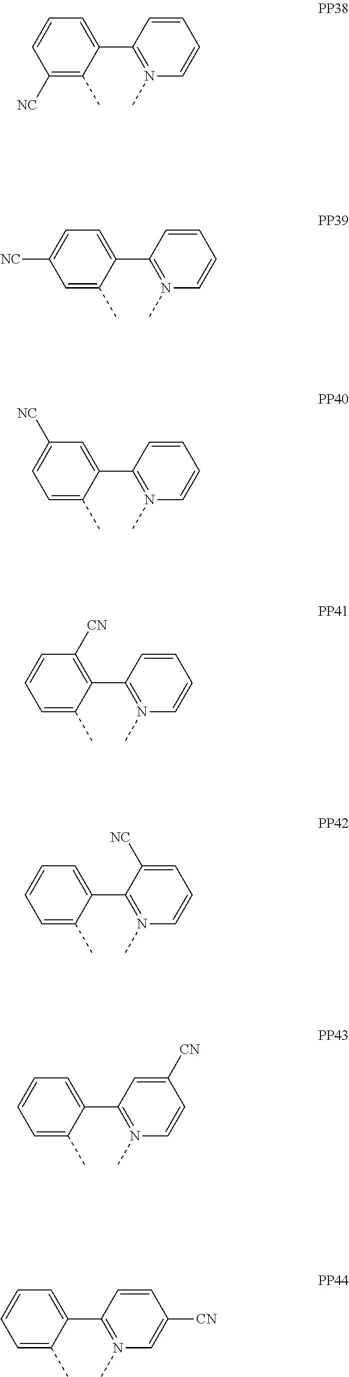

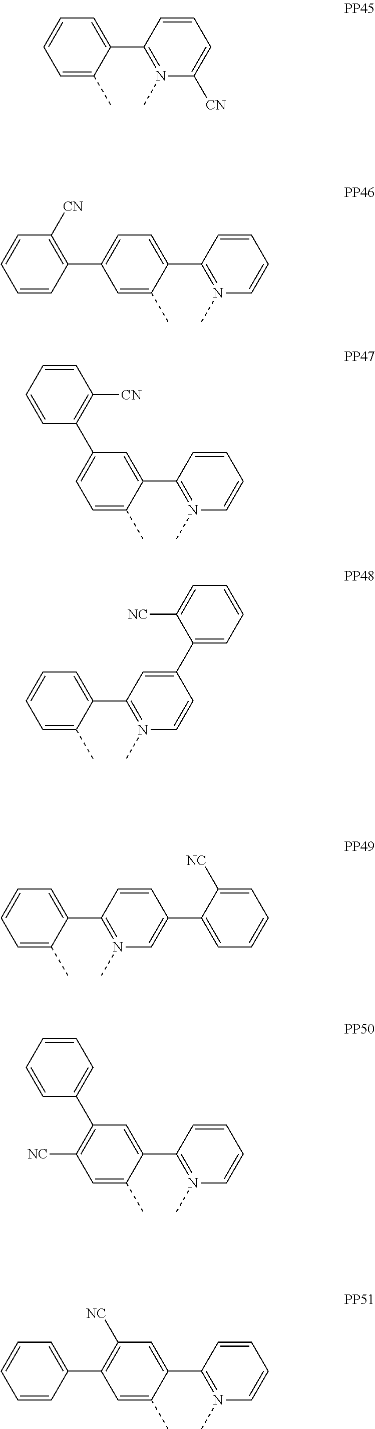

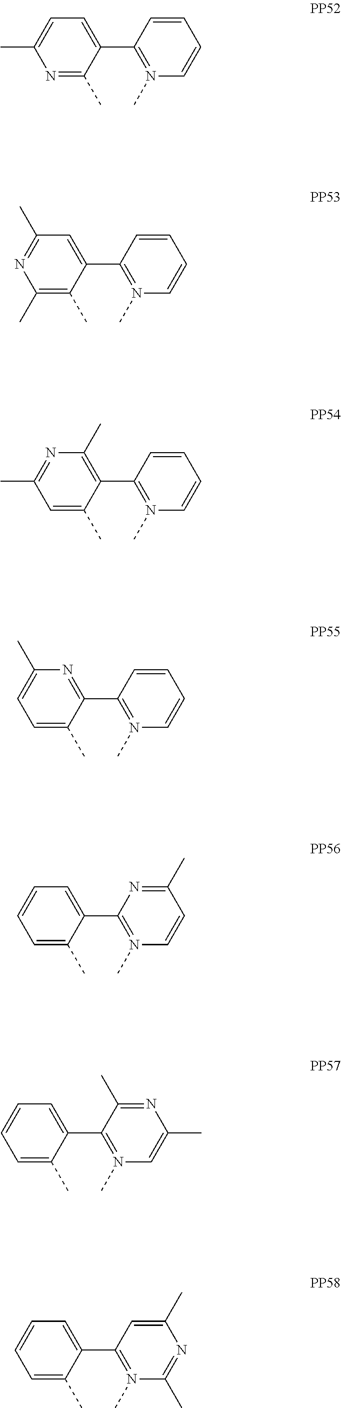

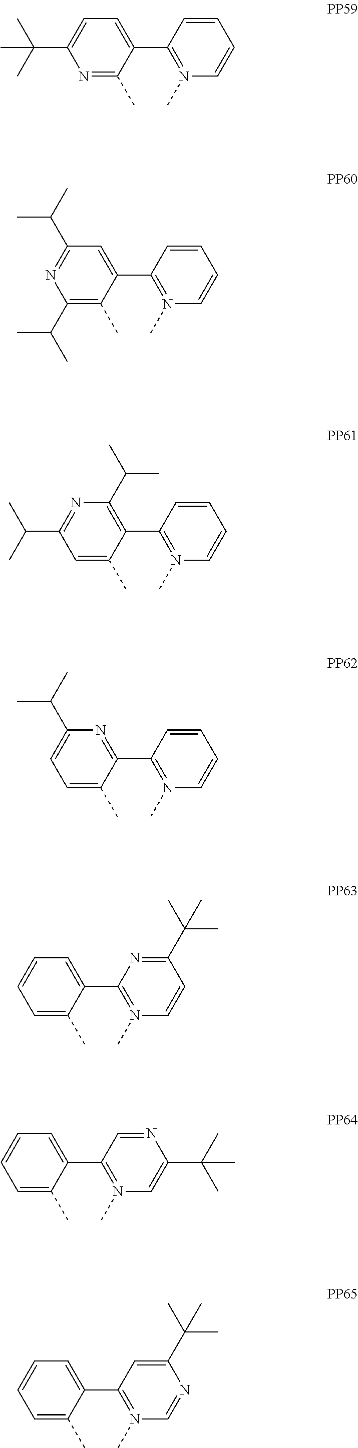

(1-7) The first light-emitting layer further satisfies the following relationship (h):

$$C 1 ( D 3 ) > C 1 ( D 1 ) . \qquad ( h )$$

In the organic light-emitting device according to the present invention, the first light-emitting layer preferably satisfies the relationship (h). Specifically, the concentration of the third metal complex in the first light-emitting layer is preferably higher than the concentration of the first metal complex in the first light-emitting layer. As described in (1-6), at least one ligand contained in the third metal complex is identical to a ligand contained in the second metal complex. Thus, carriers can easily transfer between the first light-emitting layer and the second light-emitting layer via the second metal complex and the third metal complex. For this reason, when the concentration of the third metal complex in the first light-emitting layer is higher than that of the first metal complex in the first light-emitting layer, carrier transfer can be further promoted. As a result, the organic light-emitting device according to the present invention has superior luminous efficiency.
(1-8) The first light-emitting layer and the second light-emitting layer further satisfy the following relationships (i) and (j):

$$\vert LUMO ( D 3 ) - LUMO ( D 2 ) \vert \leq 0.2 eV \qquad ( i )$$

$$\vert HOMO ( D 3 ) - HOMO ( D 2 ) \vert \leq 0.2 eV . \qquad ( j )$$

As described above, when the first light-emitting layer contains the third metal complex, carriers easily transfer between the first light-emitting layer and the second light-emitting layer via the second metal complex and the third metal complex. Small differences in HOMO and LUMO levels between the second metal complex and the third metal complex are preferred. Specifically, the second metal complex and the third metal complex preferably satisfy the relationships (i) and (j). When the above relationship is satisfied, the carrier transfer between the first light-emitting layer and the second light-emitting layer is further promoted. As a result, the organic light-emitting device according to the present invention has superior luminous efficiency.
(1-9) The first light-emitting layer and the second light-emitting layer further satisfy the following relationship (k):

$$HOMO ( D 3 ) > HOMO ( H 1 ) . \qquad ( k )$$

In the organic light-emitting device according to the present invention, the HOMO level of the third metal complex contained in the first light-emitting layer is preferably higher (closer to the vacuum level) than the HOMO level of the first organic compound. When the relationship (k) is satisfied, holes are easily trapped in the third metal complex. As described above, carriers easily transfer between the first light-emitting layer and the second light-emitting layer via the second metal complex and the third metal complex. When the relationship (k) is satisfied, the third metal complex easily traps holes, thus further promoting carrier transfer between the first light-emitting layer and the second light-emitting layer. Therefore, the organic light-emitting device according to the present invention has superior luminous efficiency.

Furthermore, the HOMO level difference between the third metal complex and the first organic compound may be 0.10 eV or more, preferably 0.15 eV or more, more preferably 0.5 eV or more, and particularly preferably 0.8 eV or more. This is because a larger HOMO level difference between the third metal complex and the first organic compound results in a higher hole-trapping property of the third metal complex.

As described in (1-2), metal complexes tend to have high HOMO levels (close to the vacuum level) and thus may satisfy the relationship (1):

$$HOMO ( D 3 ) - HOMO ( H 1 ) > LUMO ( H 2 ) - LUMO ( H 3 ) . \qquad ( 1 )$$

Therefore, the concentration of the first metal complex in the first light-emitting layer, the concentration of the third metal complex in the first light-emitting layer, and the concentration of the third organic compound in the second light-emitting layer preferably satisfy the relationship (m):

$$C 2 ( H 3 ) > C 1 ( D 3 ) , C 1 ( D 1 ) . \qquad ( m )$$

When the concentration of the third organic compound, which has the electron-trapping property, is higher than the concentration of the third metal complex and the first metal complex, which have hole-trapping properties, the first light-emitting layer and the second light-emitting layer can trap holes and electrons in a well-balanced manner. As a result, the carrier balance in the light-emitting layers is adjusted, and thus the organic light-emitting device according to the present invention has superior durability.
(1-10) The emission wavelength of the first metal complex is longer than the emission wavelength of the second metal complex.

In the organic light-emitting device according to the present invention, in order to further increase the luminous efficiency of each of the first light-emitting layer and the second light-emitting layer, the emission wavelength of the first metal complex is preferably longer than the emission wavelength of the second metal complex. When the organic light-emitting device according to the present invention has the above configuration, energy can be transferred from the second light-emitting layer that emits higher-energy light to the first light-emitting layer that emits lower-energy light. This enables a further increase in the luminous efficiency of each of the first light-emitting layer and the second light-emitting layer. Specifically, the first metal complex may be a metal complex that emits red light, and the second metal complex may be a metal complex that emits green light. In this case, the organic light-emitting device according to the present invention can emit yellow light by the light emission from the first light-emitting layer and the second light-emitting layer. The first metal complex may be a metal complex that emits green light and the second metal complex may be a metal complex that emits blue light. In this case, the organic light-emitting device according to the present invention can emit cyan light by the light emission from the first light-emitting layer and the second light-emitting layer.

In this specification, the blue-light-emitting material refers to a material that emits light having a maximum peak wavelength of 430 nm to 480 nm in the emission spectrum. The green-light-emitting material refers to a material that emits light having a maximum peak wavelength of 500 nm to 570 nm in the emission spectrum. The red-light-emitting material refers to a material that emits light having a maximum peak wavelength of 580 nm to 680 nm in the emission spectrum. Yellow-light emission indicates that a main part of an emission spectrum is included in 565 nm to 590 nm. For example, yellow-light emission can also be obtained by mixing green-light emission and red-light emission. Cyan-light emission indicates that a main part of an emission spectrum is included in 485 nm to 500 nm. For example, cyan-light emission can also be obtained by mixing blue-light emission and green-light emission. The emission spectra can be measured with the influence of other compounds and crystalline states reduced by using, for example, a dilute toluene solution.
(1-11) The thickness of the first light-emitting layer is smaller than the thickness of the second light-emitting layer.

When the organic light-emitting device according to the present invention has the configuration described in (1-10), the thickness of the first light-emitting layer is preferably smaller than the thickness of the second light-emitting layer. At this time, the recombination zone of electrons and holes is easily localized on the second light-emitting layer side. This further promotes energy transfer from the second light-emitting layer, which emits higher-energy light, to the first light-emitting layer, which emits lower-energy light. As a result, it is possible to provide the organic light-emitting device having superior luminous efficiency.
(1-12) The second metal complex and the third metal complex are the same compound.

In the organic light-emitting device according to the present invention, the second metal complex and the third metal complex are preferably the same compound. In the case of the above-described configuration, carrier transfer can be further promoted because of a smaller energy difference between the first light-emitting layer and the second light-emitting layer. In particular, when the emission wavelength of the first metal complex is longer than the emission wavelength of the second metal complex, energy transfer can also be promoted. Therefore, the organic light-emitting device according to the present invention has superior durability and luminous efficiency.
(1-13) The first organic compound and the second organic compound are the same compound.

In the organic light-emitting device according to the present invention, the first organic compound and the second organic compound are preferably the same compound. In the case of the above-described configuration, carrier transfer can be further promoted because of a smaller energy difference between the first light-emitting layer and the second light-emitting layer. In particular, when the emission wavelength of the first metal complex is longer than the emission wavelength of the second metal complex, energy transfer can also be promoted. Therefore, the organic light-emitting device according to the present invention has superior durability and luminous efficiency.
(1-14) The first light-emitting layer and the second light-emitting layer further satisfy the following relationship (n):

$$HOMO ( D 1 ) - HOMO ( H 1 ) > LUMO ( H 2 ) - LUMO ( H 3 ) \geq 0.1 eV . \qquad ( n )$$

When the organic light-emitting device according to the present invention satisfies the relationship (n), it is possible to provide the organic light-emitting device having superior durability.

As described in (1-1), the organic light-emitting device according to the present invention has a configuration in which the first light-emitting layer easily traps holes, and the second light-emitting layer easily traps electrons. The inventors have focused on the magnitude of the HOMO level difference between the first metal complex and the first organic compound, and the magnitude of the LUMO level difference between the second organic compound and the third organic compound. Since the magnitude of the carrier trapping property of the light-emitting layers tends to be proportional to the HOMO (LUMO) level difference between the compounds contained in each light-emitting layer, preferably, there is a certain difference in HOMO (LUMO) level. Therefore, the organic light-emitting device according to the present invention preferably satisfies the relationship (n).

Specifically, in the first light-emitting layer, the HOMO level difference between the first metal complex and the first organic compound may be 0.10 eV or more, preferably 0.15 eV or more, more preferably 0.30 eV or more, even more preferably 0.50 eV or more, and particularly preferably 1.0 eV or more.

In the second light-emitting layer, the LUMO level difference between the second organic compound and the third organic compound may be 0.10 eV or more, preferably 0.15 eV or more, more preferably 0.30 eV or more, and particularly preferably 0.40 eV or more.

When the organic light-emitting device according to the present invention satisfies the relationship (n), each of the first light-emitting layer and the second light-emitting layer more easily trap holes and electrons, so that the carrier balance in the light-emitting layers can be further adjusted. As a result, the organic light-emitting device according to the present invention has superior durability.

### (2) First to Third Metal Complexes

The first to third metal complexes used in an embodiment of the present invention are not particularly limited as long as they are metal complexes, but are preferably metal complexes represented by the following general formula [1]:

Ir(L)q(L′)r(L″)s [1].

In the general formula [1], L, L′, and L″ each represent a different bidentate ligand.

q is an integer of 1 to 3, and r and s are each an integer of 0 to 2, provided that q+r+s=3. When r is 2, a plurality of L′ may be the same or different. When s is 2, a plurality of L″ may be the same or different.

The partial structure Ir(L) q is a structure represented by the following general formulae [Ir-1] to [Ir-16].

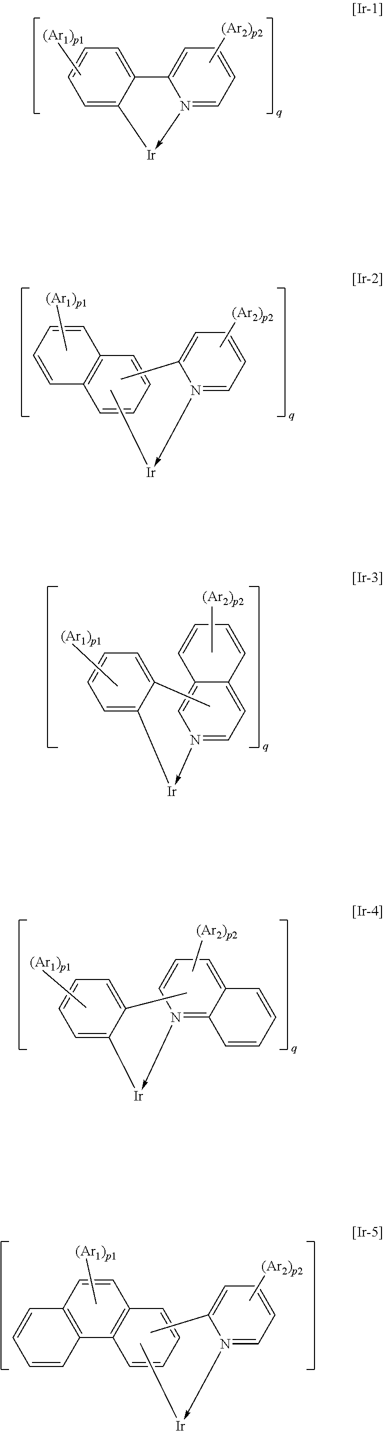

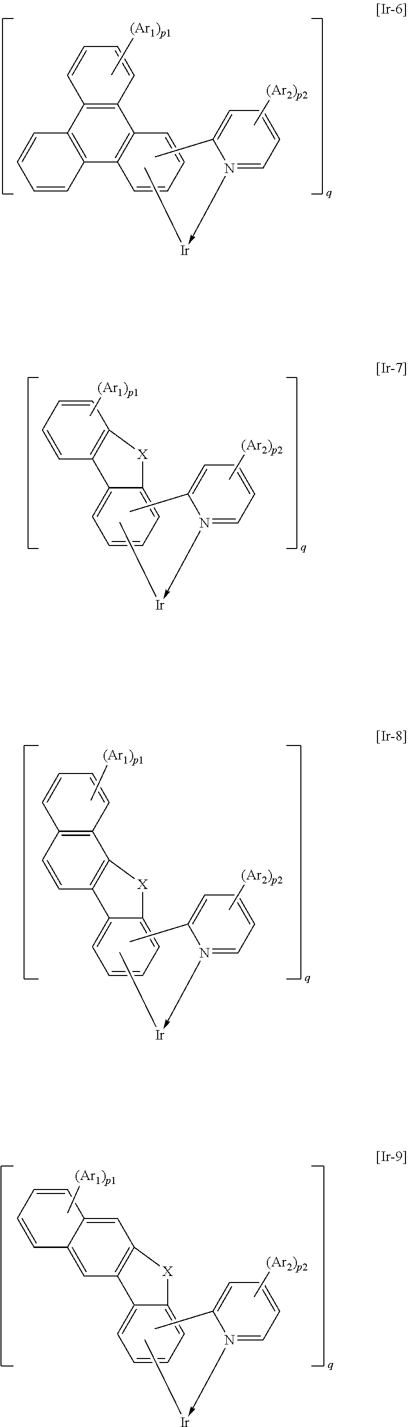

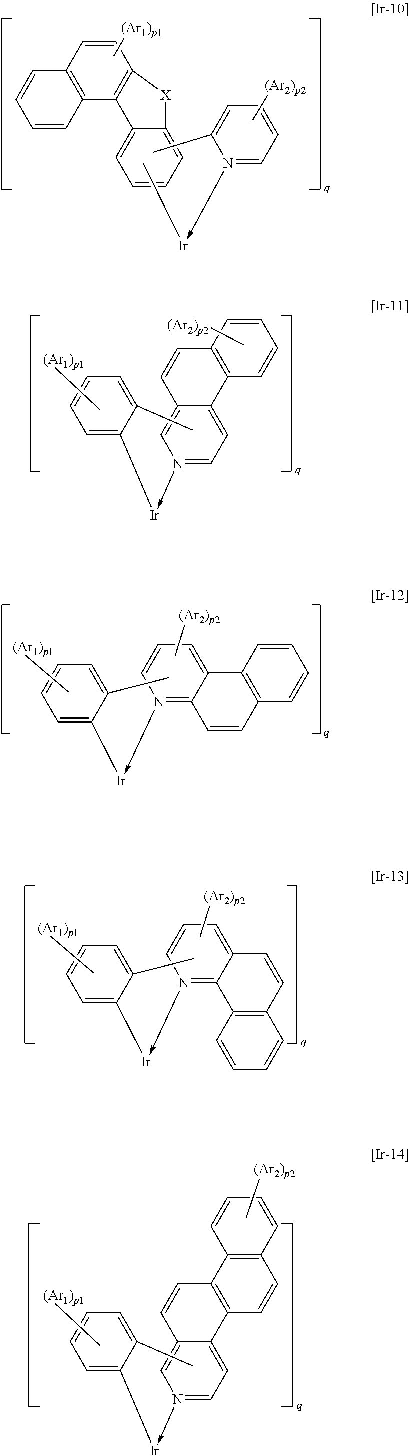

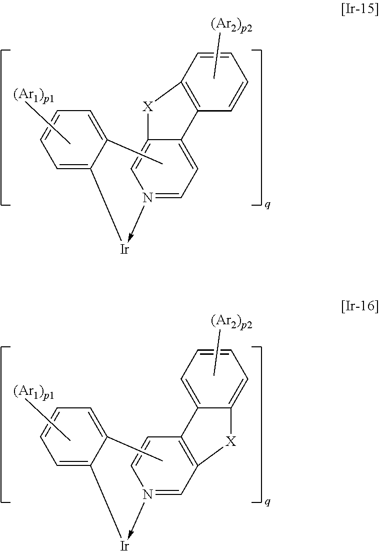

In each of general formulae [Ir-1] to [Ir-16], Ar₁ and Ar₂ are each independently selected from a deuterium atom, a halogen atom, a substituted or unsubstituted alkyl group, a substituted or unsubstituted alkoxy group, a substituted or unsubstituted aryl group, a substituted or unsubstituted heterocyclic group, a substituted or unsubstituted silyl group, and a cyano group. When a plurality of Ar₁ or Ar₂ are present, the plurality of Ar₁ or Ar₂ may be the same substituent or different substituents. Ar₂ and Ar₂ may each be an alkyl group having 1 to 6 carbon atoms, an alkoxy group having 1 to 4 carbon atoms, an aryl group having 6 to 10 carbon atoms, an alkyl group-substituted silyl group, or a cyano group. In particular, an alkyl group having 1 to 4 carbon atoms or an aryl group having 6 to 10 carbon atoms is preferred. A methyl group, an ethyl group, an isopropyl group, a tert-butyl group, or a phenyl group is more preferred. These substituents have relatively small molecular weights and bulky structures. Thus, compounds having these substituents have excellent sublimability.

X is selected from an oxygen atom, a sulfur atom, C(R₁) (R₂), and NR₃. R₁ to R₃ are each independently selected from a hydrogen atom, a deuterium atom, a halogen atom, a substituted or unsubstituted alkyl group, a substituted or unsubstituted alkoxy group, a substituted or unsubstituted amino group, a substituted or unsubstituted aryloxy group, a substituted or unsubstituted aryl group, a substituted or unsubstituted heterocyclic group, a substituted or unsubstituted silyl group, and a cyano group. R₁ and R₂ may be bonded together to form a ring. R₁ to R₃ may each be an alkyl group having 1 to 3 carbon atoms or a phenyl group. In particular, an alkyl group having 1 or 2 carbon atoms or a phenyl group is preferred. A methyl group is more preferred. When these substituents are contained, overlapping of the fused rings can be inhibited, thus resulting in excellent sublimability.

p₁ and p₂ are each an integer of 0 to 4.

q is an integer of 1 to 3.

Each of the first to third metal complexes preferably has a fused-ring structure in its ligand. Specifically, the metal complex preferably has a triphenylene skeleton, a phenanthrene skeleton, a fluorene skeleton, a benzofluorene skeleton, a dibenzofuran skeleton, a dibenzothiophene skeleton, a benzoisoquinoline skeleton, or a naphthoisoquinoline skeleton in its ligand. More specifically, the metal complex is more preferably represented by any of general formulae [Ir-5] to [Ir-16]. All of these skeletons are highly planar, thus allowing the ligands to easily approach each other. As a result, energy transfer by the Dexter mechanism occurs easily, making it possible to provide an organic light-emitting device having excellent luminous efficiency.

Specific examples of the first to third metal complexes according to the present invention are illustrated below. However, the present invention is not limited to these. In the structural formulae below, both of the two bonds between the ligand and the iridium atom may be represented by solid lines. In such cases, one of the bonds may be a covalent bond, and the other bond may be a coordinate bond. When solid lines and dotted lines are mixed, the solid lines may represent covalent bonds, and the dotted lines may represent coordinate bonds.

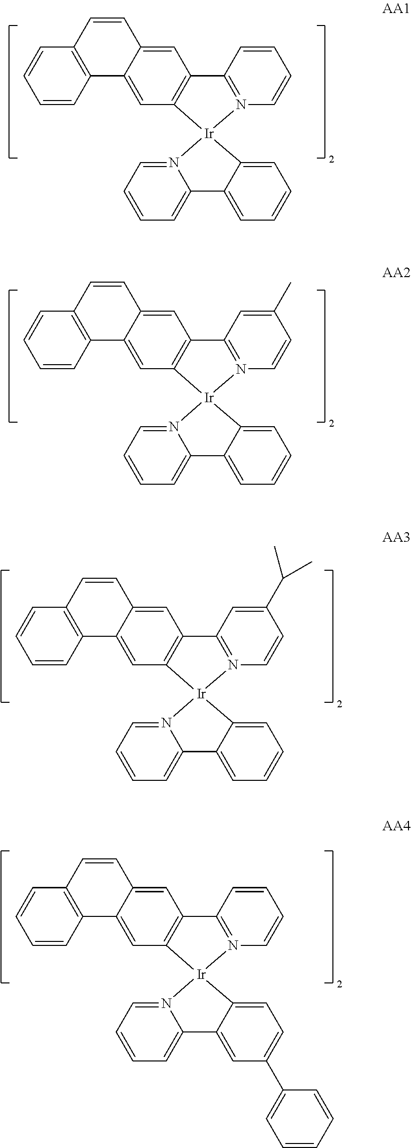

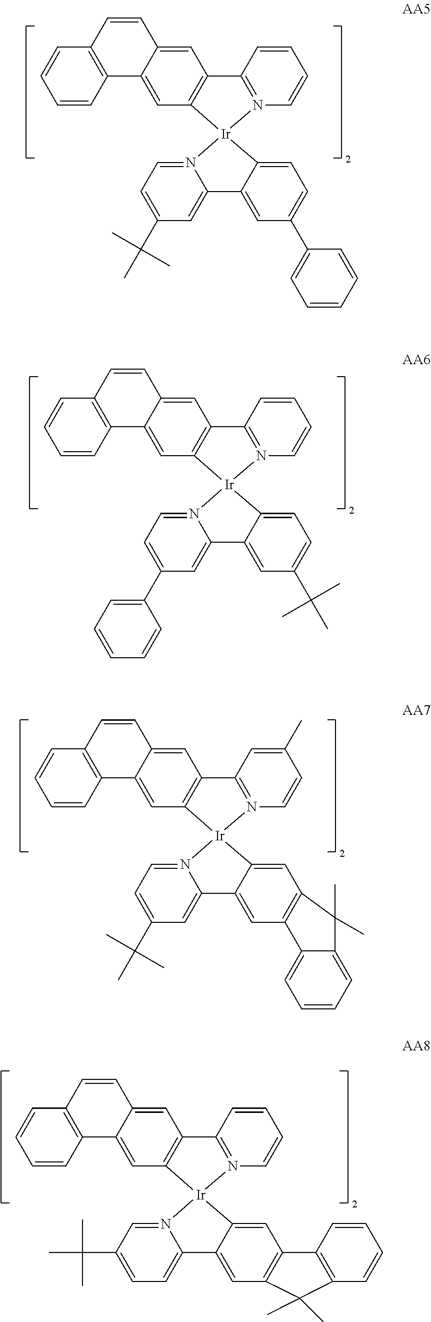

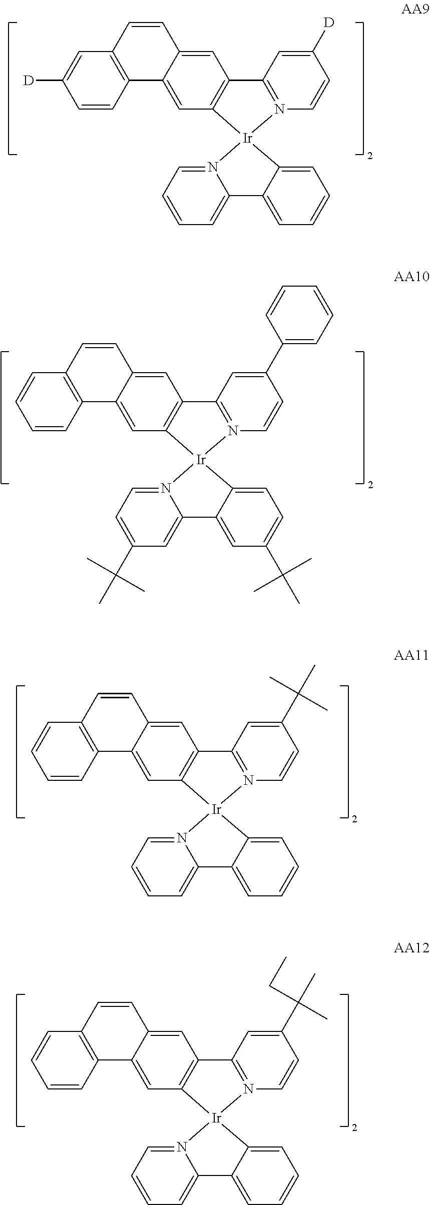

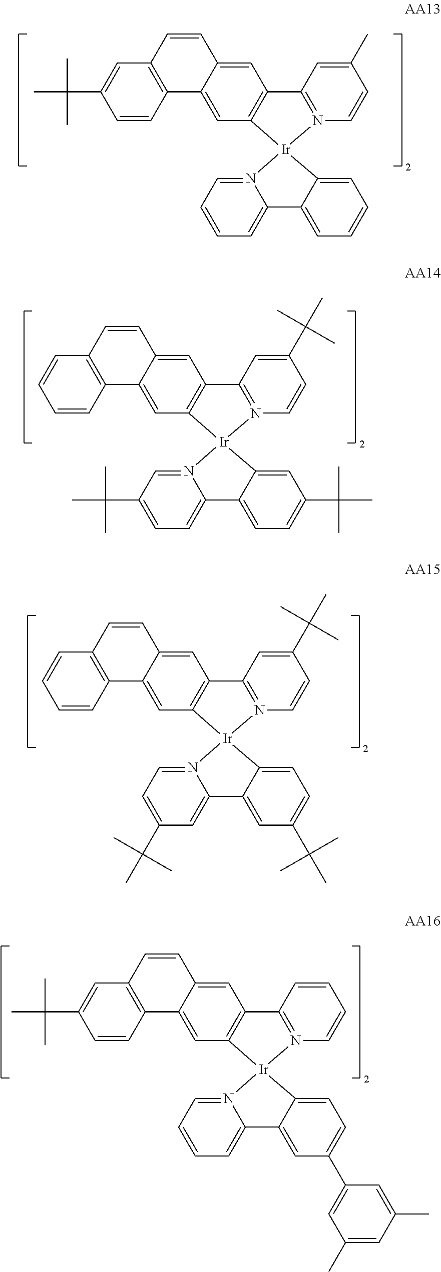

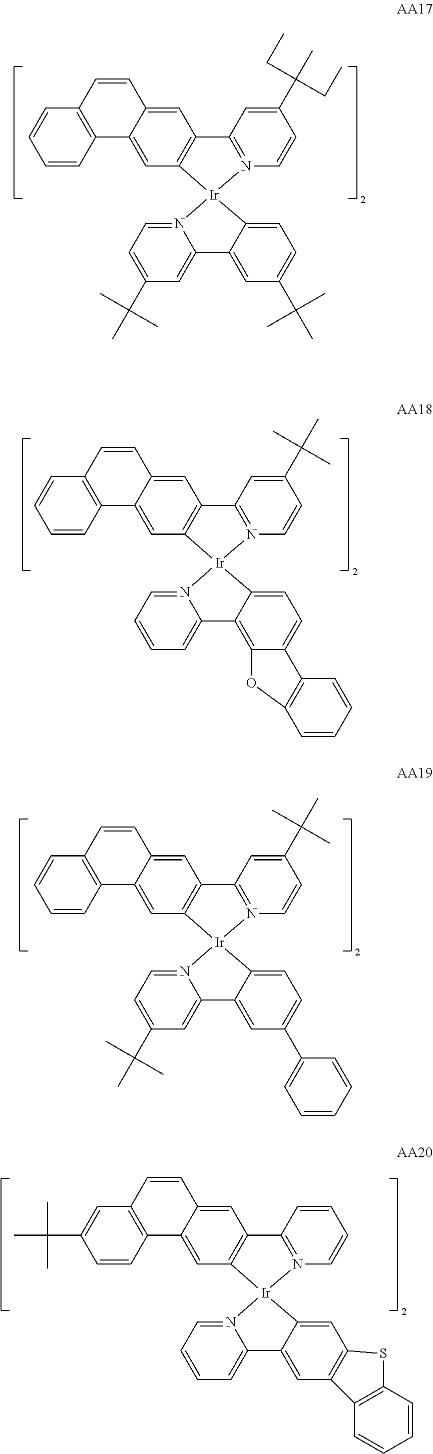

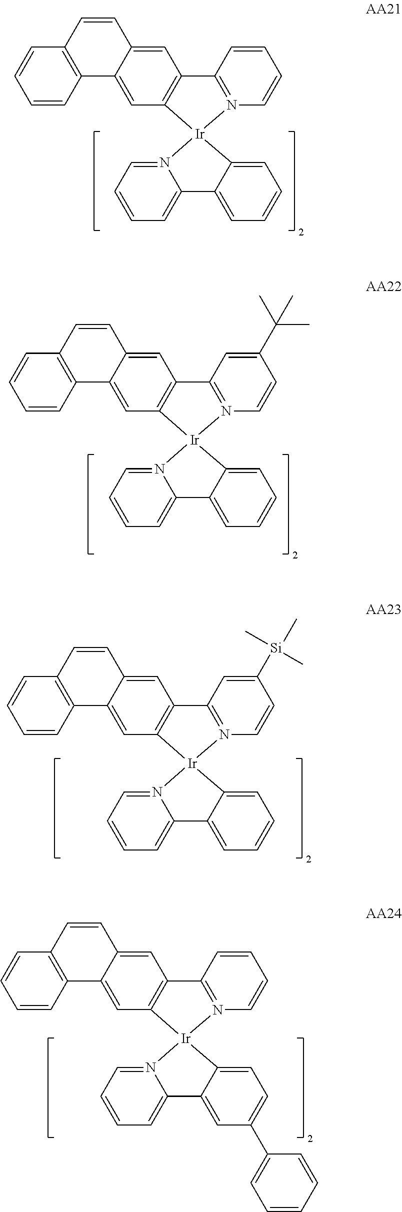

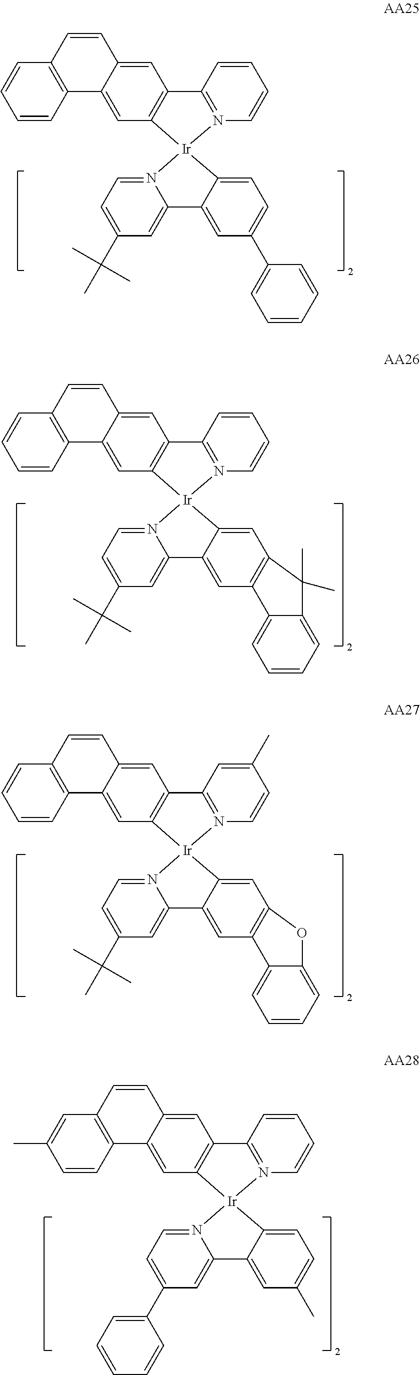

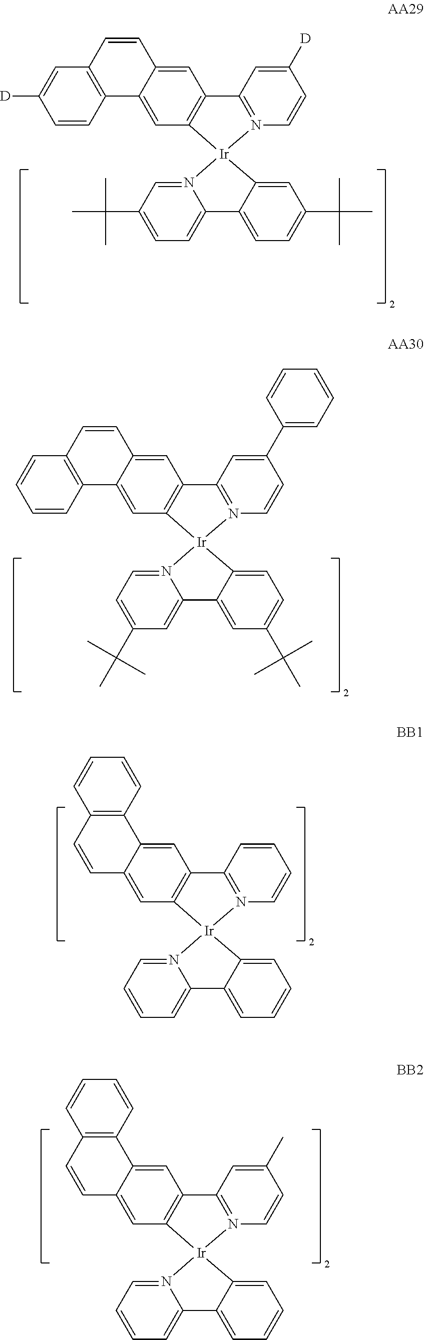

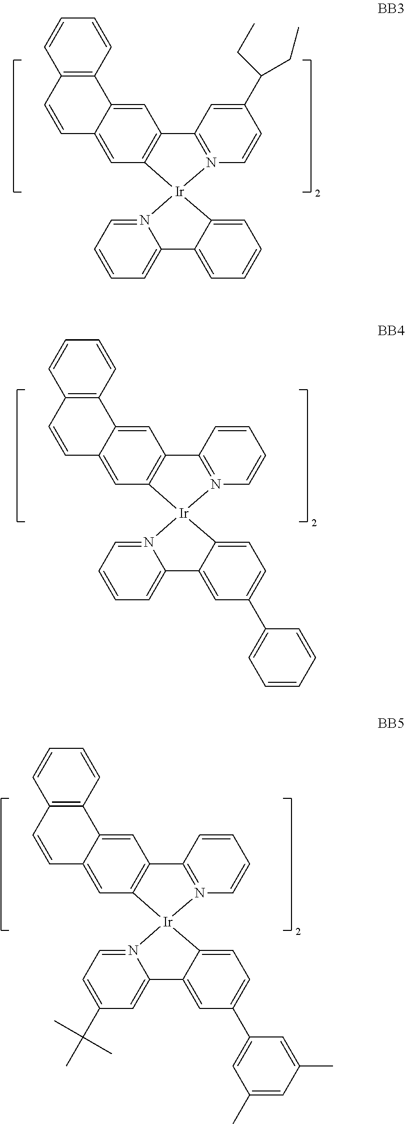

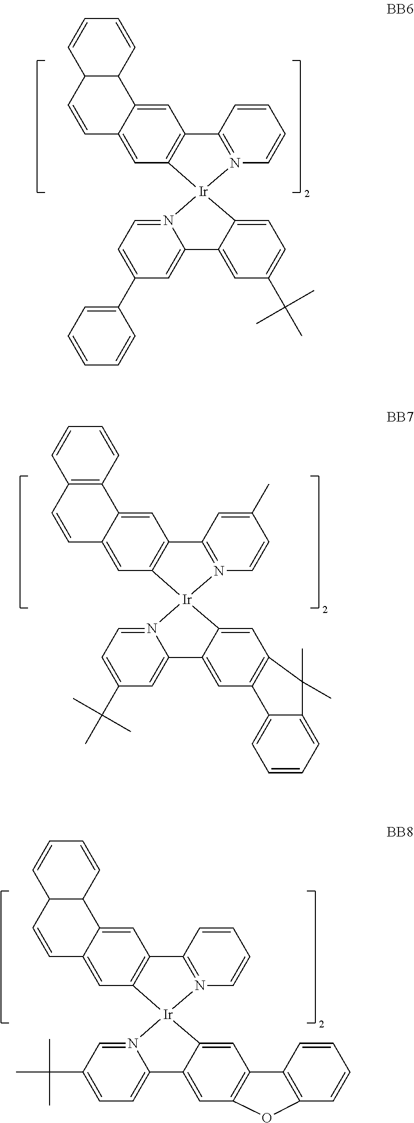

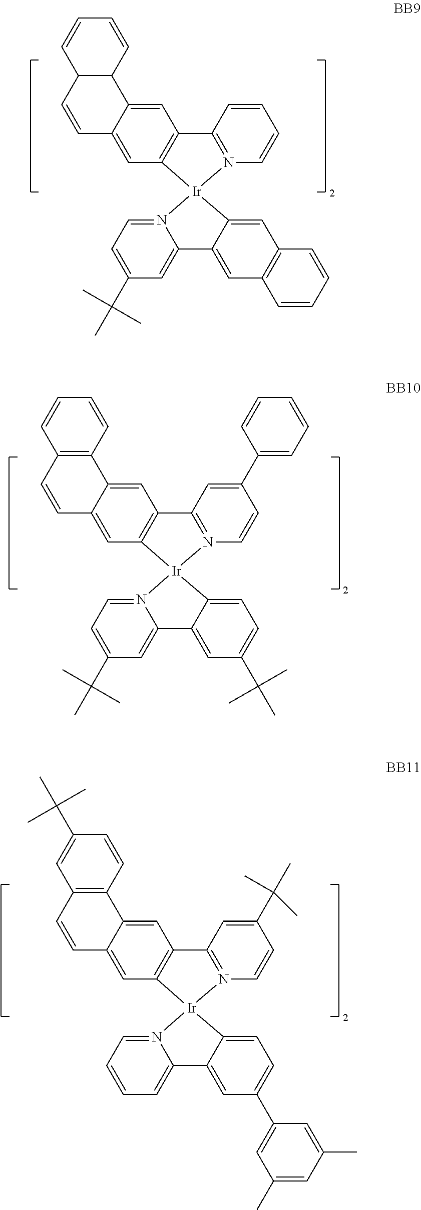

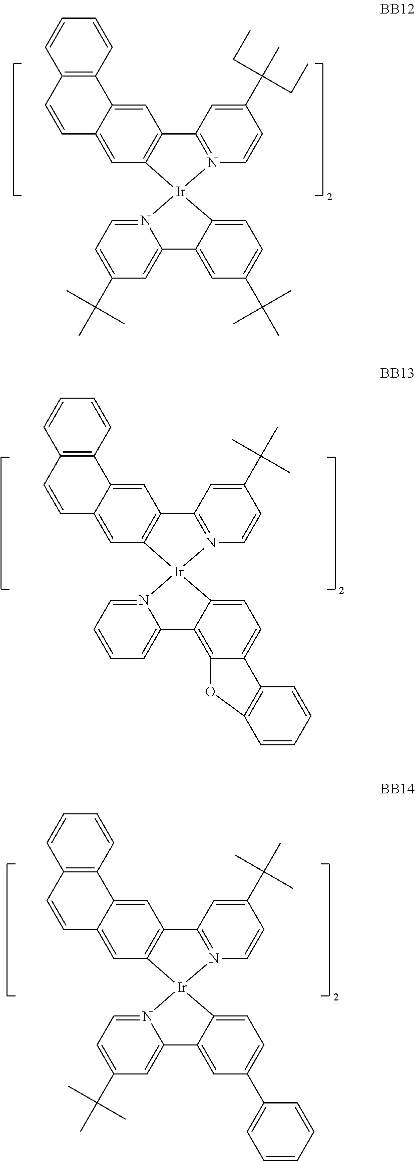

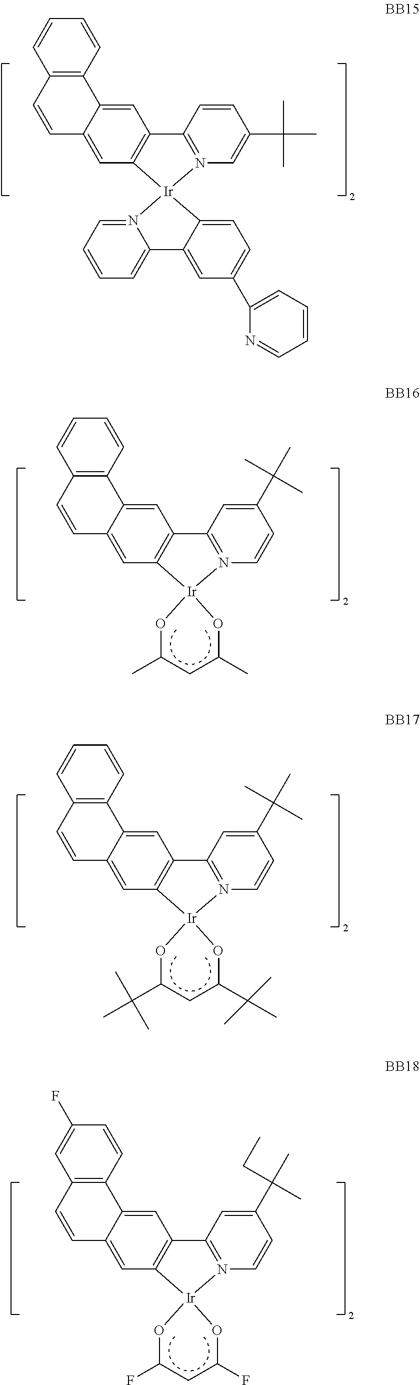

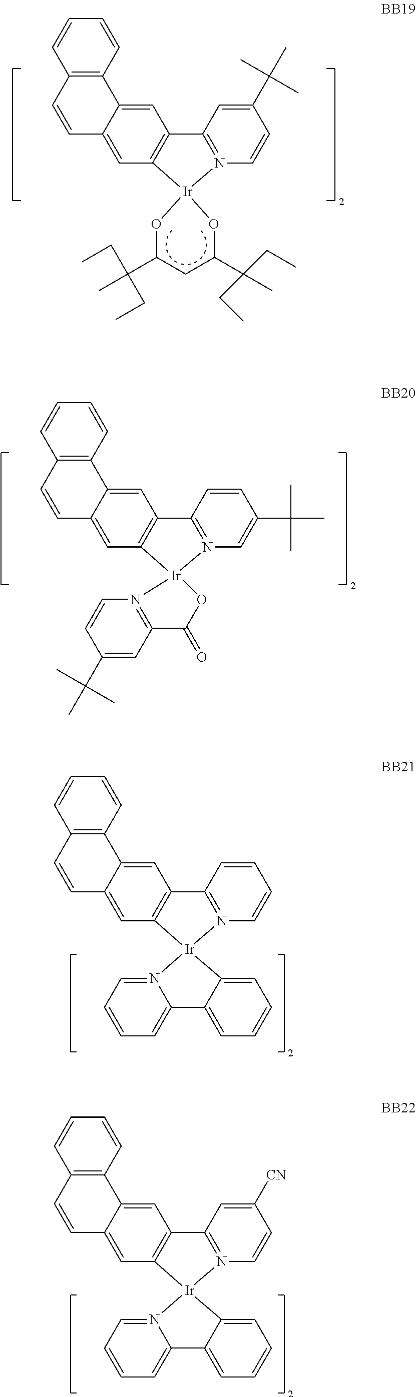

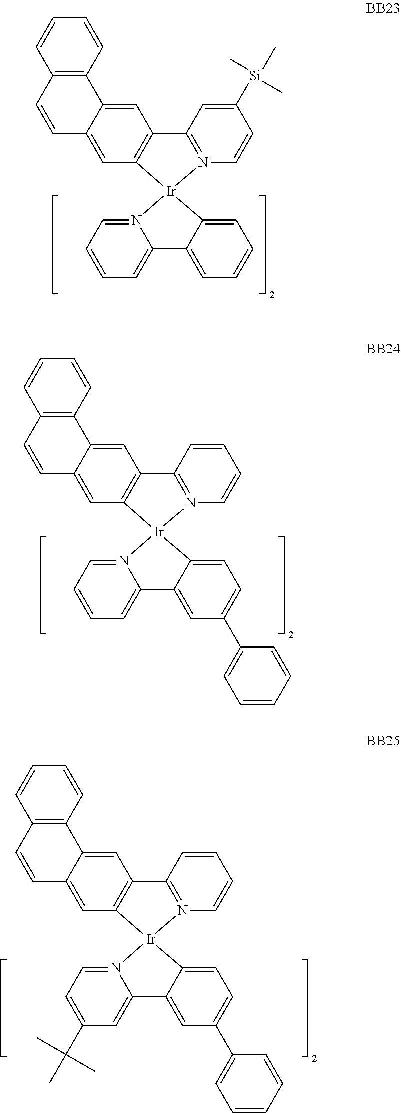

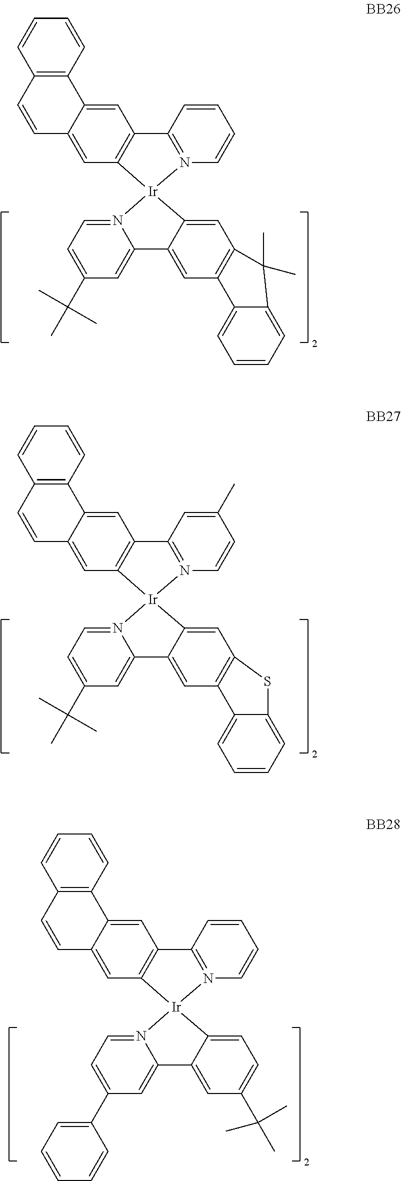

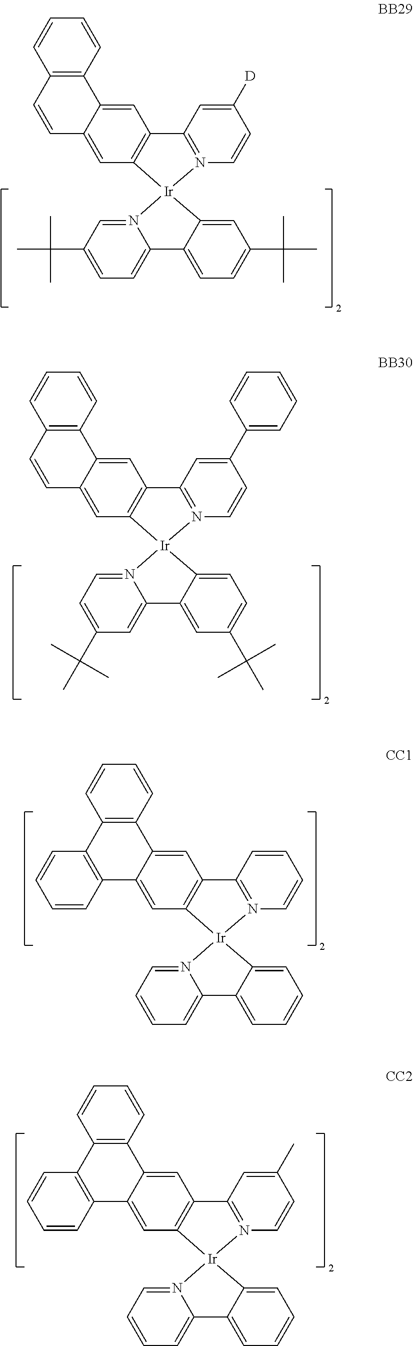

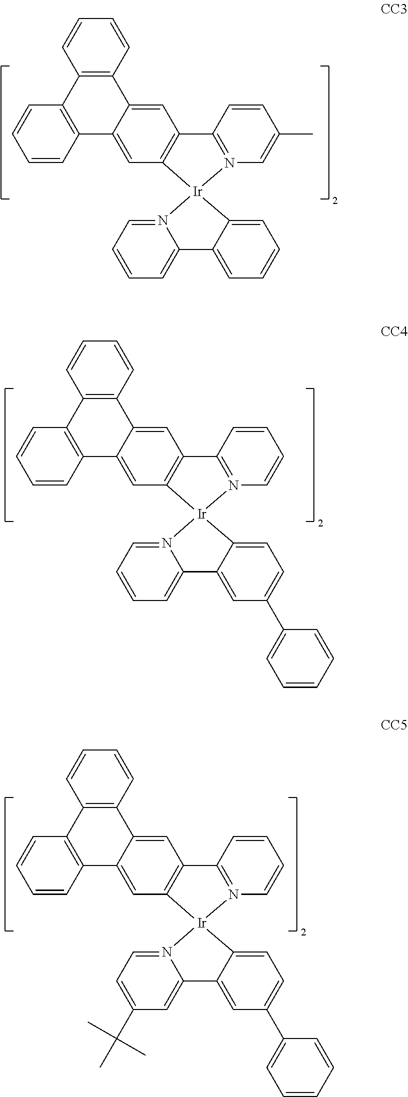

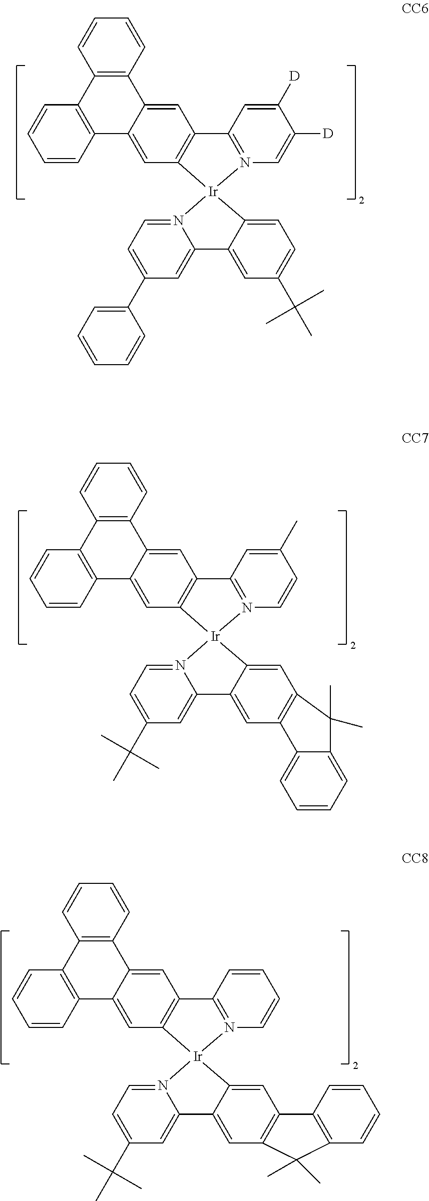

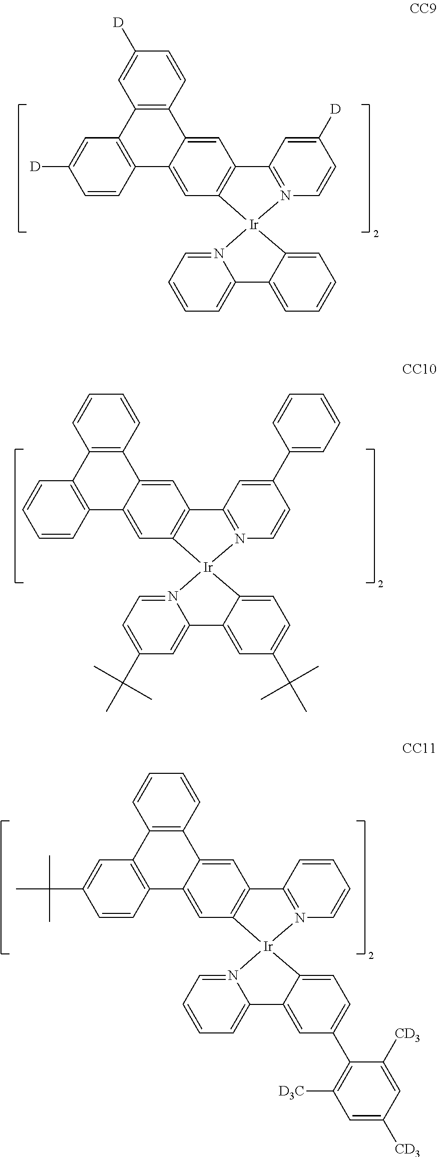

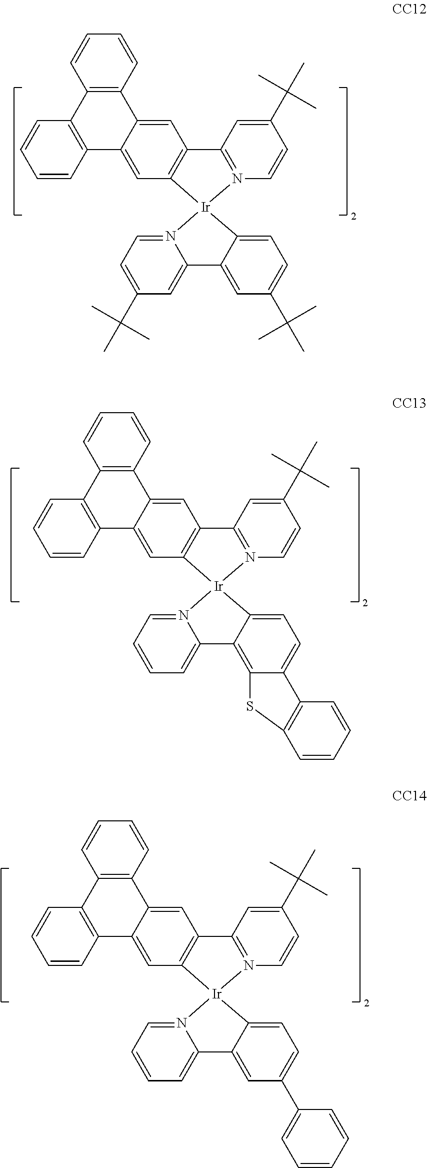

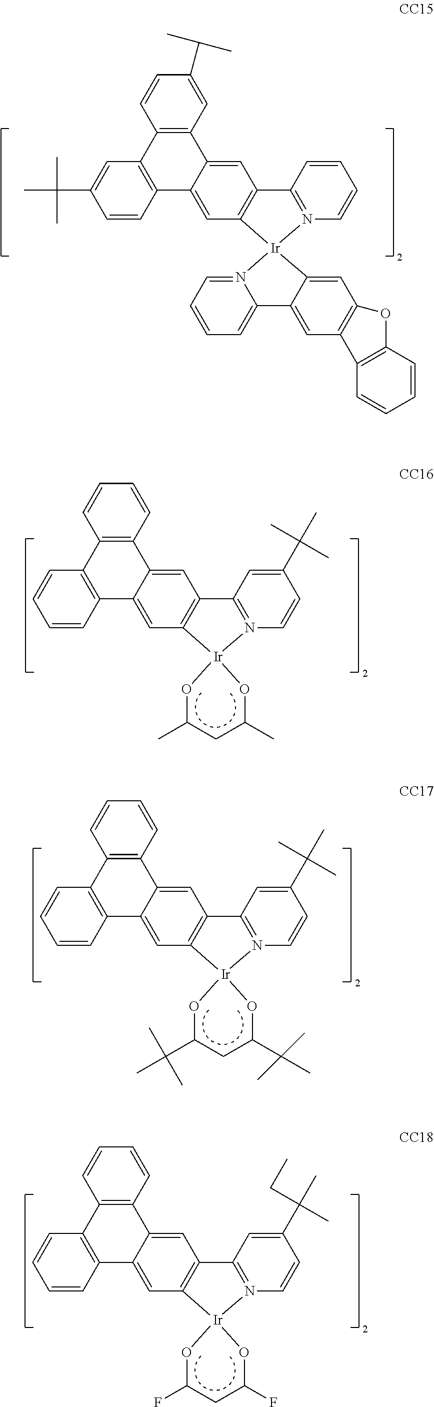

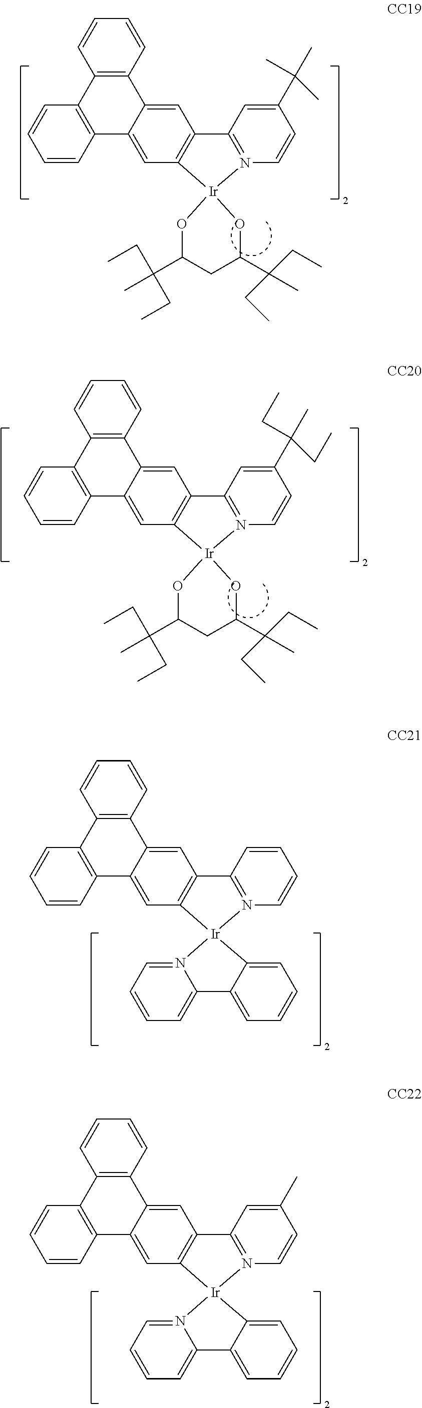

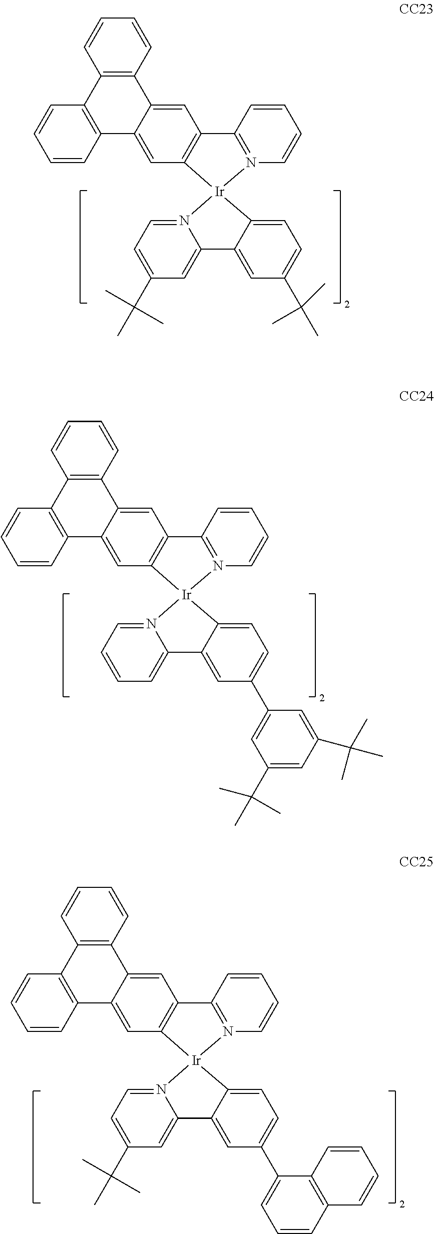

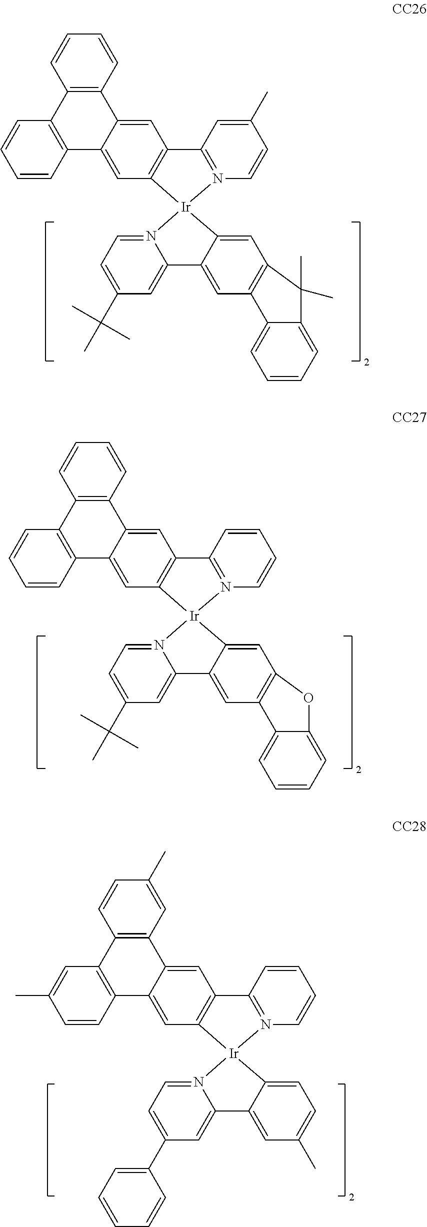

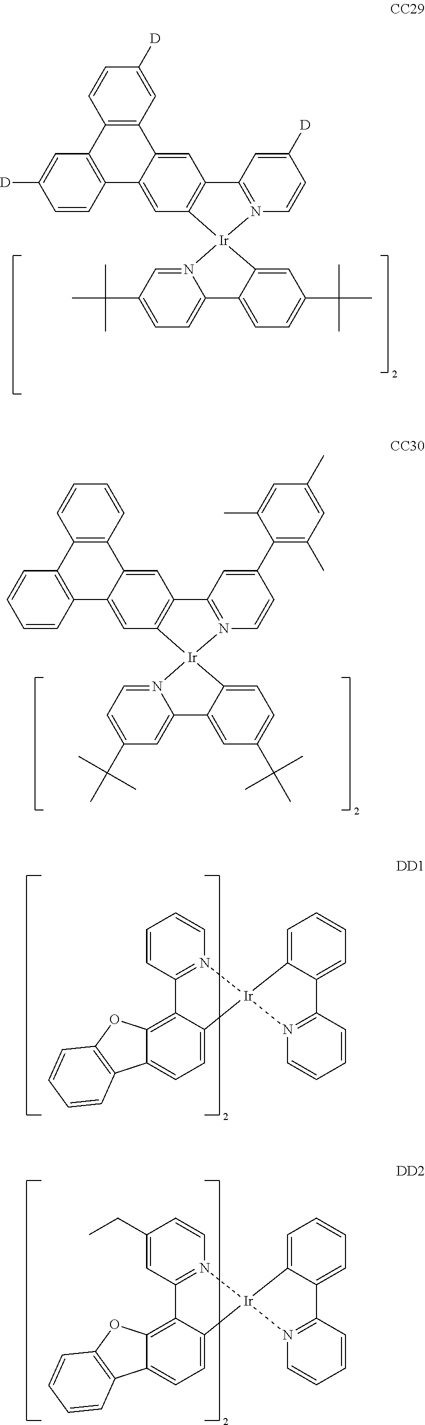

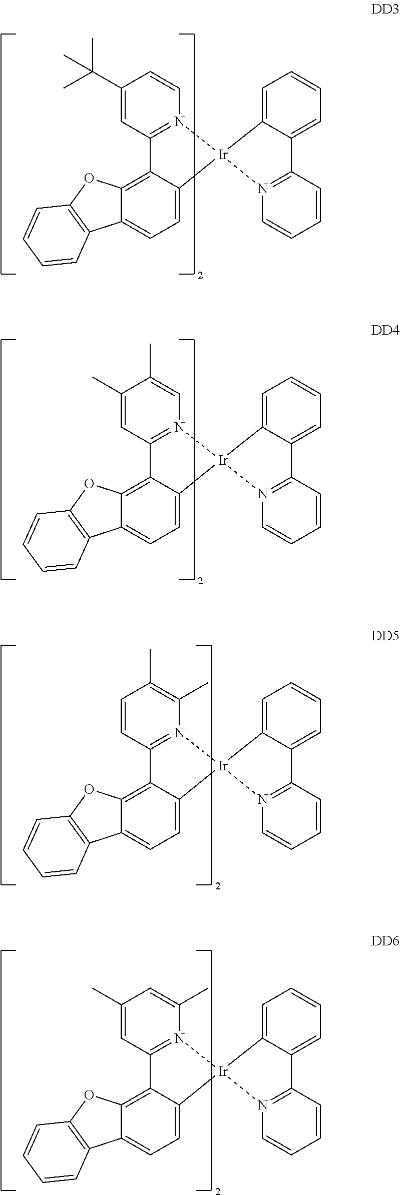

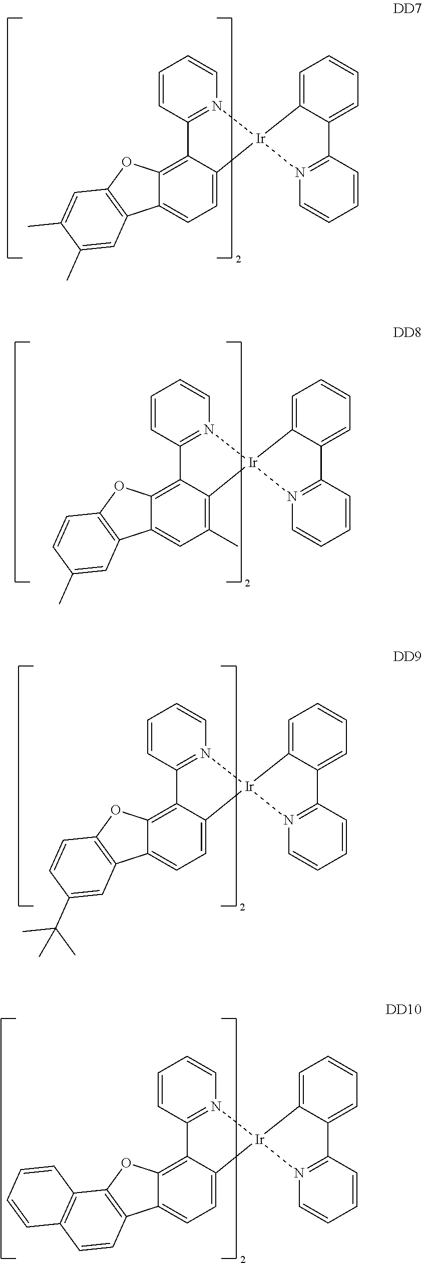

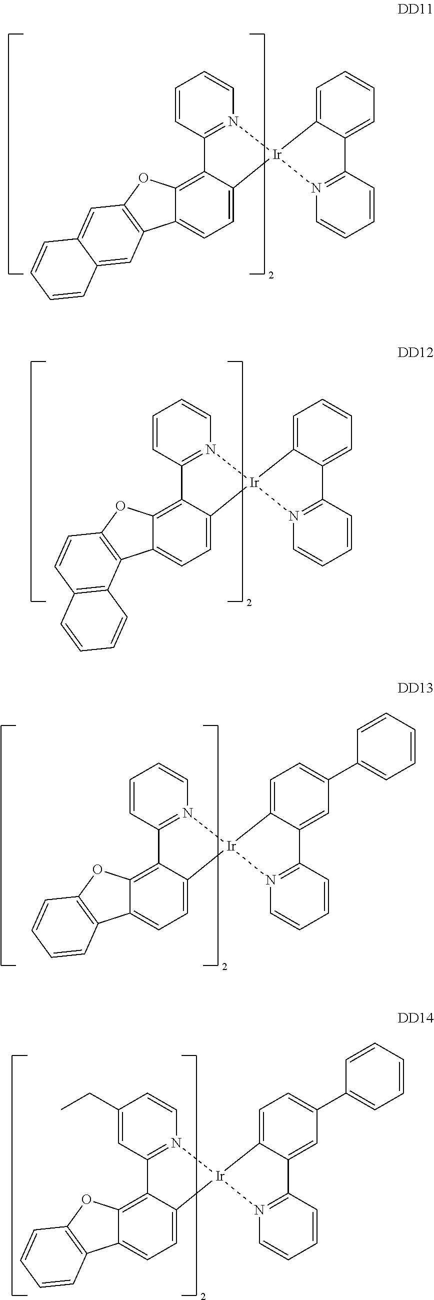

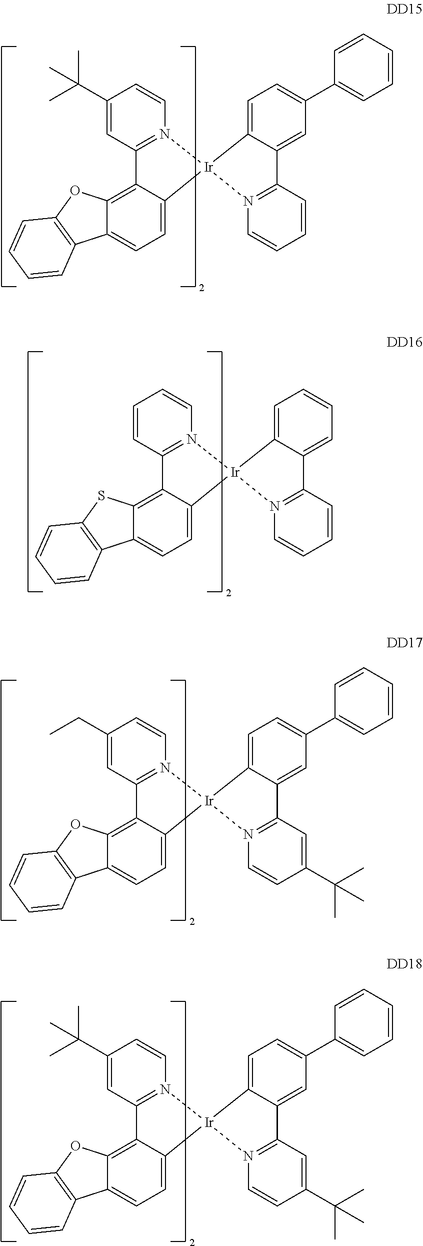

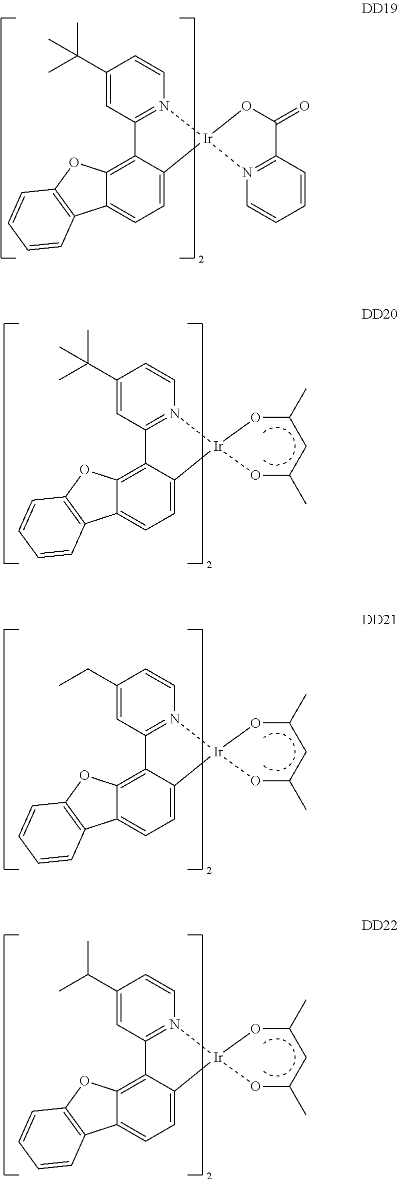

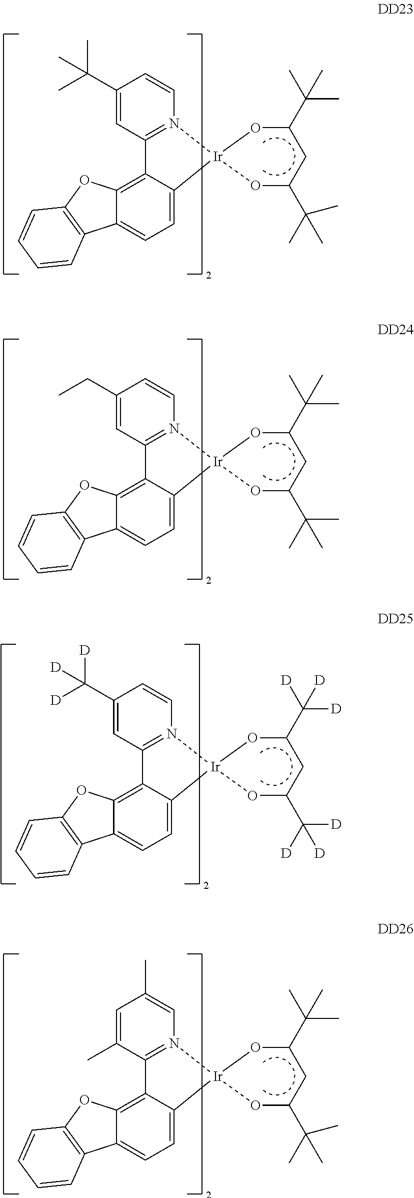

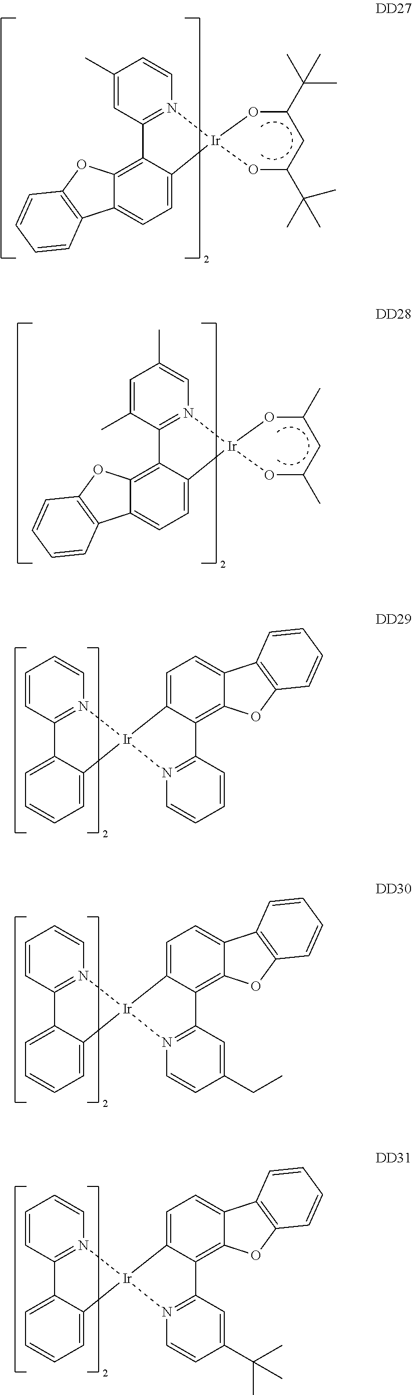

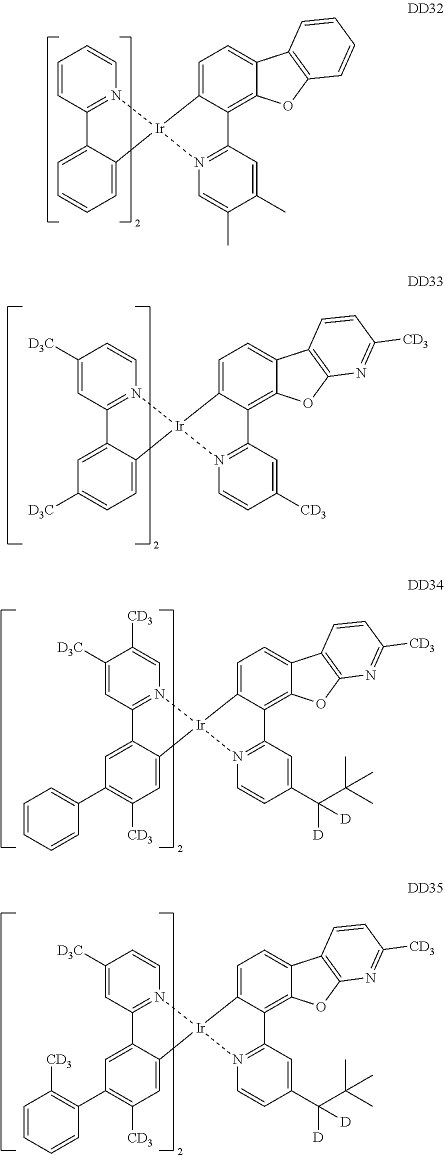

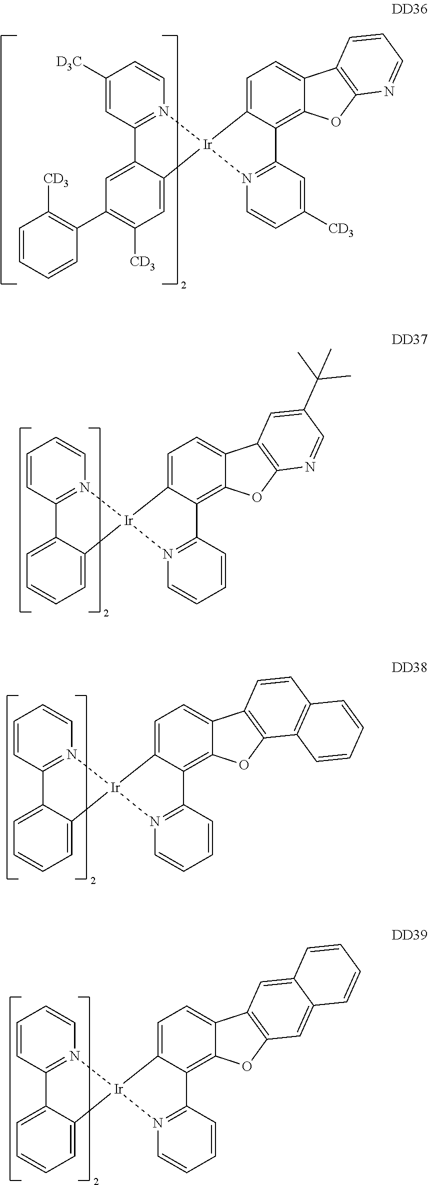

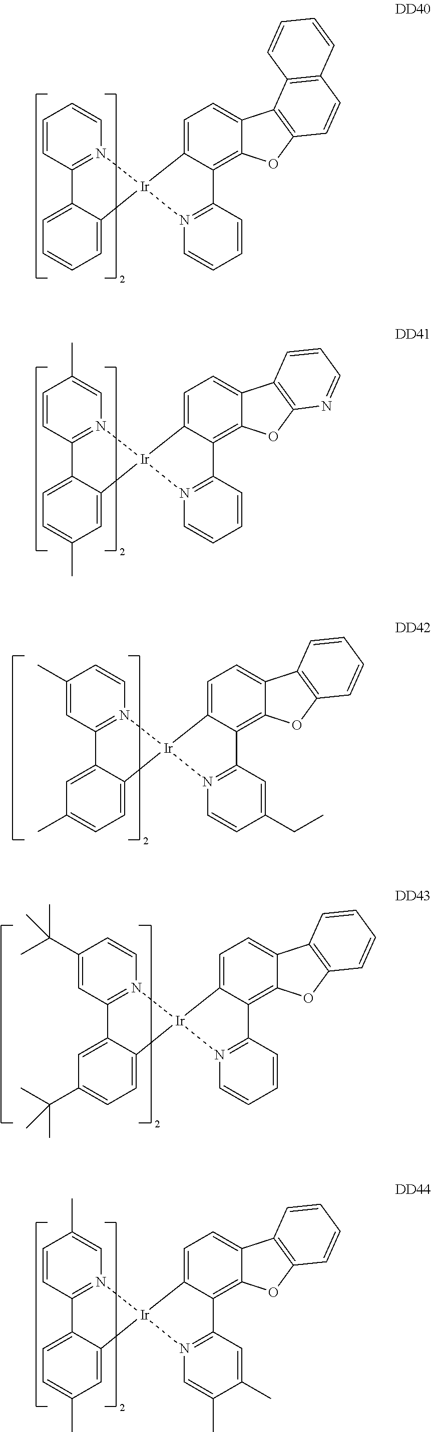

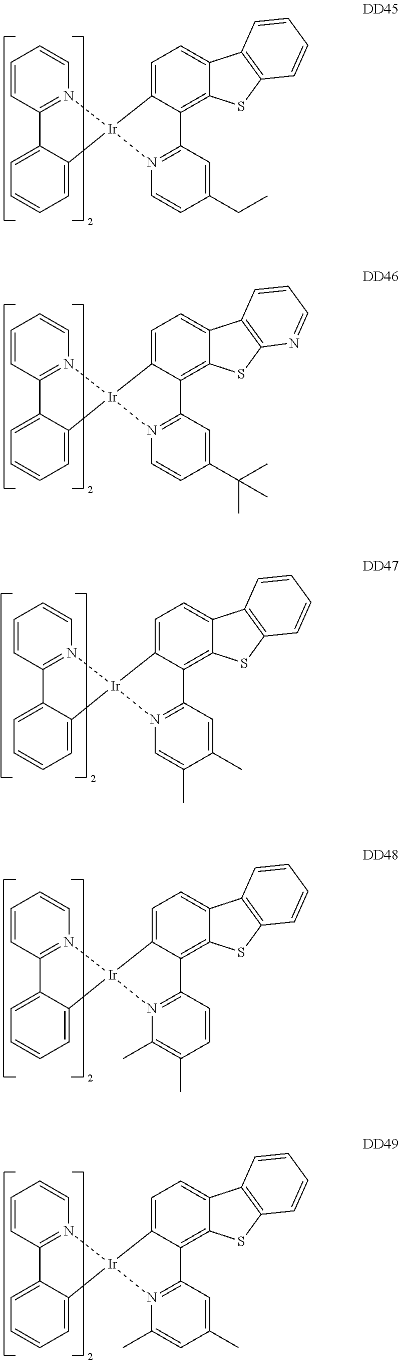

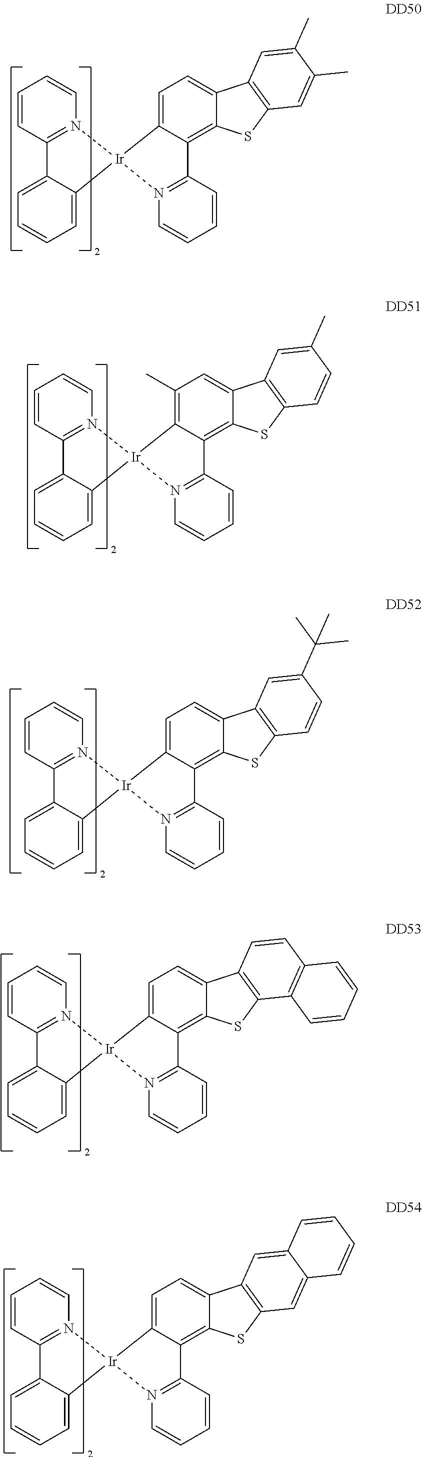

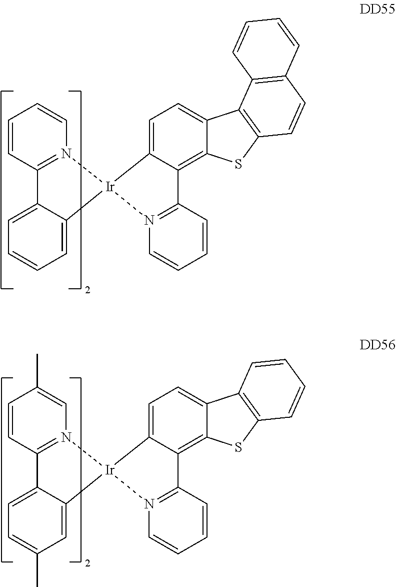

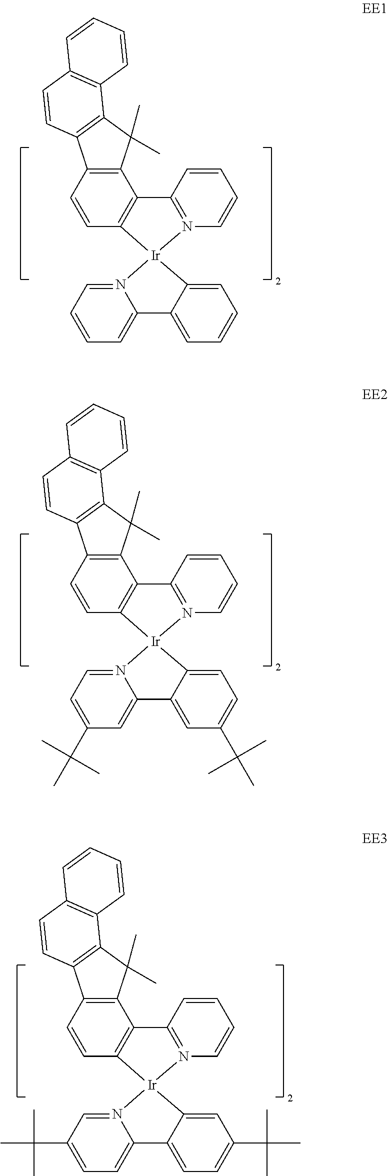

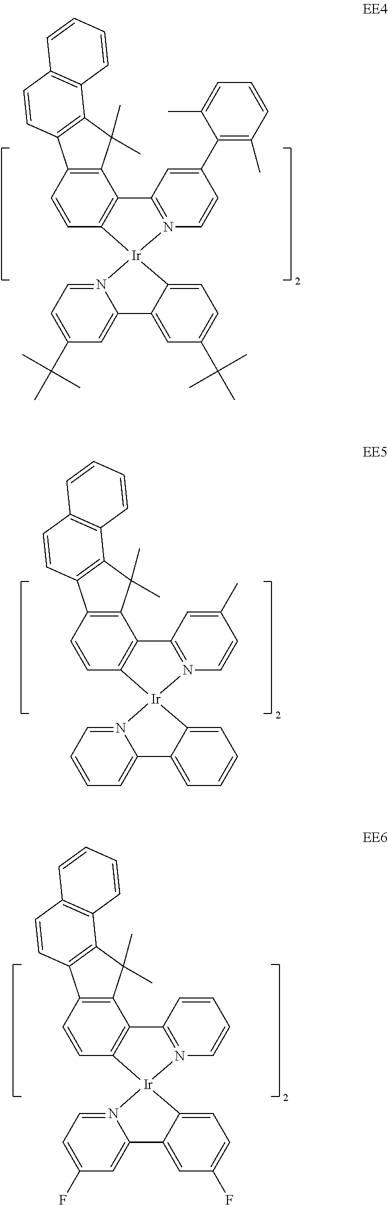

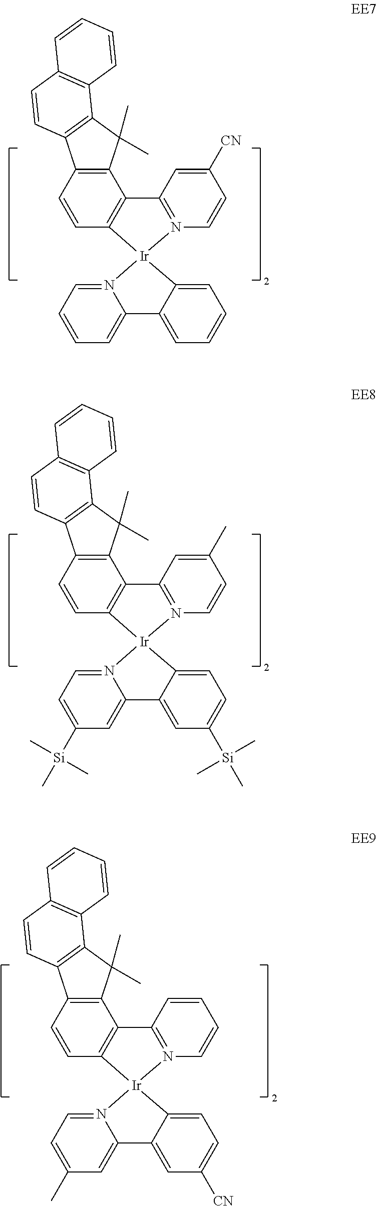

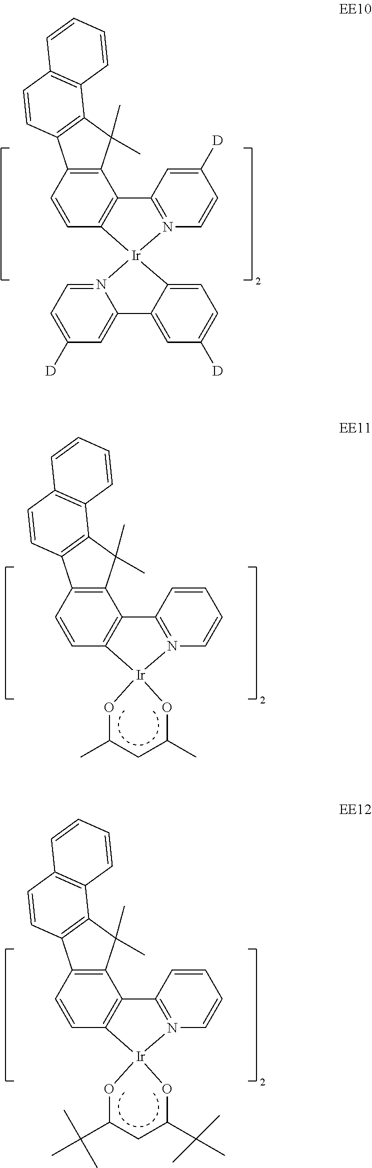

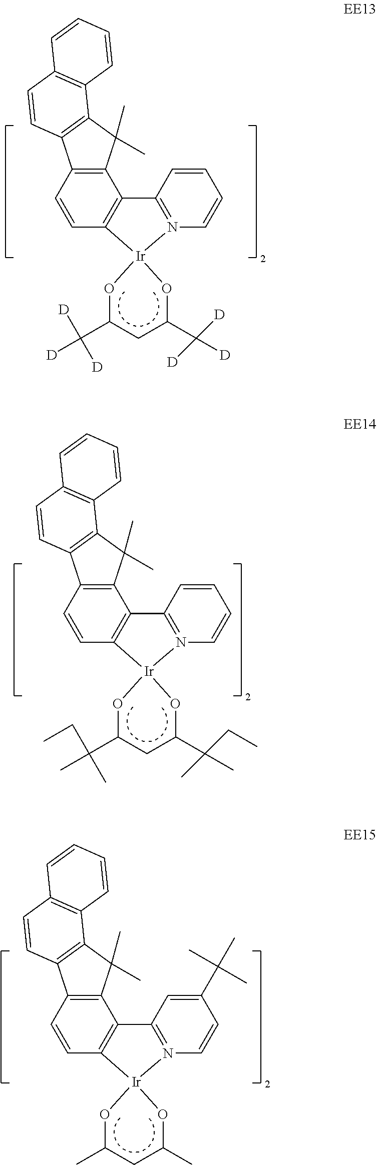

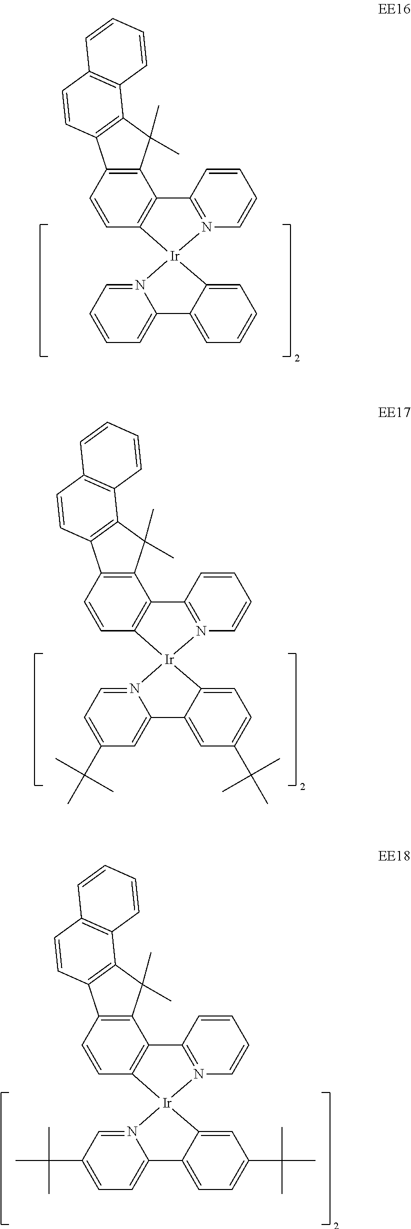

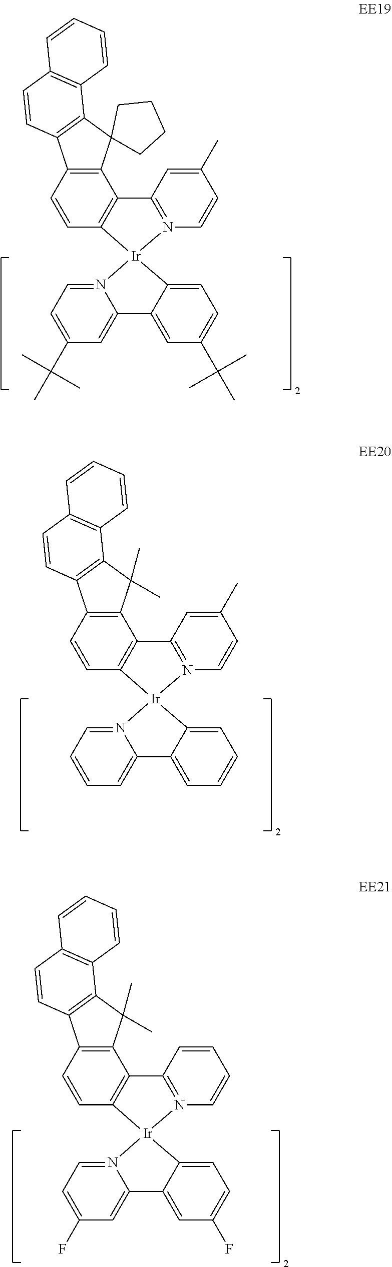

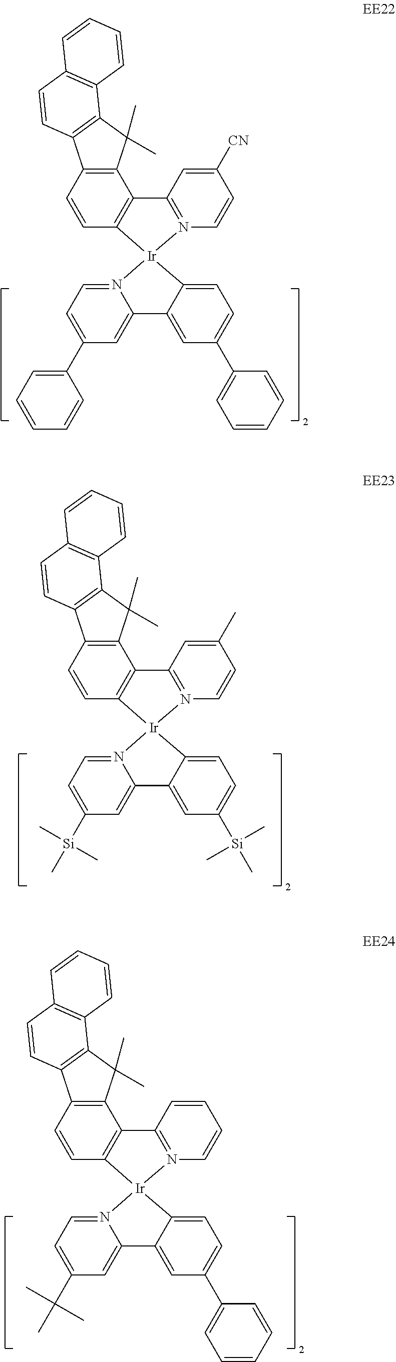

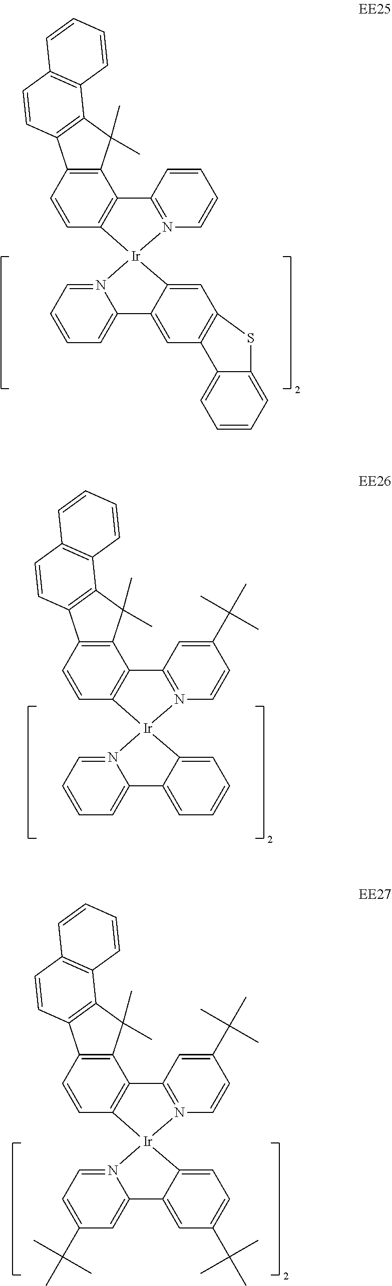

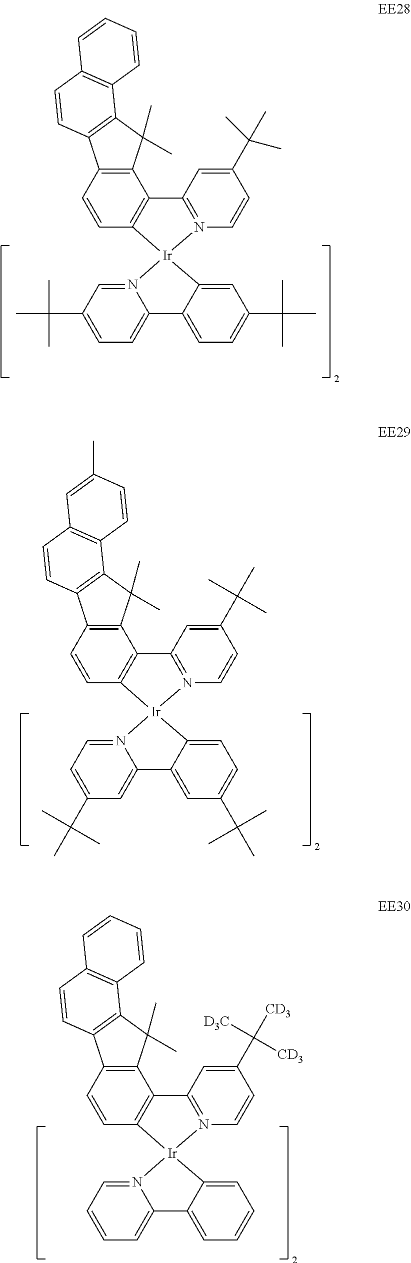

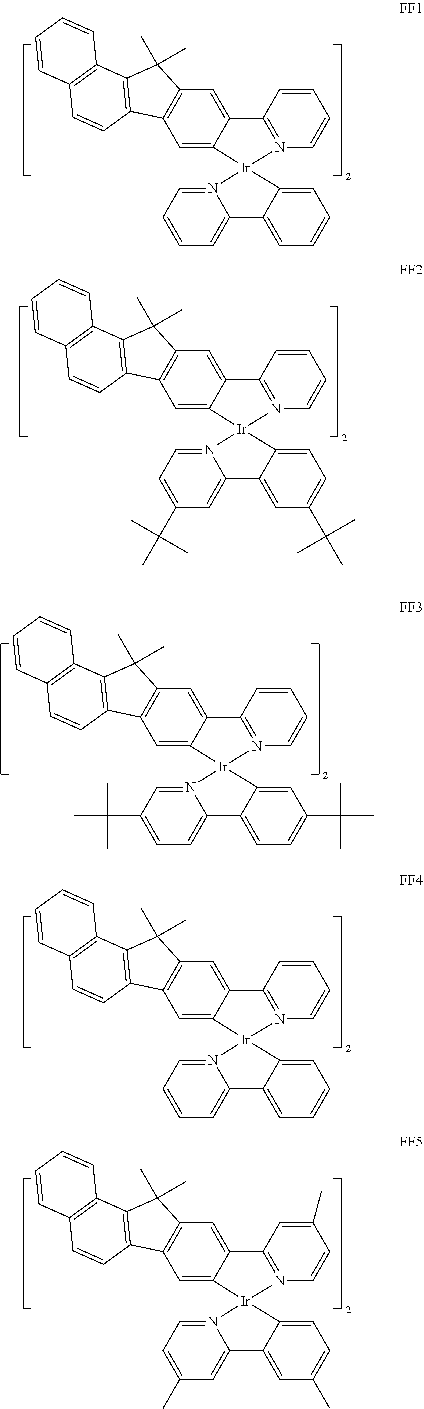

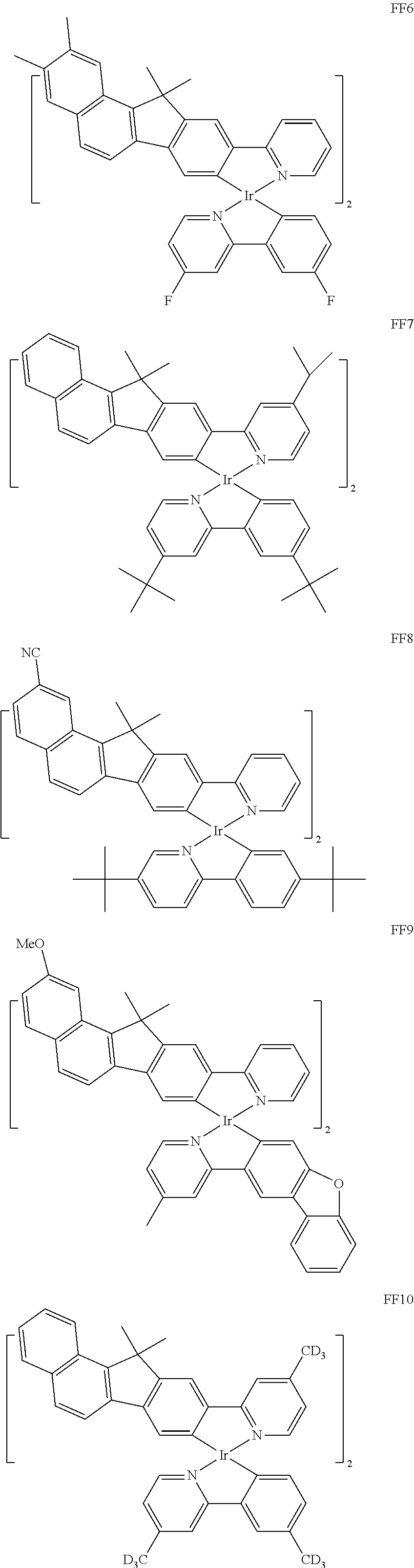

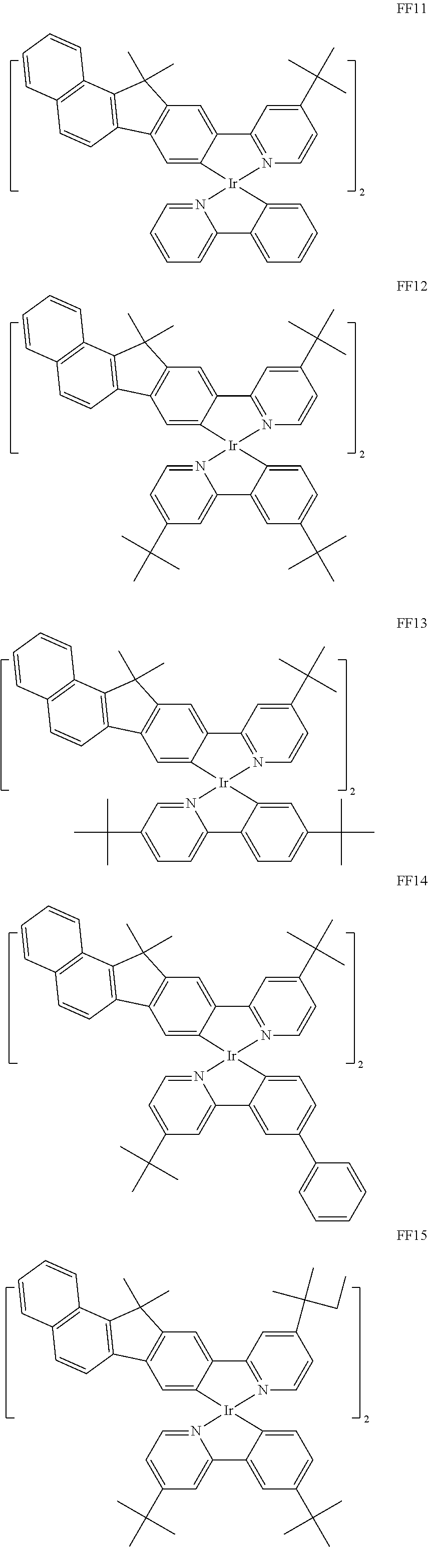

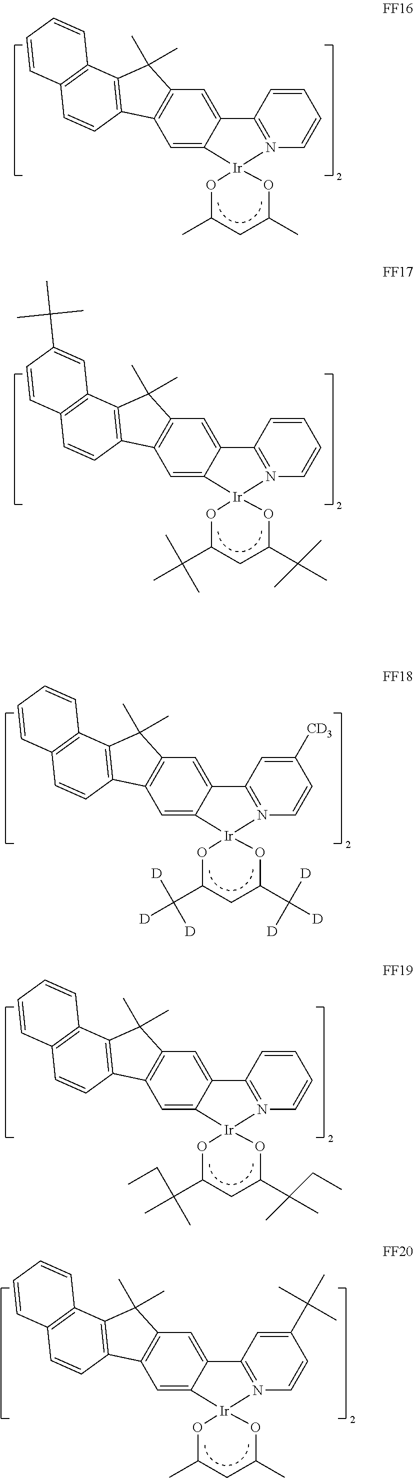

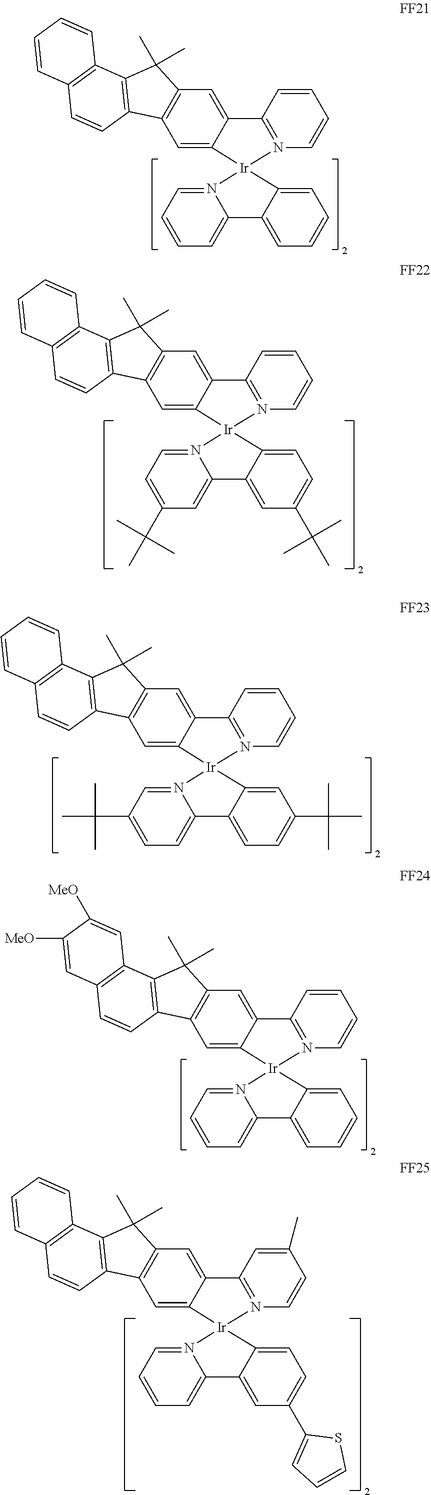

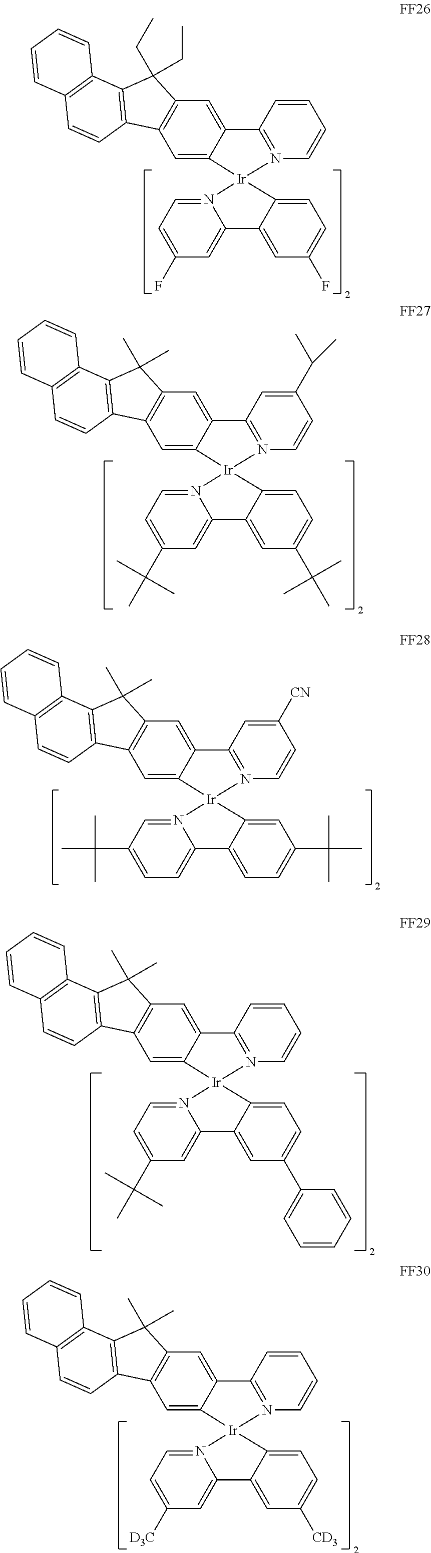

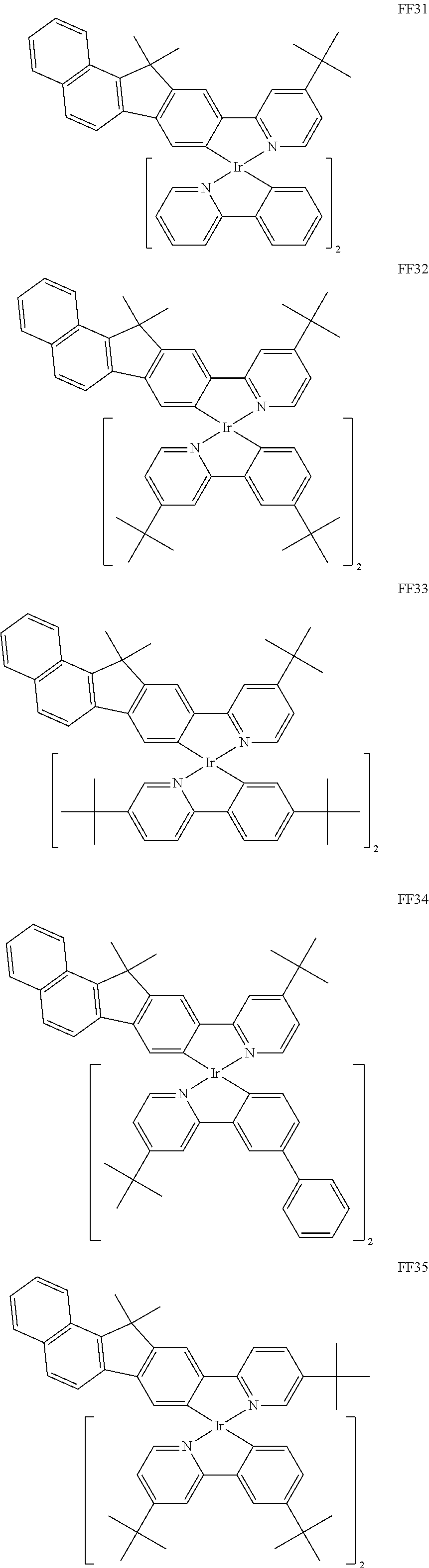

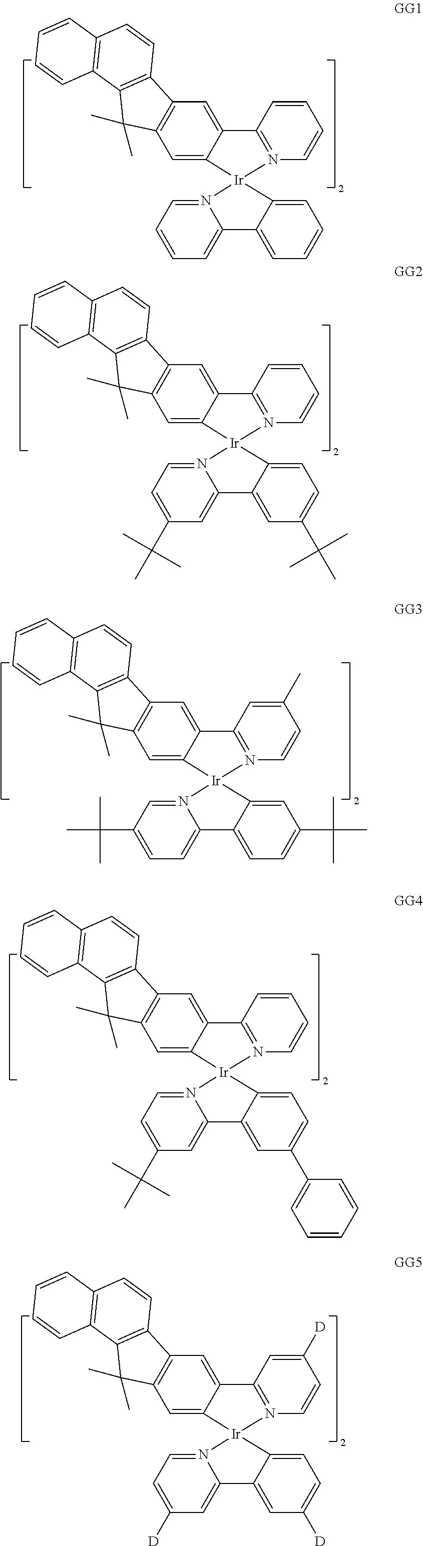

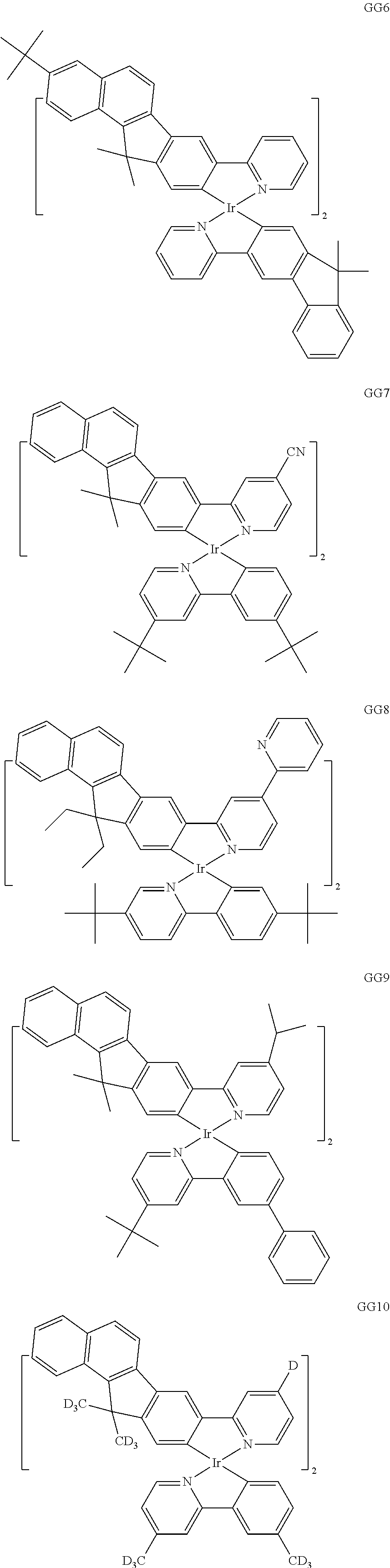

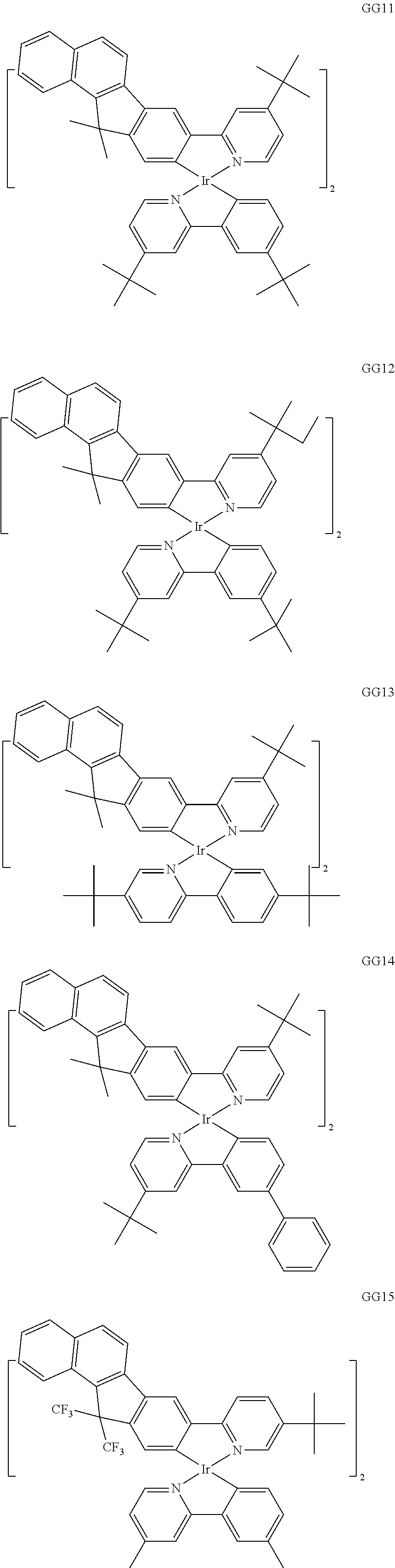

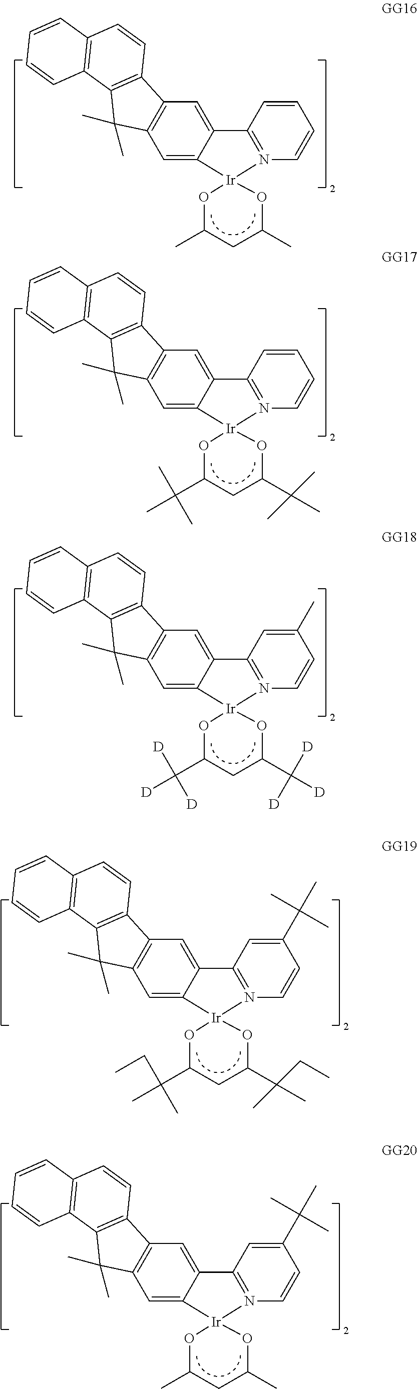

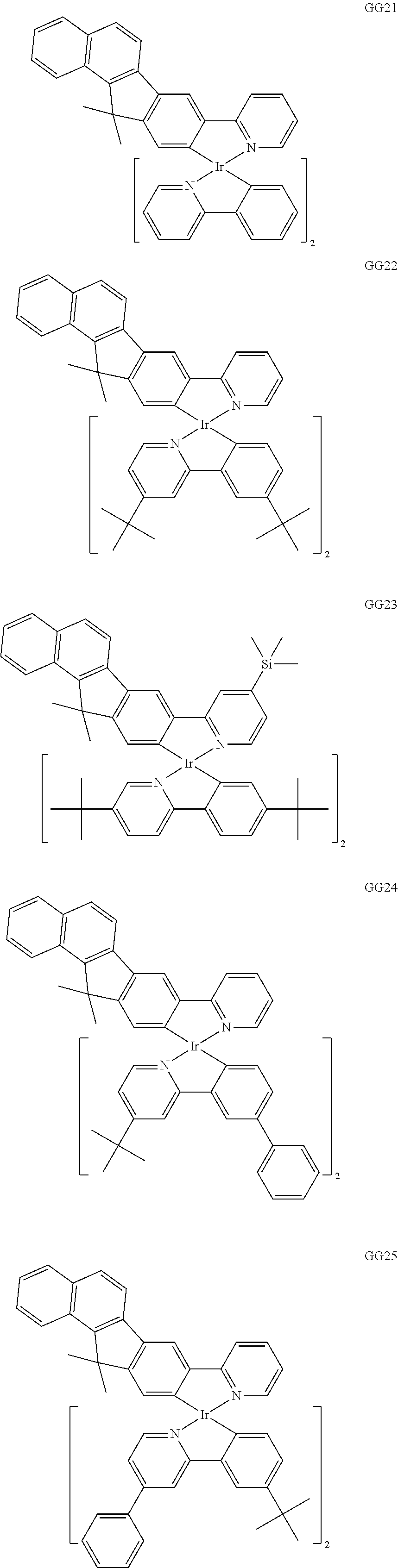

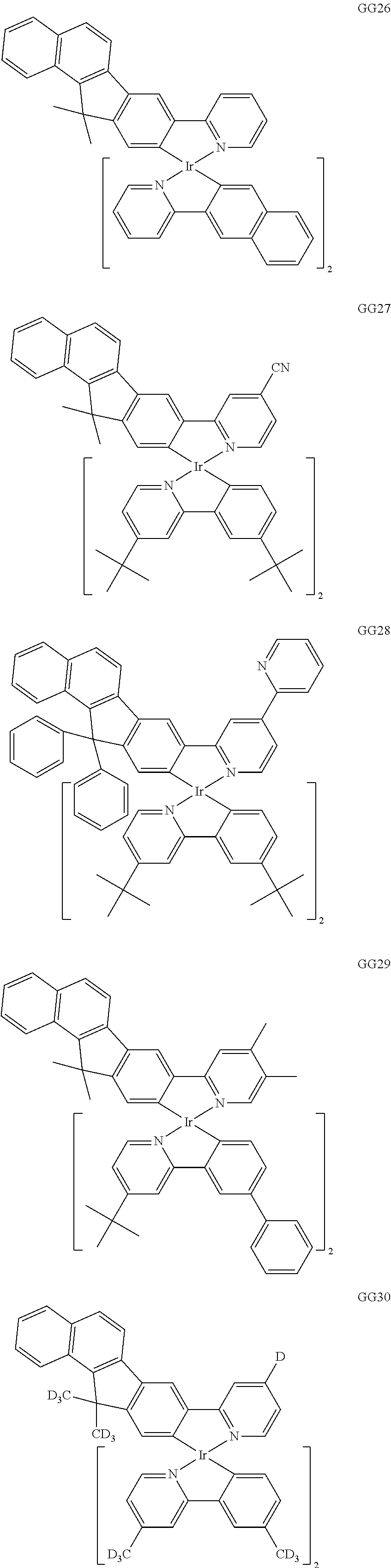

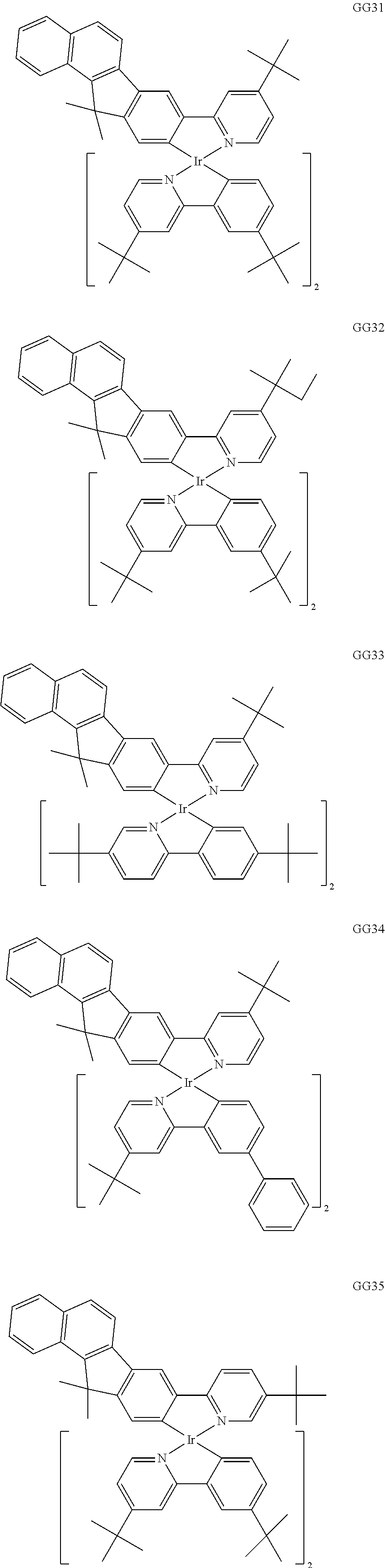

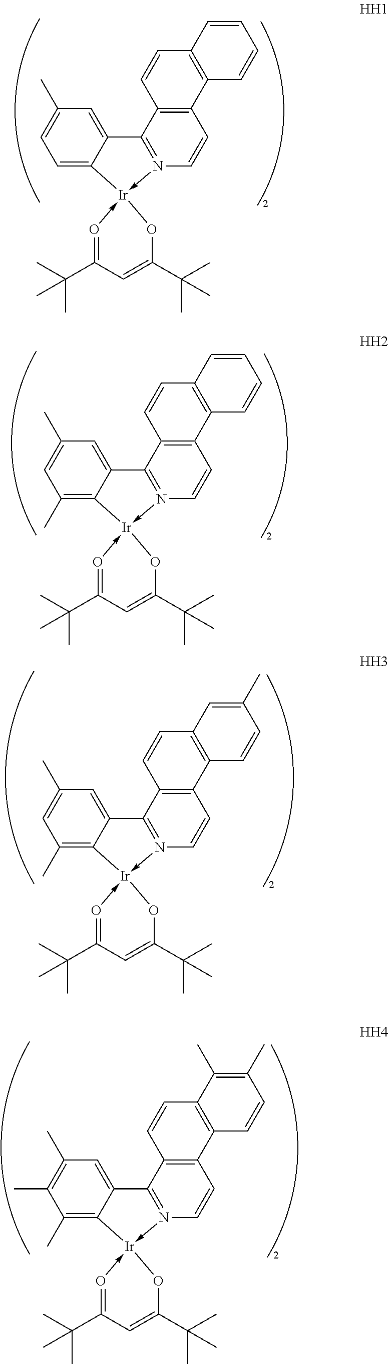

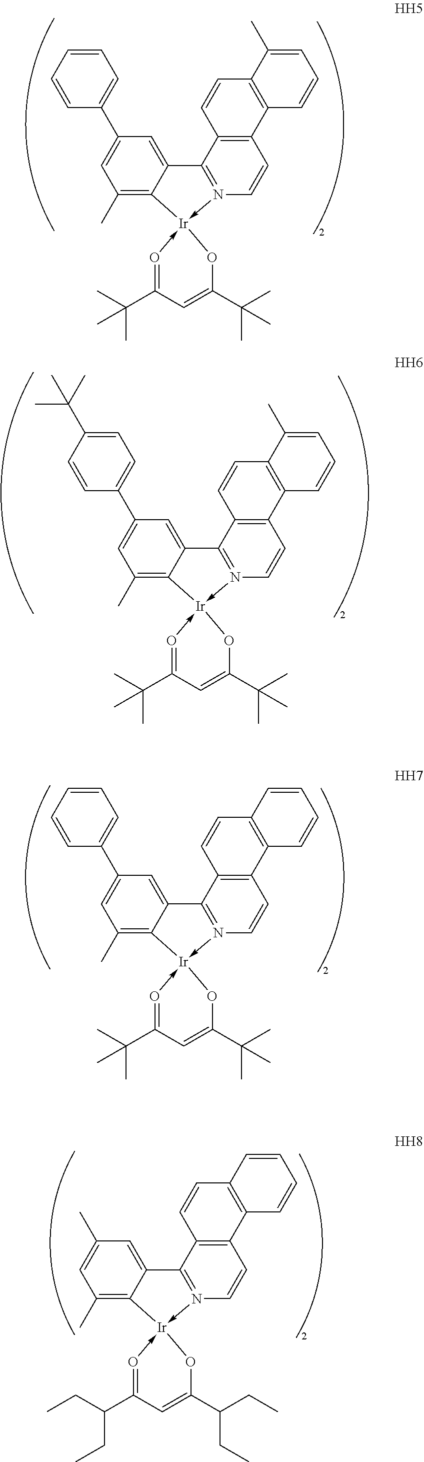

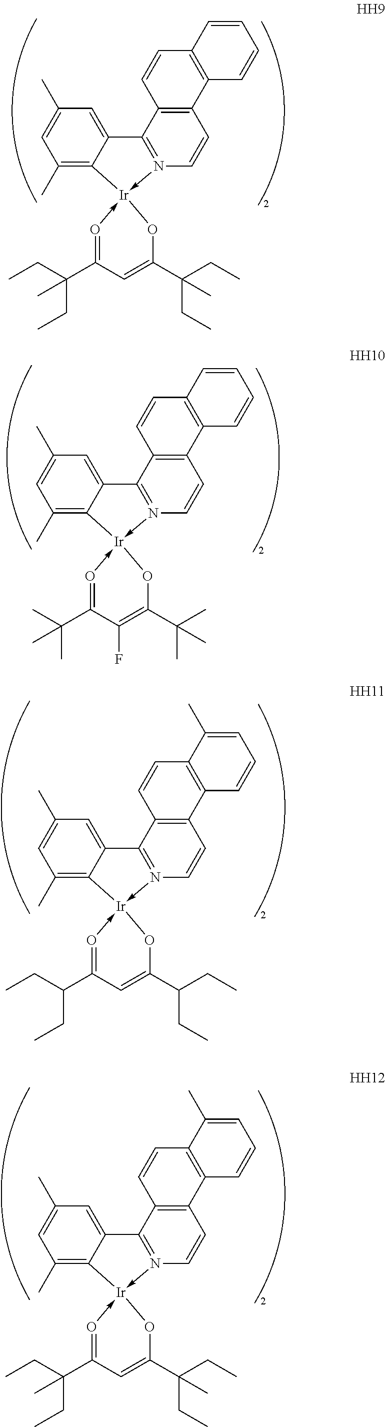

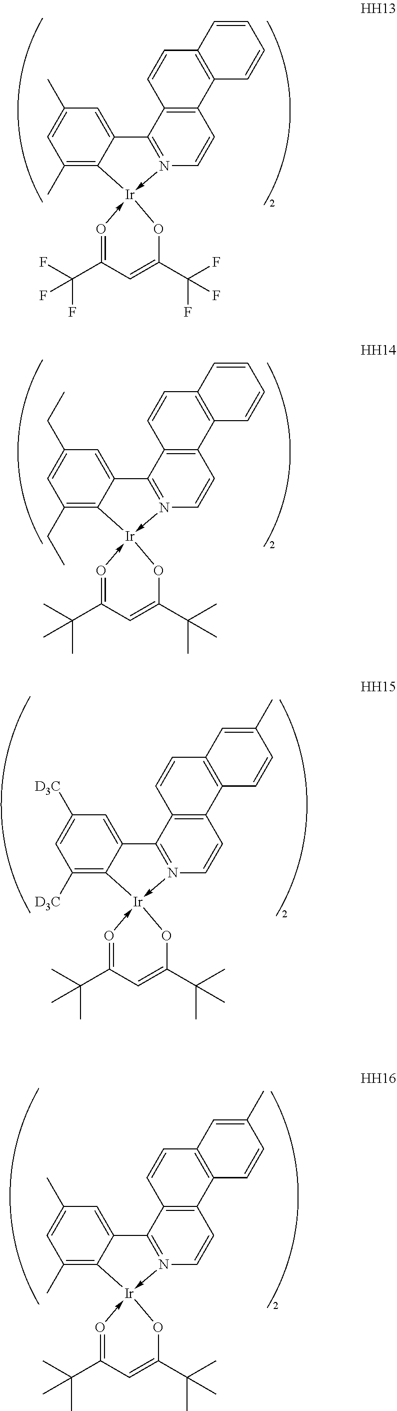

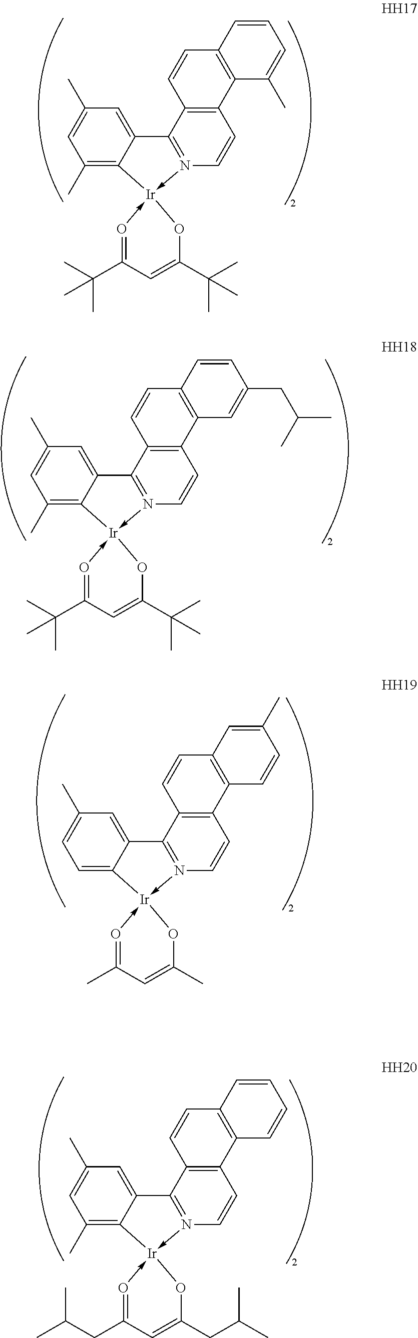

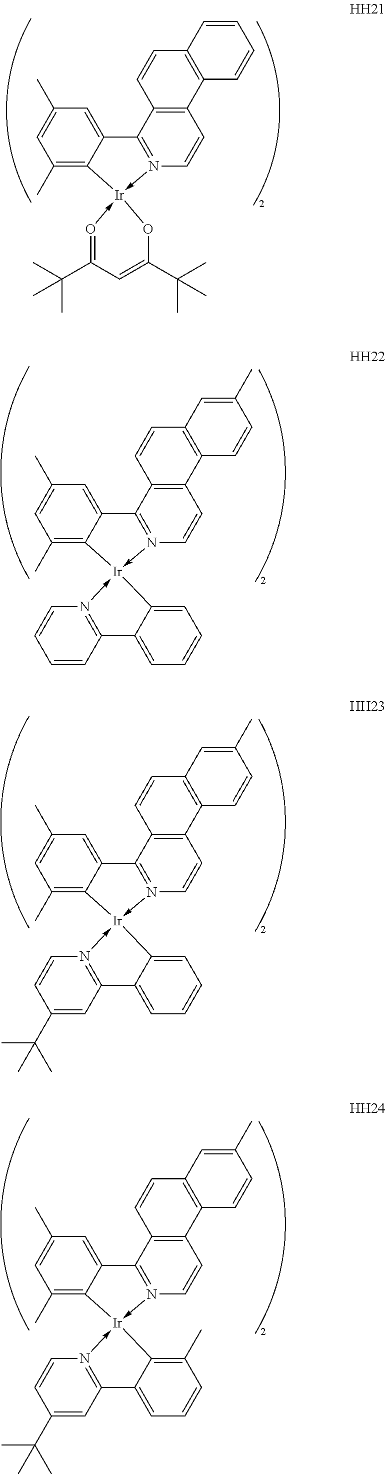

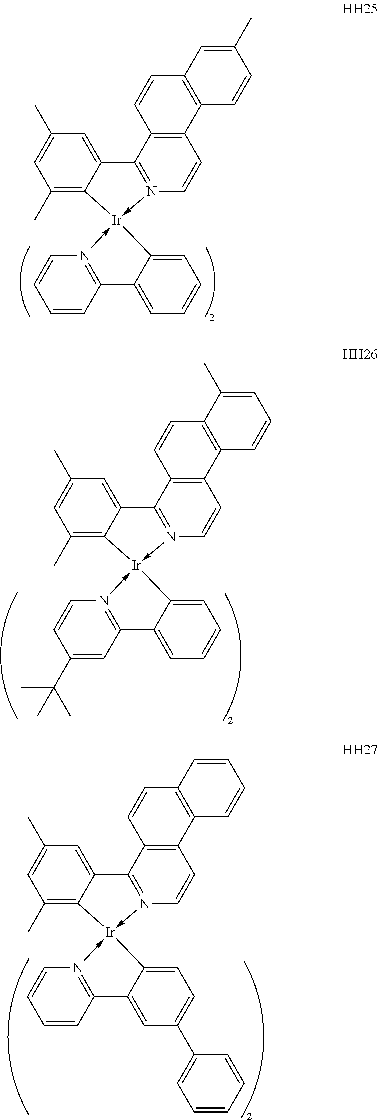

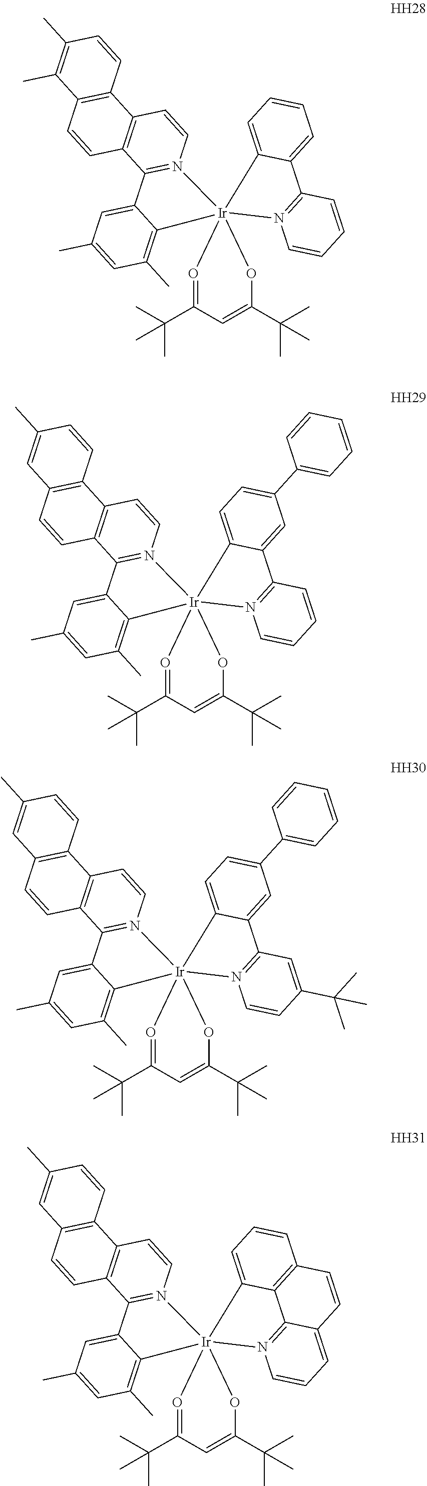

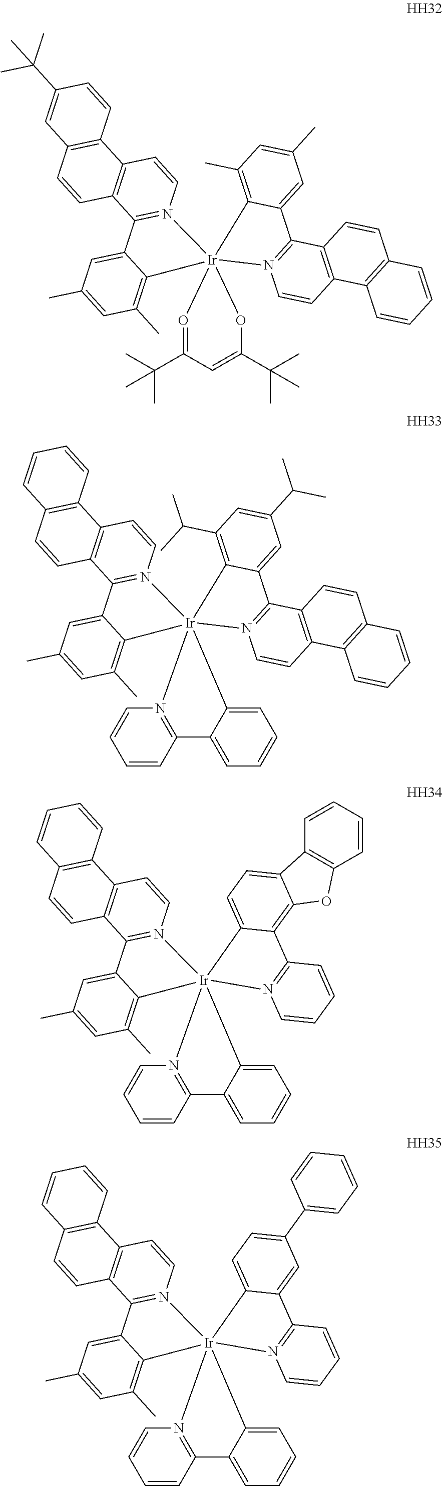

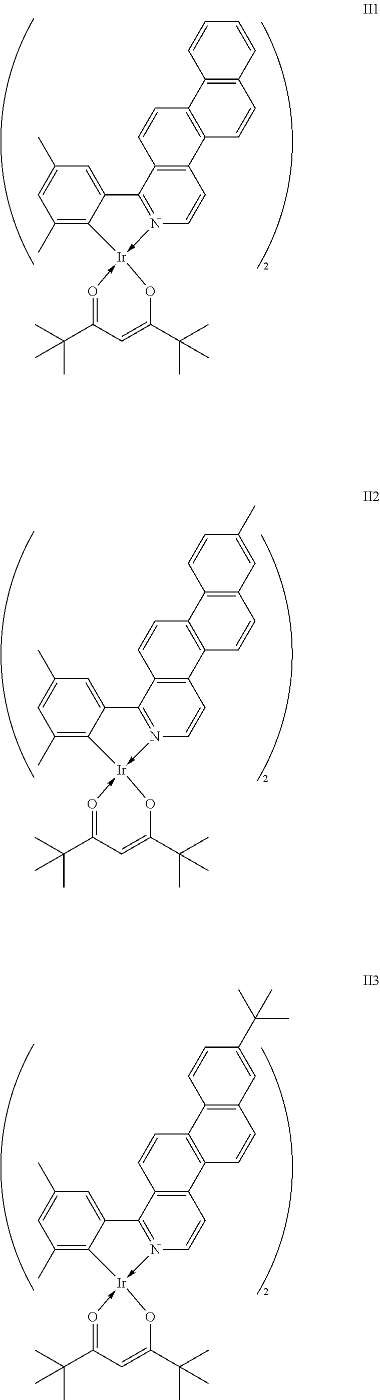

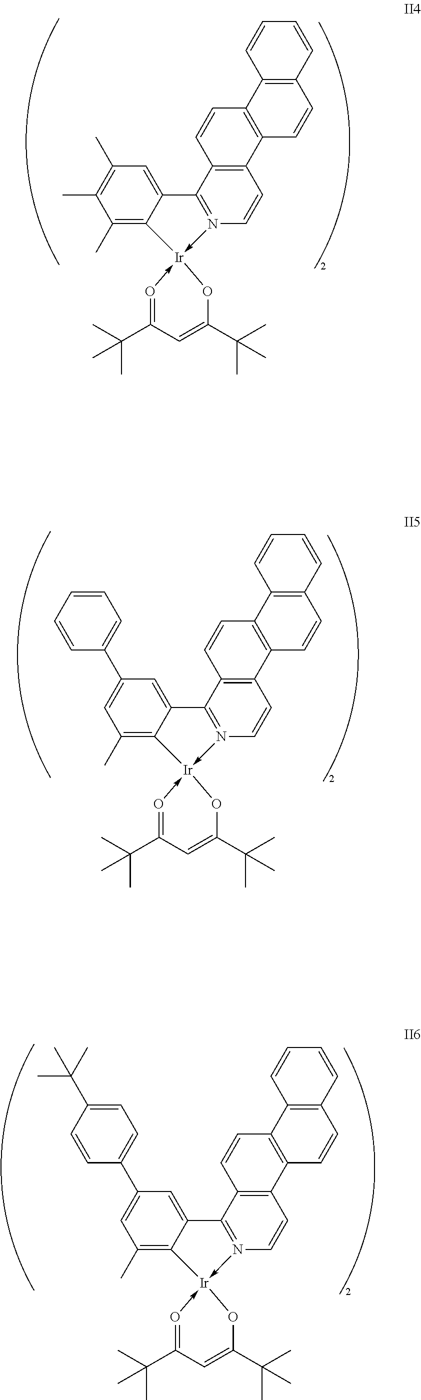

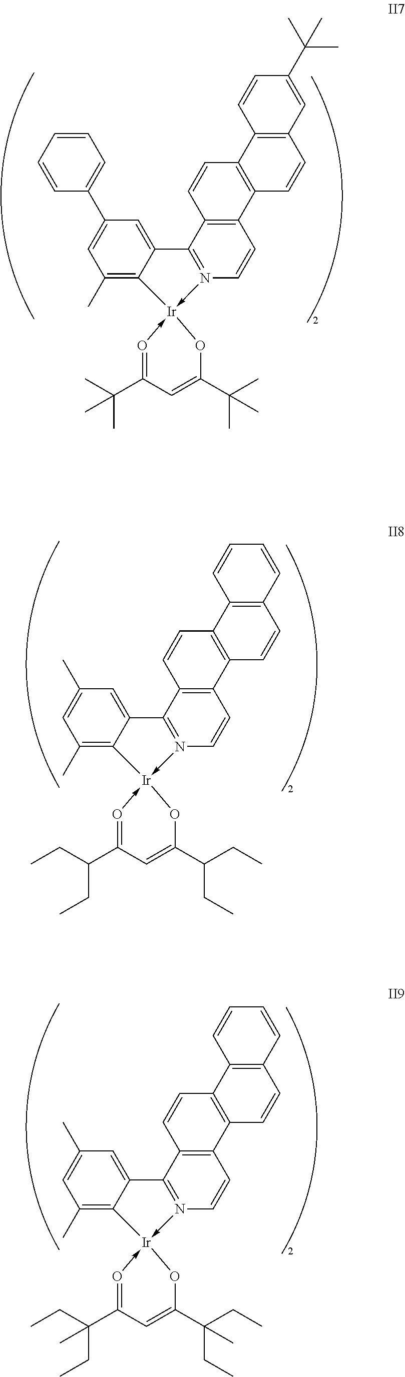

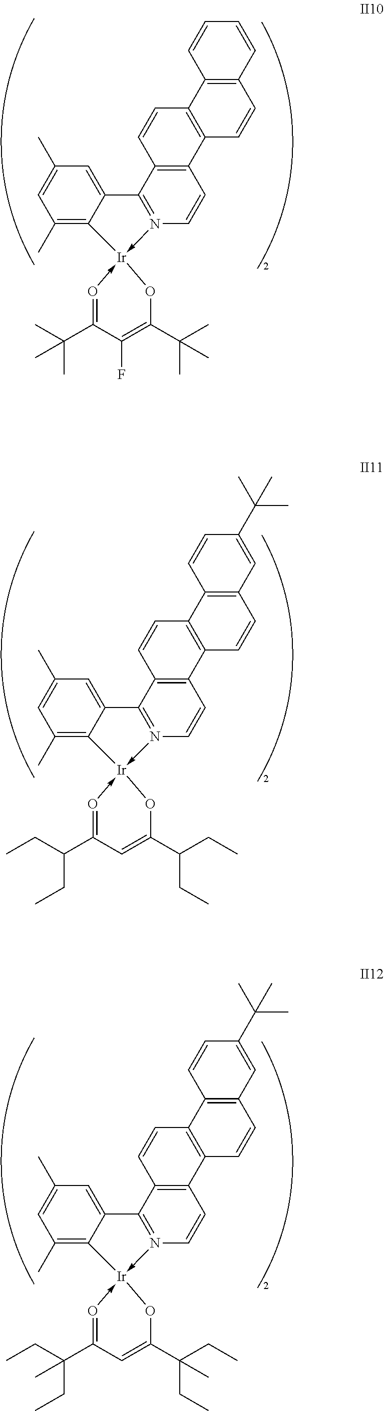

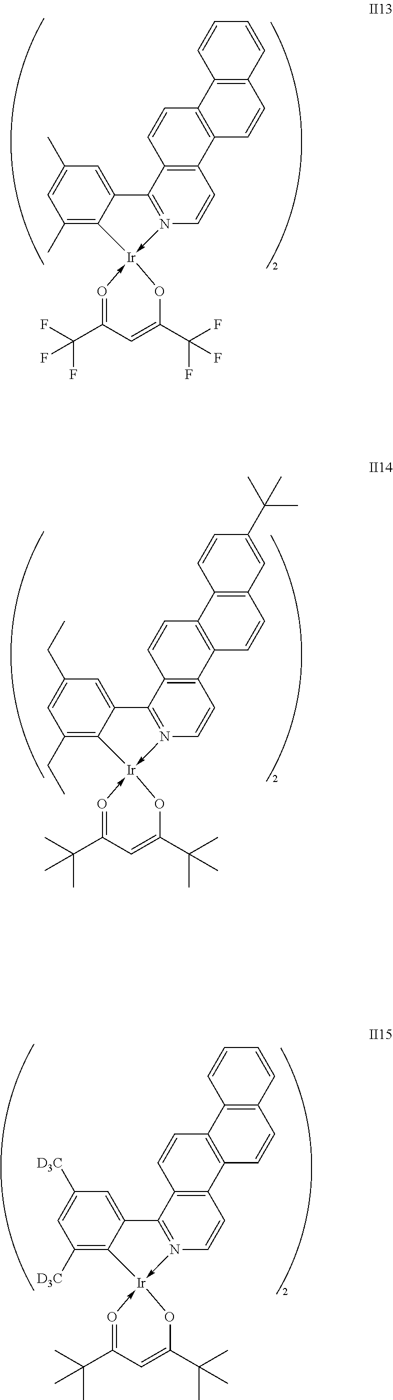

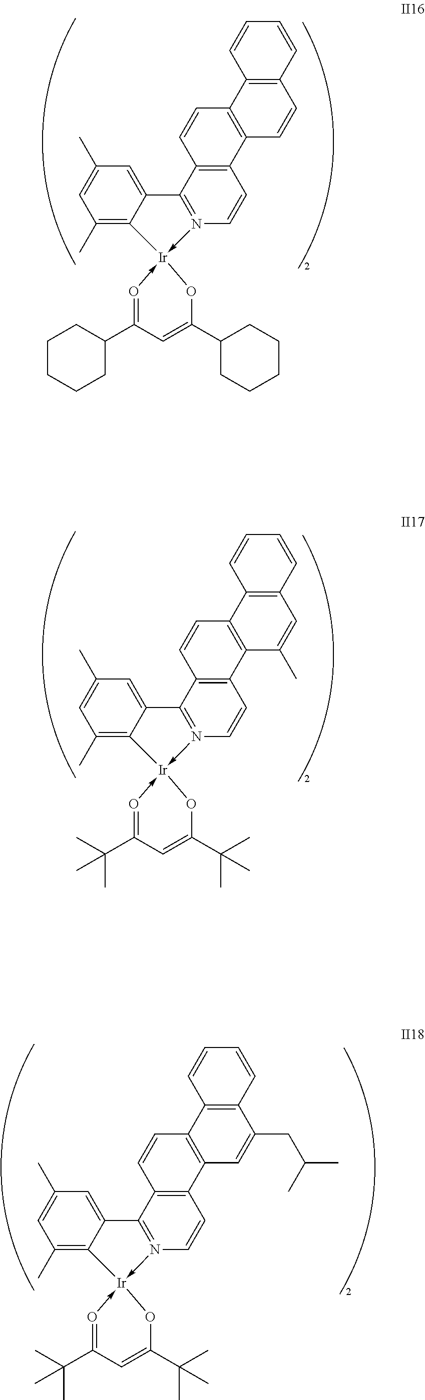

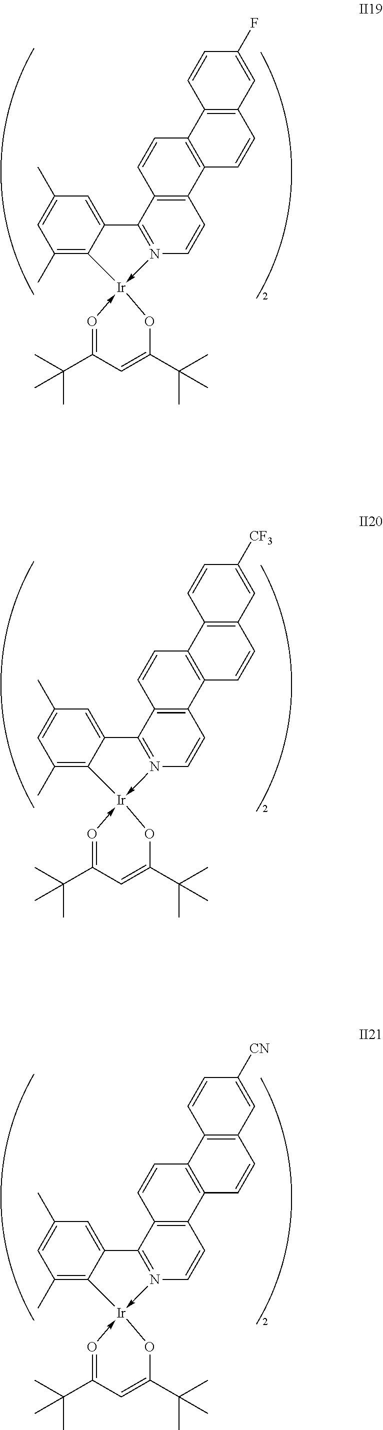

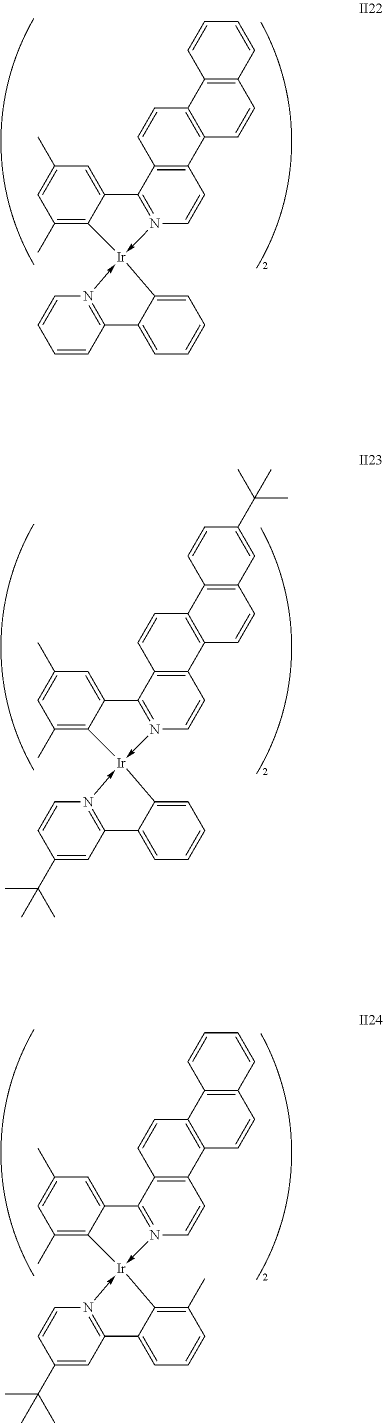

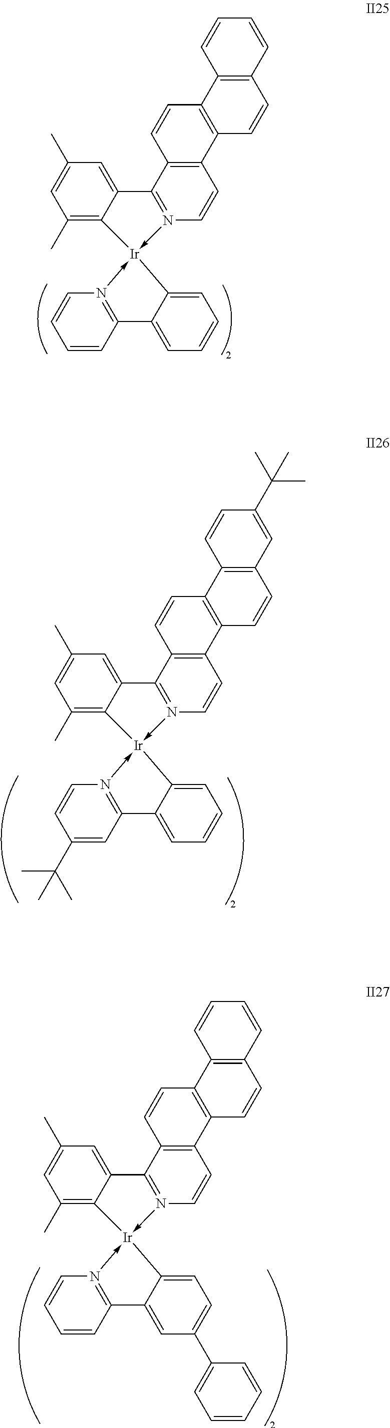

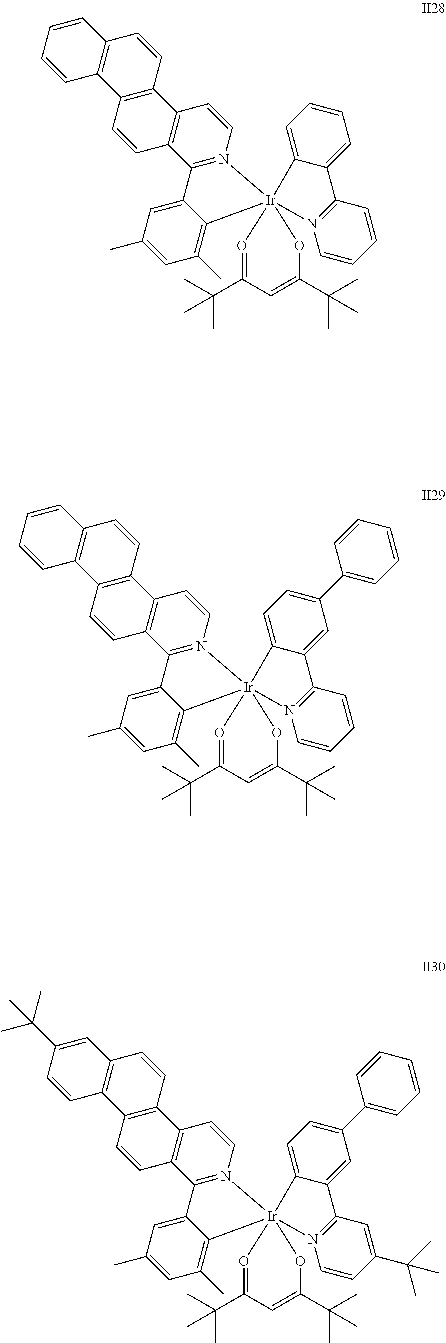

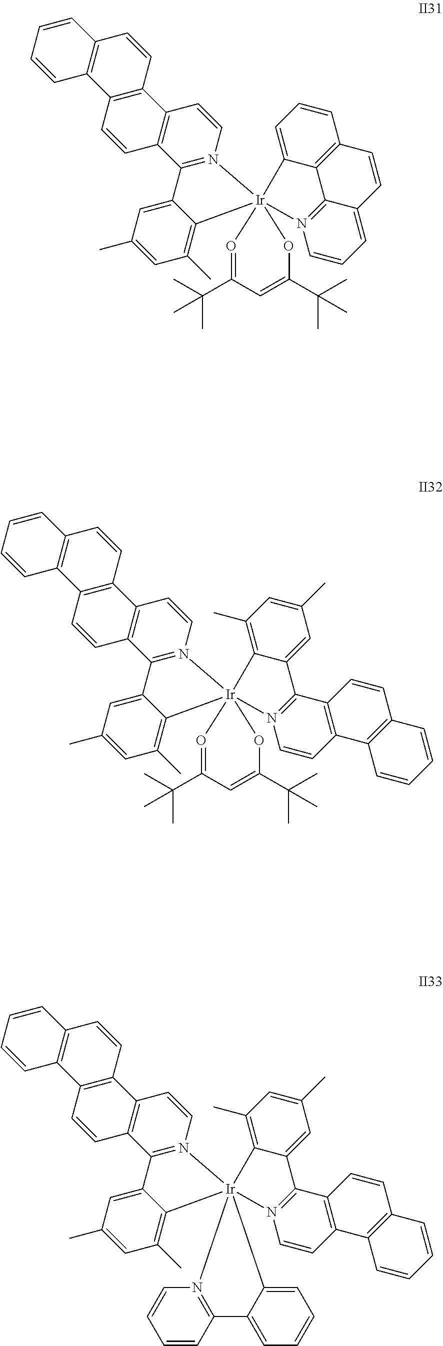

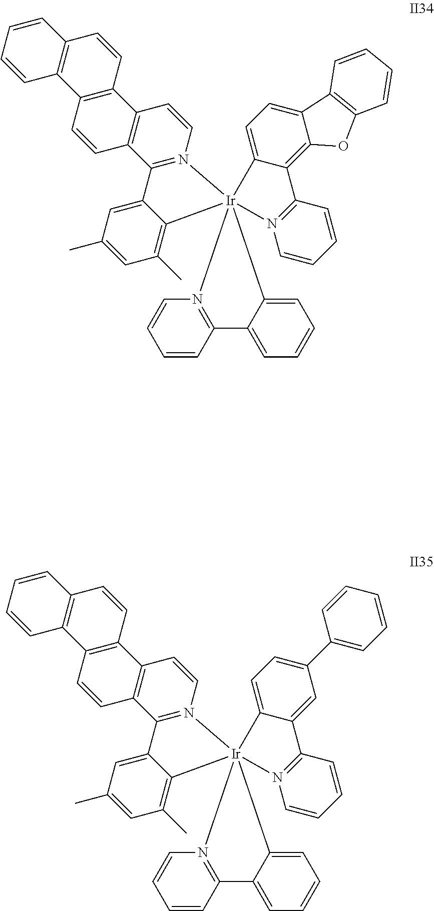

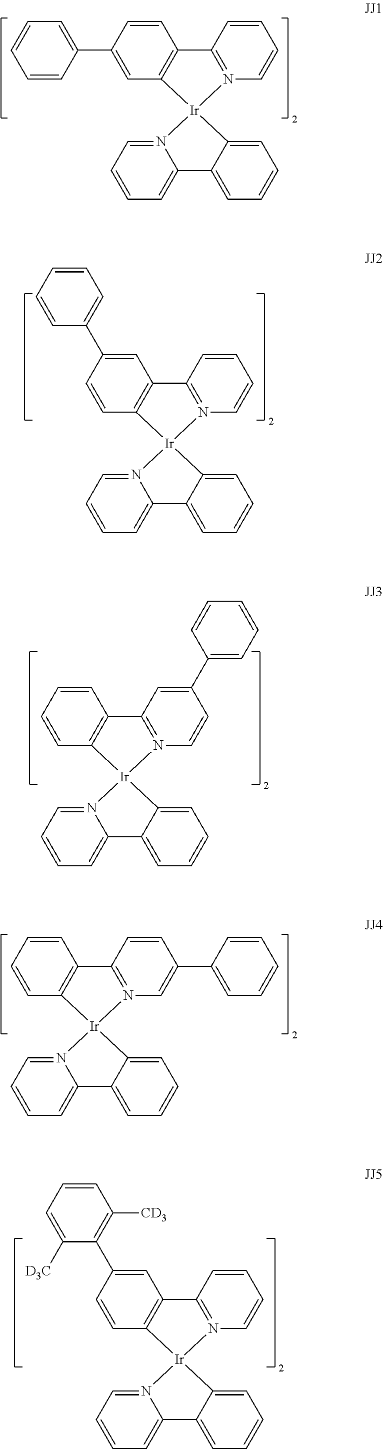

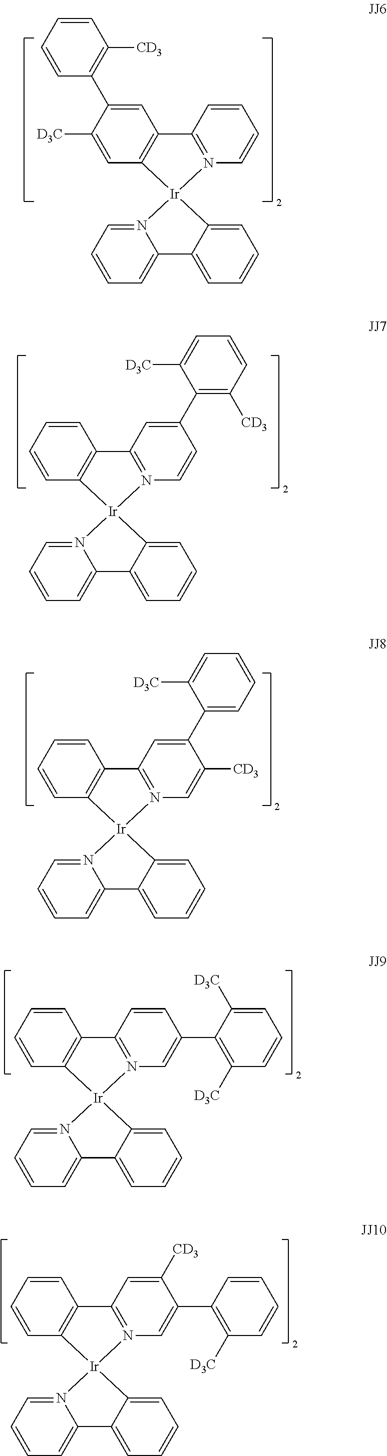

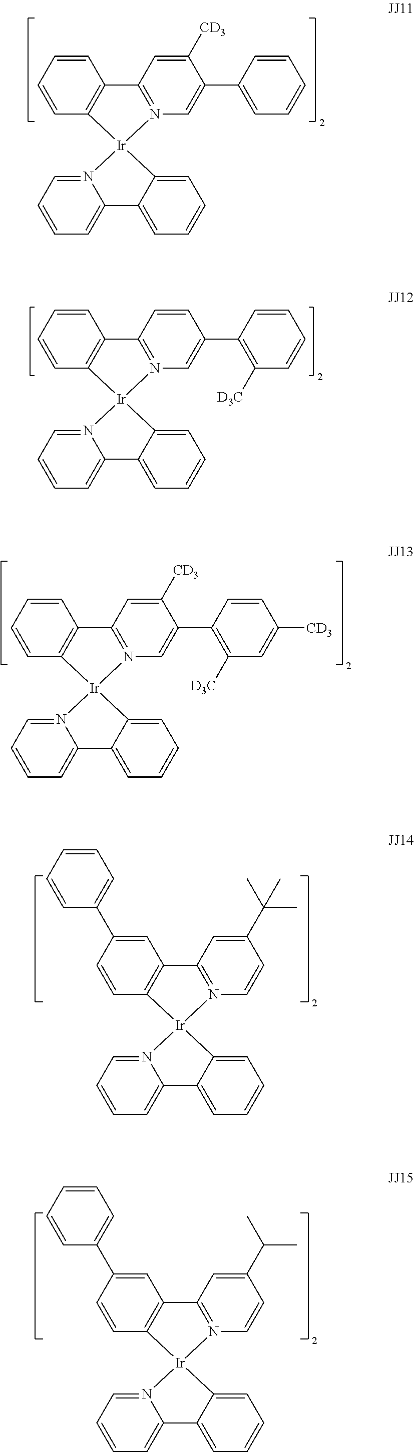

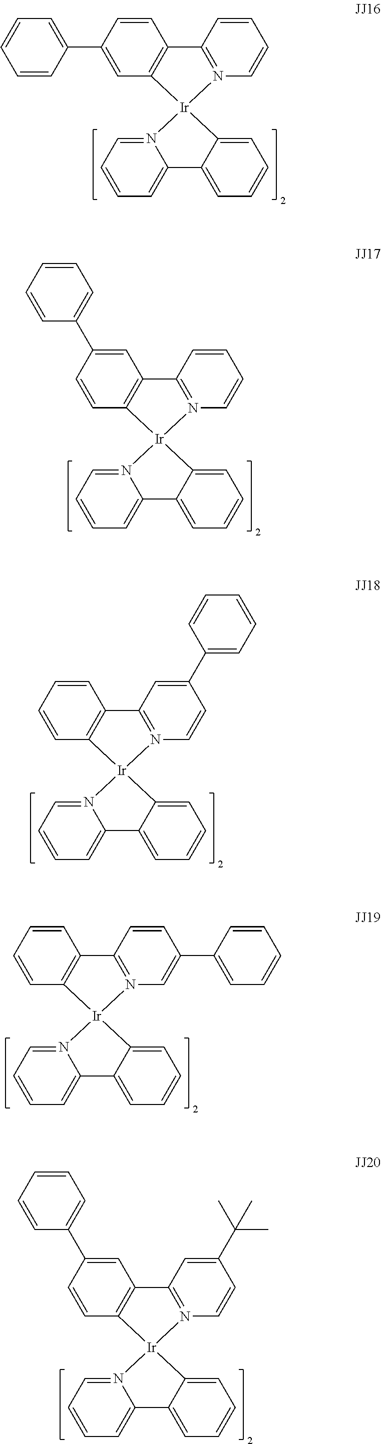

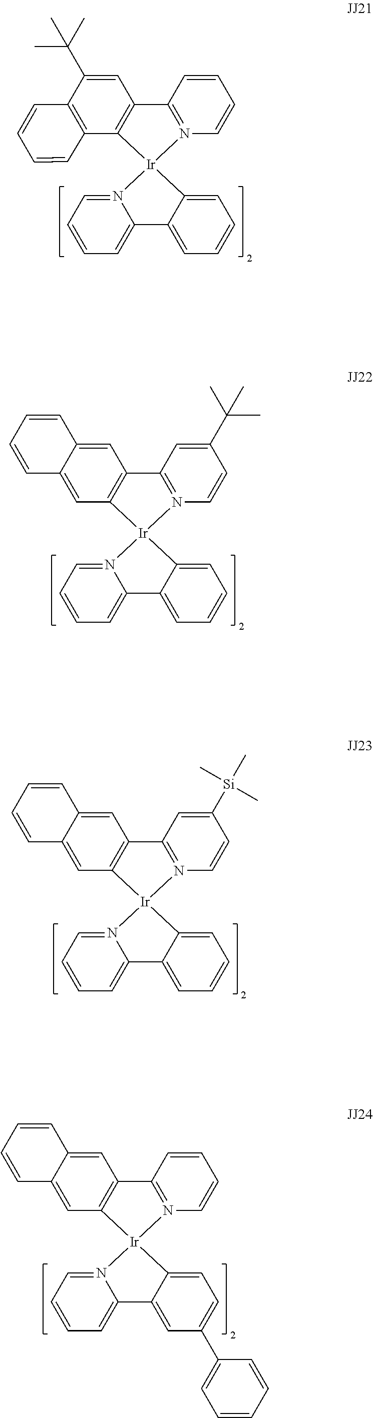

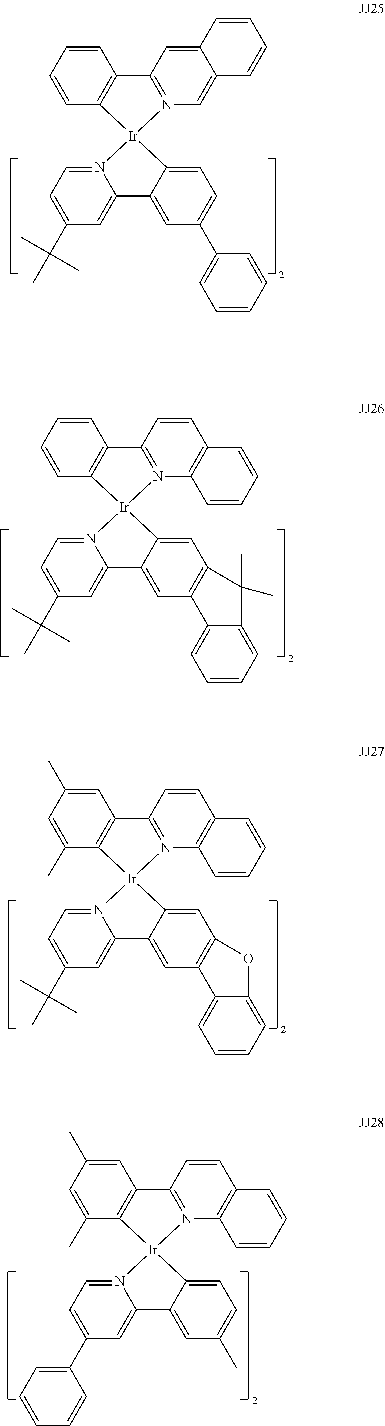

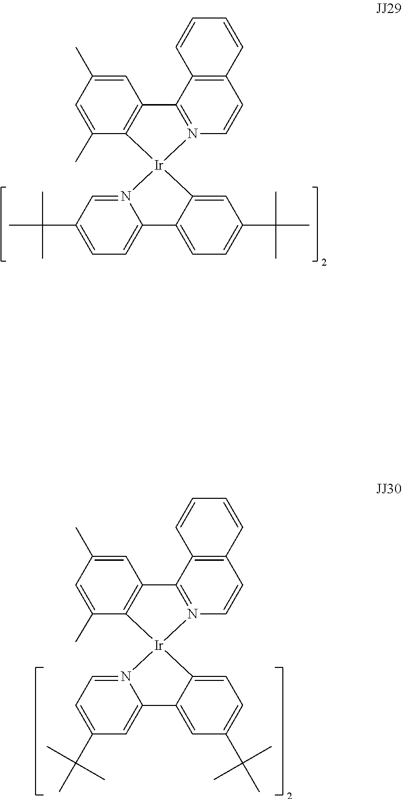

Among the above exemplified compounds, the exemplary compounds belonging to group AA and group BB are compounds each having at least a phenanthrene skeleton in the ligand of the Ir complex. Thus, these are compounds particularly excellent in stability.

Among the above exemplified compounds, the exemplified compounds belonging to group CC are compounds each having at least a triphenylene skeleton in the ligand of the Ir complex. Thus, these are compounds particularly excellent in stability.

Among the exemplified compounds, the exemplified compounds belonging to group DD are compounds each having at least a dibenzofuran skeleton or a dibenzothiophene skeleton in the ligand of the Ir complex. Since these compounds contain oxygen atoms or sulfur atoms in the ligands, the abundant lone-pair electrons possessed by these atoms can further promote carrier transfer. Thus, the compounds are particularly easy to adjust the carrier balance.

Among the above exemplified compounds, the exemplified compounds belonging to group EE, group FF, and group GG are compounds each having at least a benzofluorene skeleton in the ligand of the Ir complex. These compounds each further contain a substituent at the 9-position of the fluorene. The fluorene ring has the substituent in a direction perpendicular to the in-plane direction of the fluorene ring; thus, it is possible to particularly inhibit the fused rings from overlapping each other. For this reason, these compounds are particularly excellent in sublimability.

Among the exemplified compounds, the exemplified compounds belonging to group HH are compounds each having at least a benzoisoquinoline skeleton in the ligand of the Ir complex. These compounds contain nitrogen atoms in the ligands; hence, the carrier transfer can be promoted because of the lone-pair electrons and high electronegativity of these atoms. Thus, the compounds are particularly easy to adjust the carrier balance.

Among the above exemplified compounds, the exemplified compounds belonging to group II are compounds each having at least a naphthoisoquinoline skeleton in the ligand of the Ir complex. These compounds contain nitrogen atoms in the fused rings; hence, the carrier transfer can be promoted because of the lone-pair electrons and high electronegativity of these atoms. Thus, the compounds are particularly easy to adjust the carrier balance.

Among the above exemplified compounds, the exemplified compounds belonging to group JJ are compounds each represented by any of general formulae [Ir-1] to [Ir-4]. These compounds have excellent sublimability, particularly because of their small molecular weights.

### (3) First to Third Organic Compounds

The first and second organic compounds preferably have a highly planar structure. Specifically, each of the first and second organic compounds preferably has a fused-ring structure having three or more rings, and more preferably has at least any one of a dibenzothiophene skeleton, a dibenzofuran skeleton, a triphenylene skeleton, and a phenanthrene skeleton. When the compound has at least one of the above skeletons, highly planar structures can easily approach each other, making it possible to further promote carrier transfer.

In particular, compounds each having a dibenzothiophene skeleton or a dibenzofuran skeleton contain oxygen atoms or sulfur atoms and thus can enhance the carrier transportability because of the abundant lone-pair electrons possessed by these atoms. Thus, the compounds are particularly easy to adjust the carrier balance. Moreover, the compound having a triphenylene skeleton or a phenanthrene skeleton is a compound having excellent durability.

The third organic compound is preferably a compound having excellent electron-trapping property. Specifically, the compound has at least any one of an azine skeleton, a thioxanthone skeleton, and a xanthone skeleton. A compound having at least one of the above skeletons has excellent electron-withdrawing properties and can lower the LUMO level (further from the vacuum level), thereby enhancing the electron-trapping property.

Specific examples of the first to third organic compounds are illustrated below. However, the present invention is not limited to these.

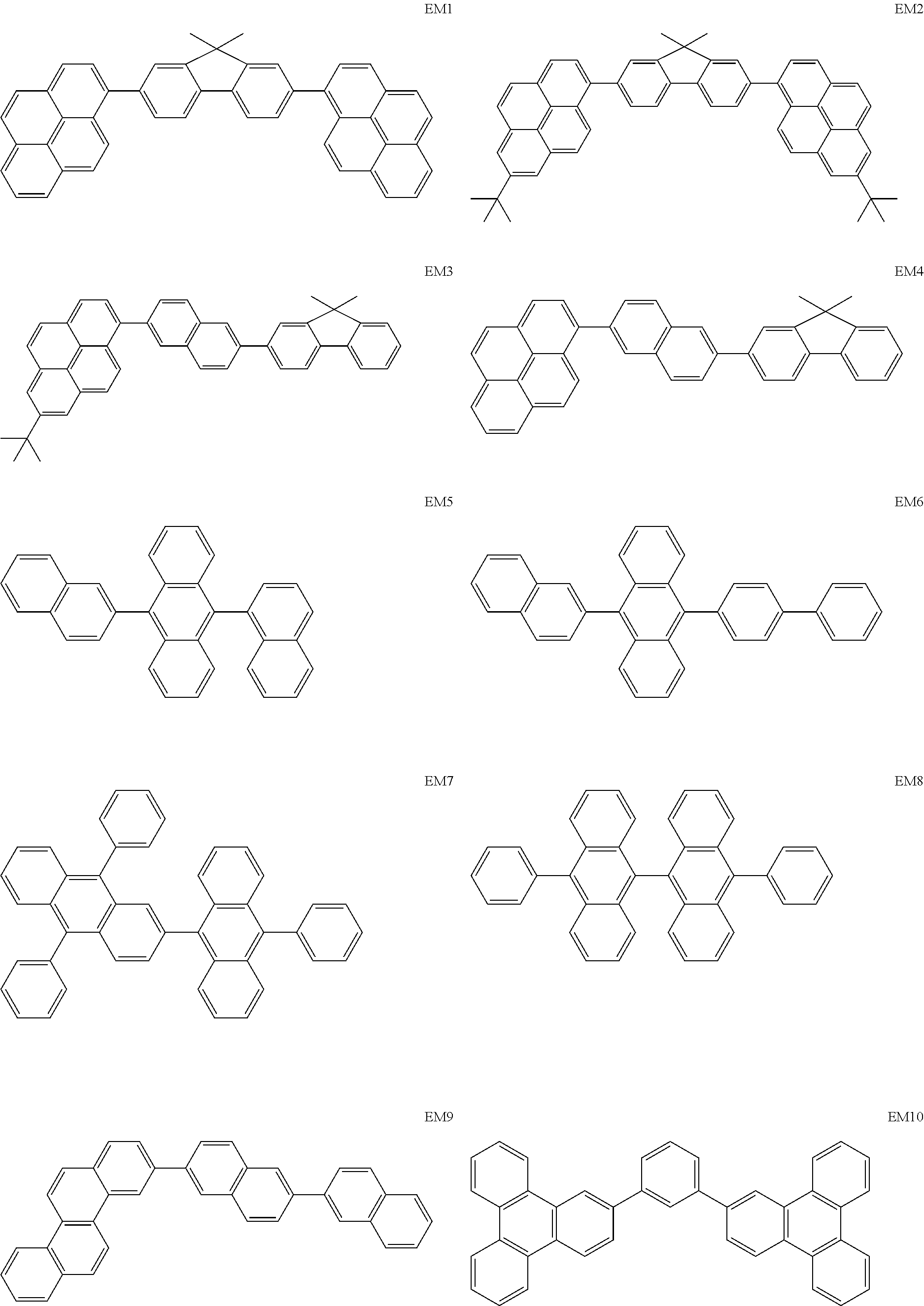

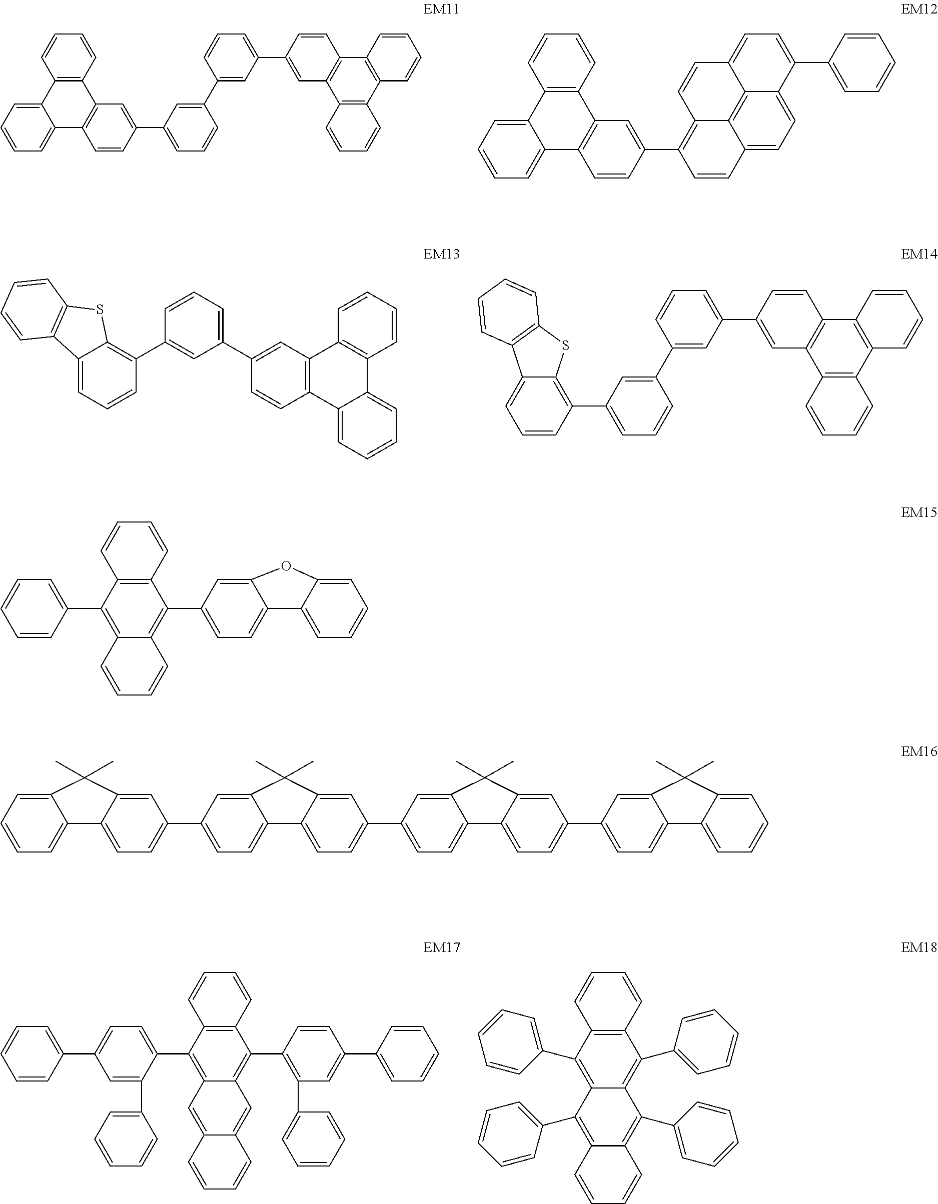

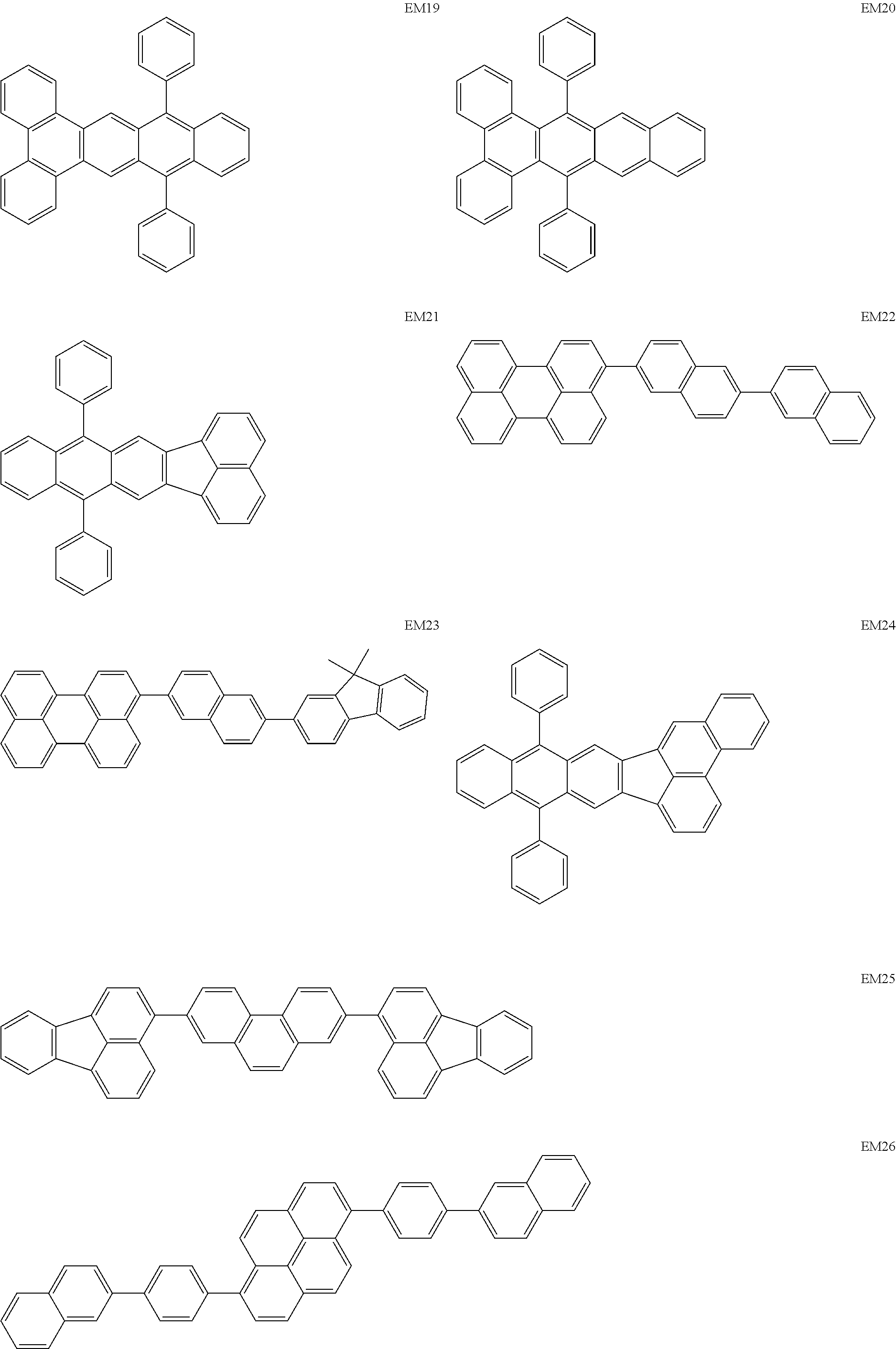

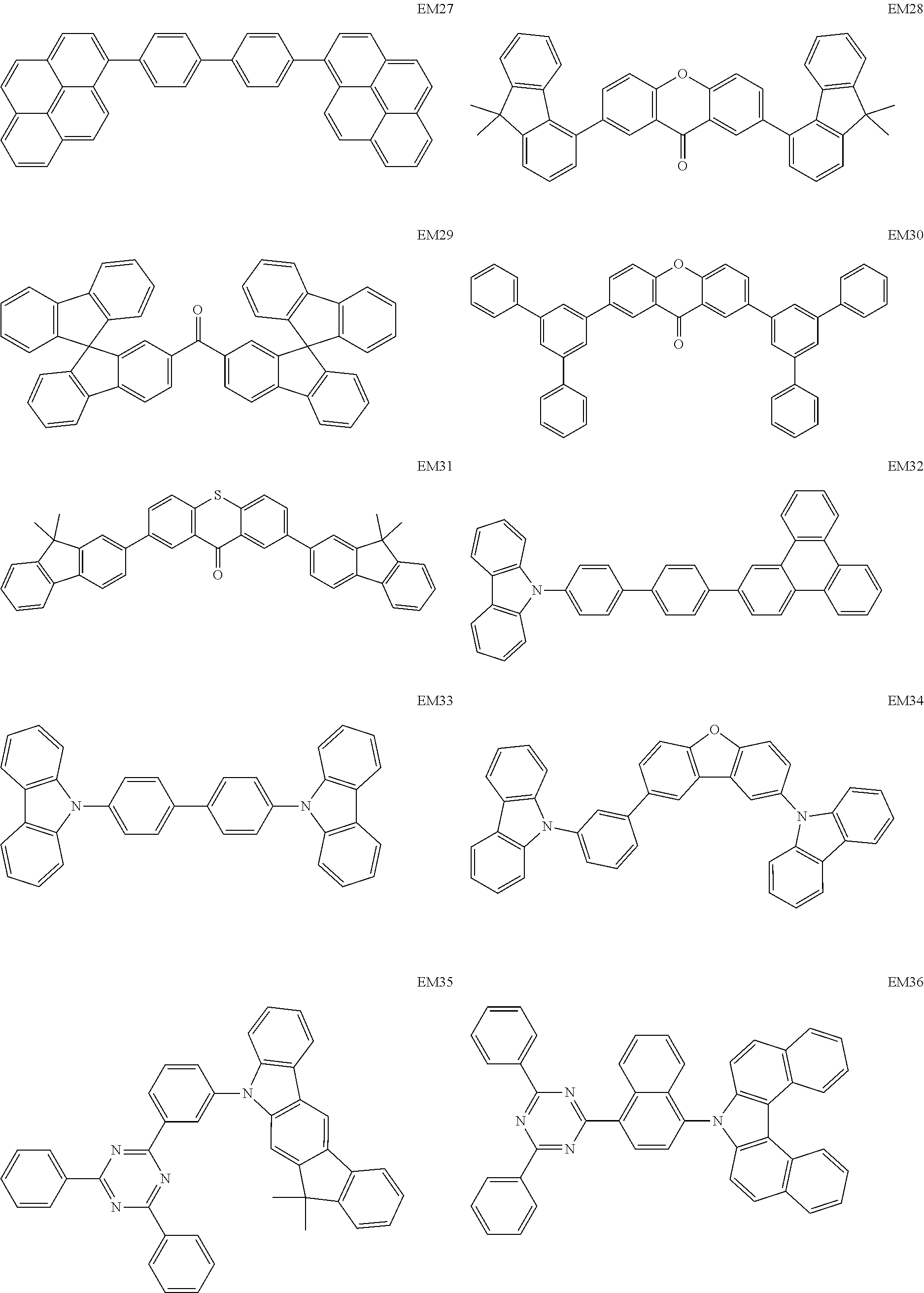

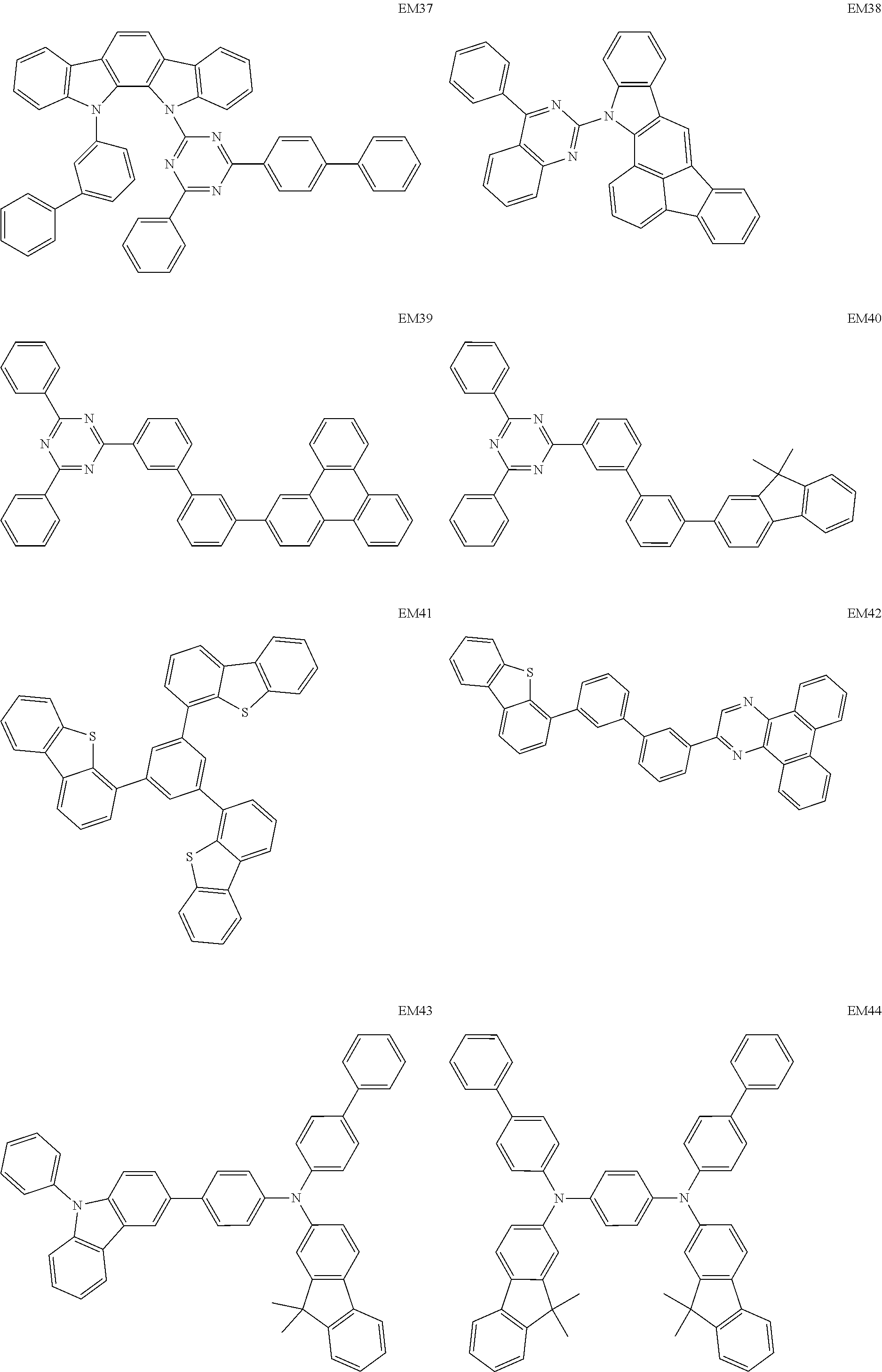

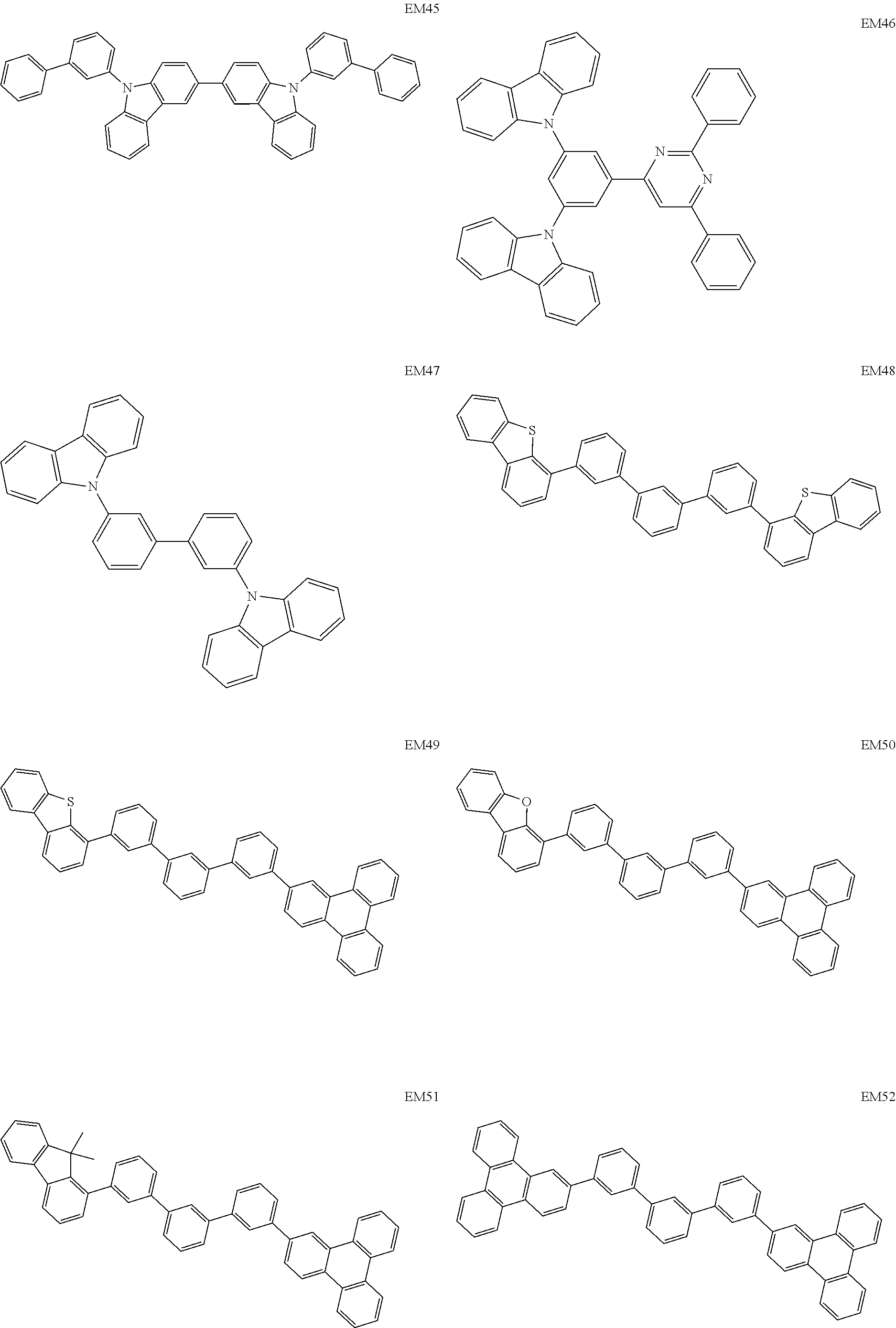

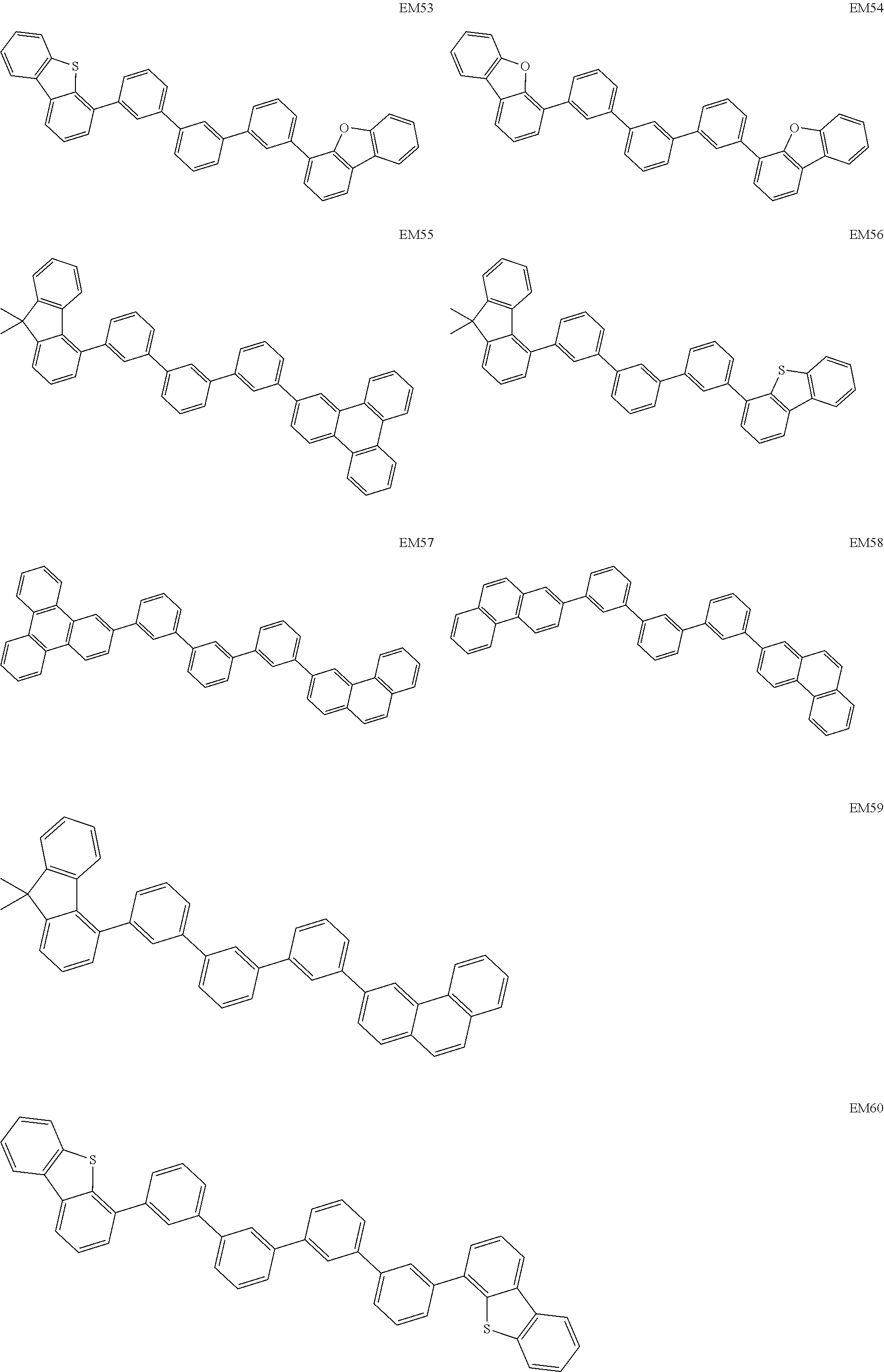

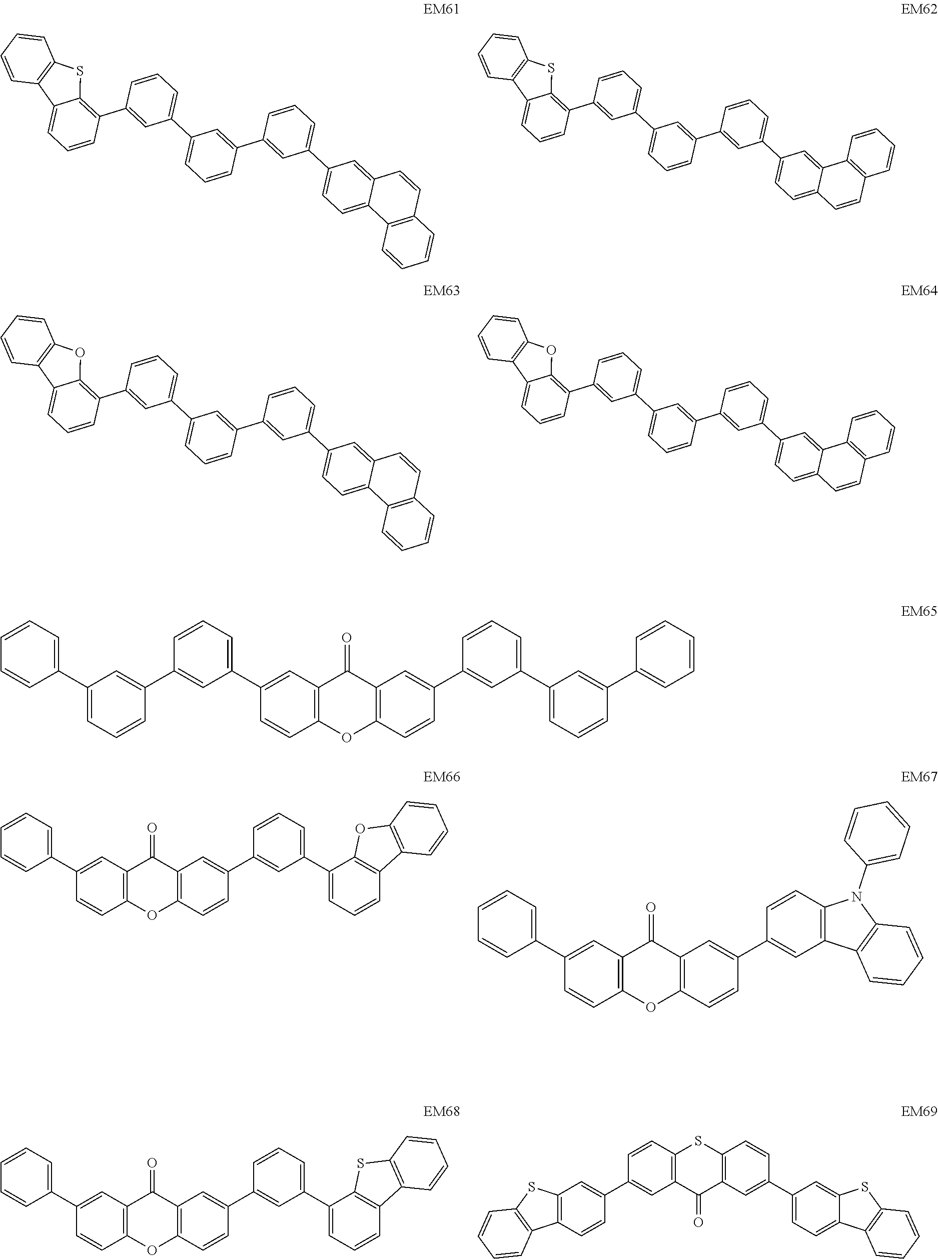

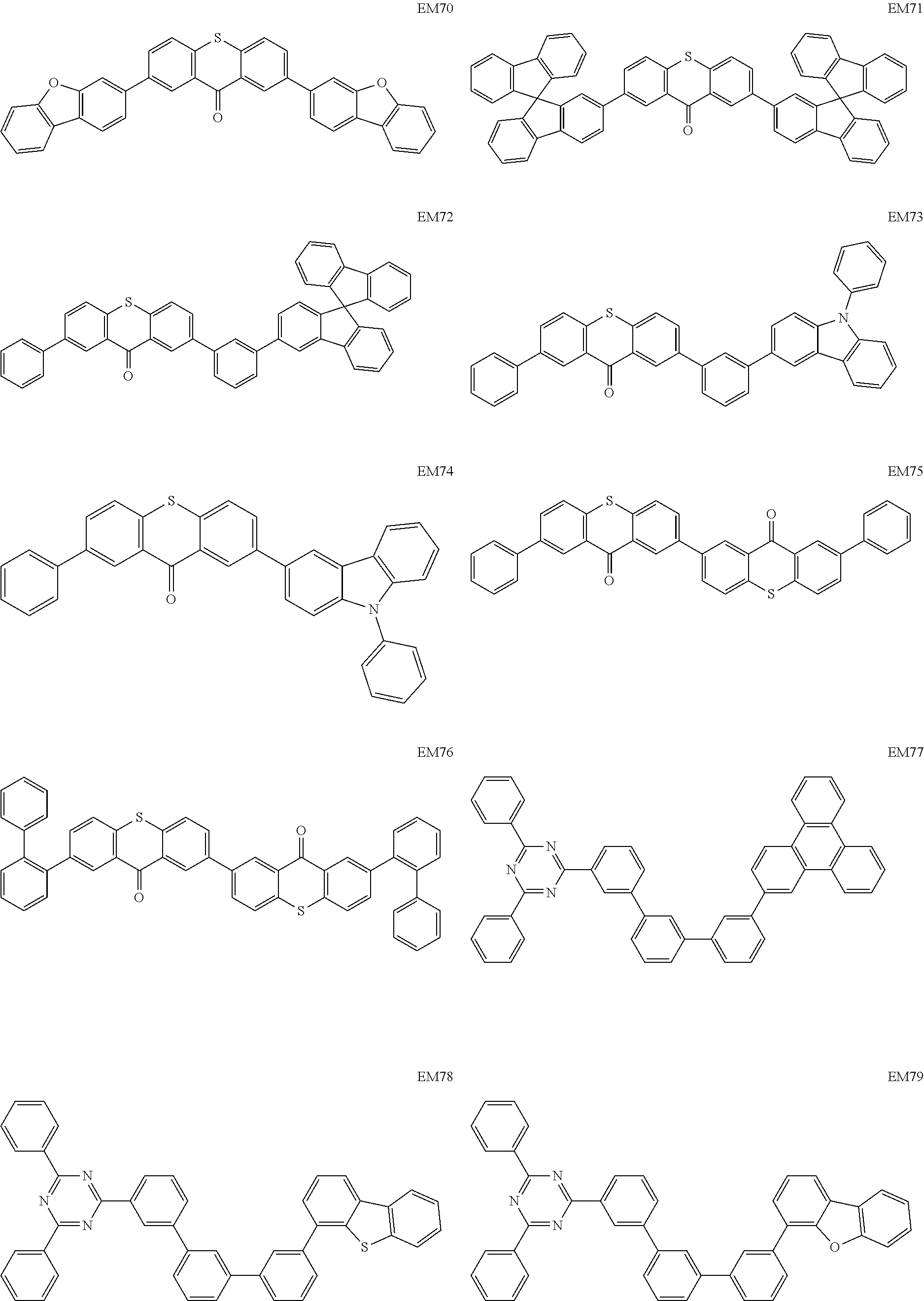

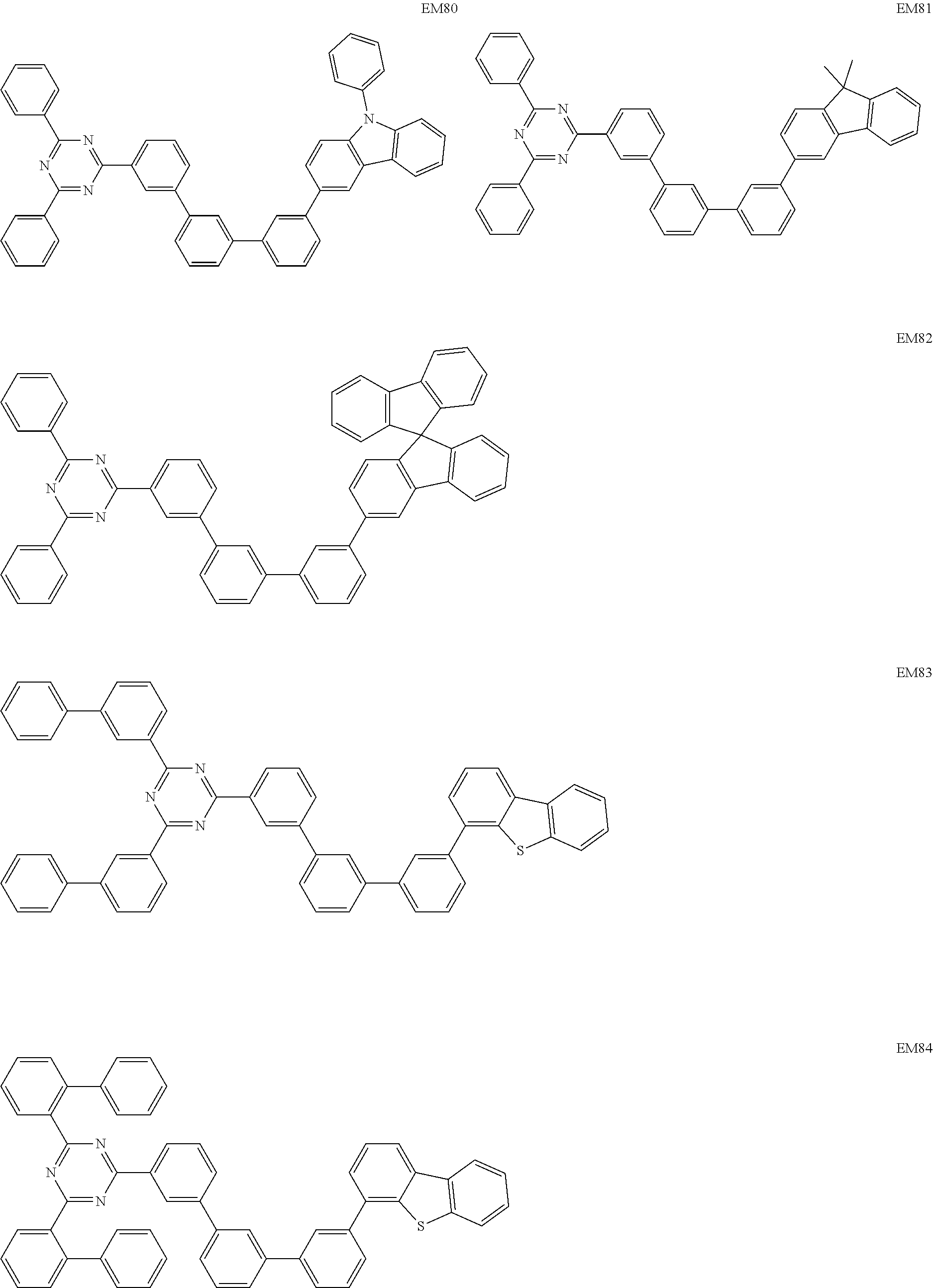

### (4) Other Compounds

Specific examples of other compounds that can be used in the organic light-emitting device according to the present invention are illustrated below.

As a hole injection-transport material that can be used for a hole injection layer or the hole transport layer, a material having high hole mobility is preferred in order to facilitate the injection of holes from the anode and to transport the injected holes to the light-emitting layers. To inhibit a deterioration in film quality, such as crystallization, in the organic light-emitting device, a material having a high glass transition temperature is preferred. Examples of low- or high-molecular-weight materials having the ability to inject and transport holes include triarylamine derivatives, aryl carbazole derivatives, phenylenediamine derivatives, stilbene derivatives, phthalocyanine derivatives, porphyrin derivatives, poly(vinyl carbazole), poly(thiophene), and other conductive polymers. Moreover, the hole injection-transport material can also be used for an electron-blocking layer.

The following are specific examples of compounds used as the hole injection-transport materials, but of course the hole injection-transport materials are not limited thereto.

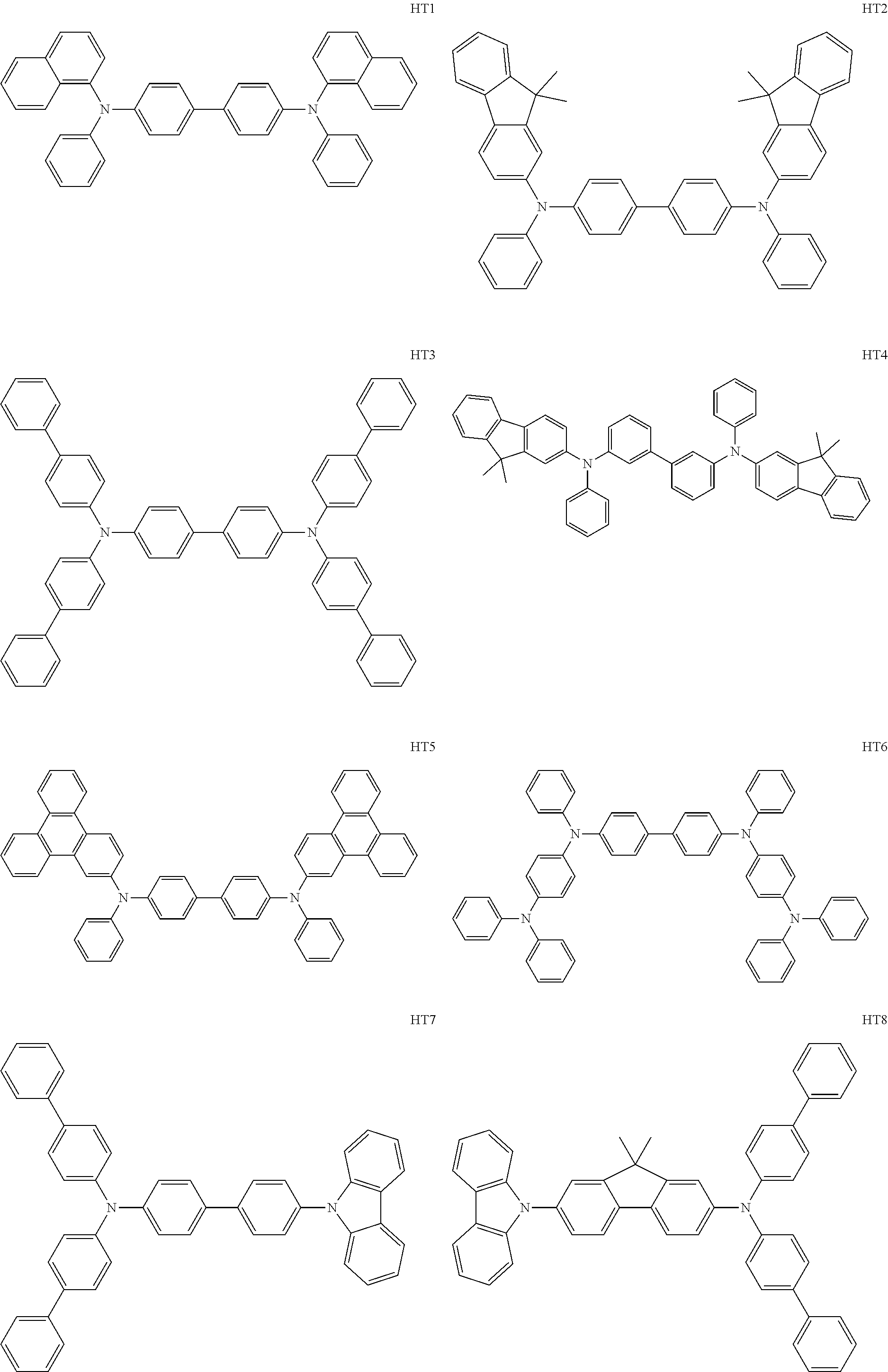

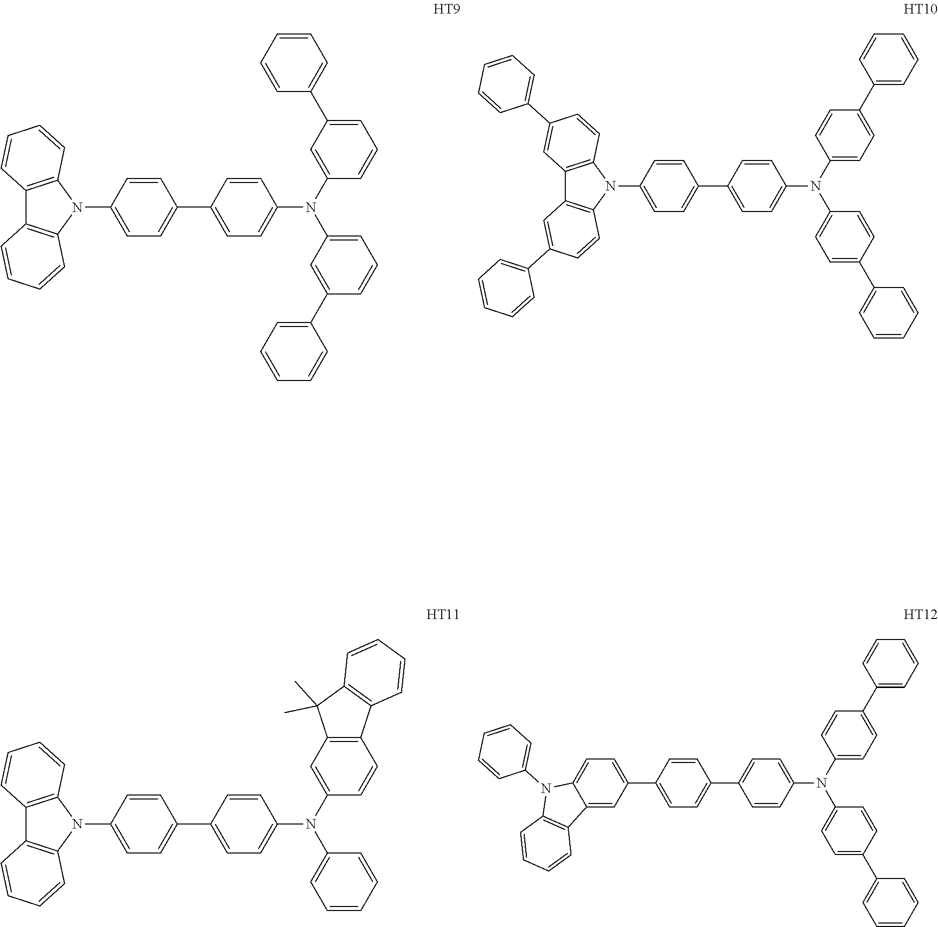 [SMILES: c1ccc(-c2cccc(N(c3ccc(-c4ccc(-n5c6ccccc6c6ccccc65)cc4)cc3)c3cccc(-c4ccccc4)c3)c2)cc1 ; c1ccc(-c2ccc(N(c3ccc(-c4ccccc4)cc3)c3ccc(-c4ccc(-n5c6ccc(-c7ccccc7)cc6c6cc(-c7ccccc7)ccc65)cc4)cc3)cc2)cc1 ; CC1(C)c2ccccc2-c2ccc(N(c3ccccc3)c3ccc(-c4ccc(-n5c6ccccc6c6ccccc65)cc4)cc3)cc21 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1]

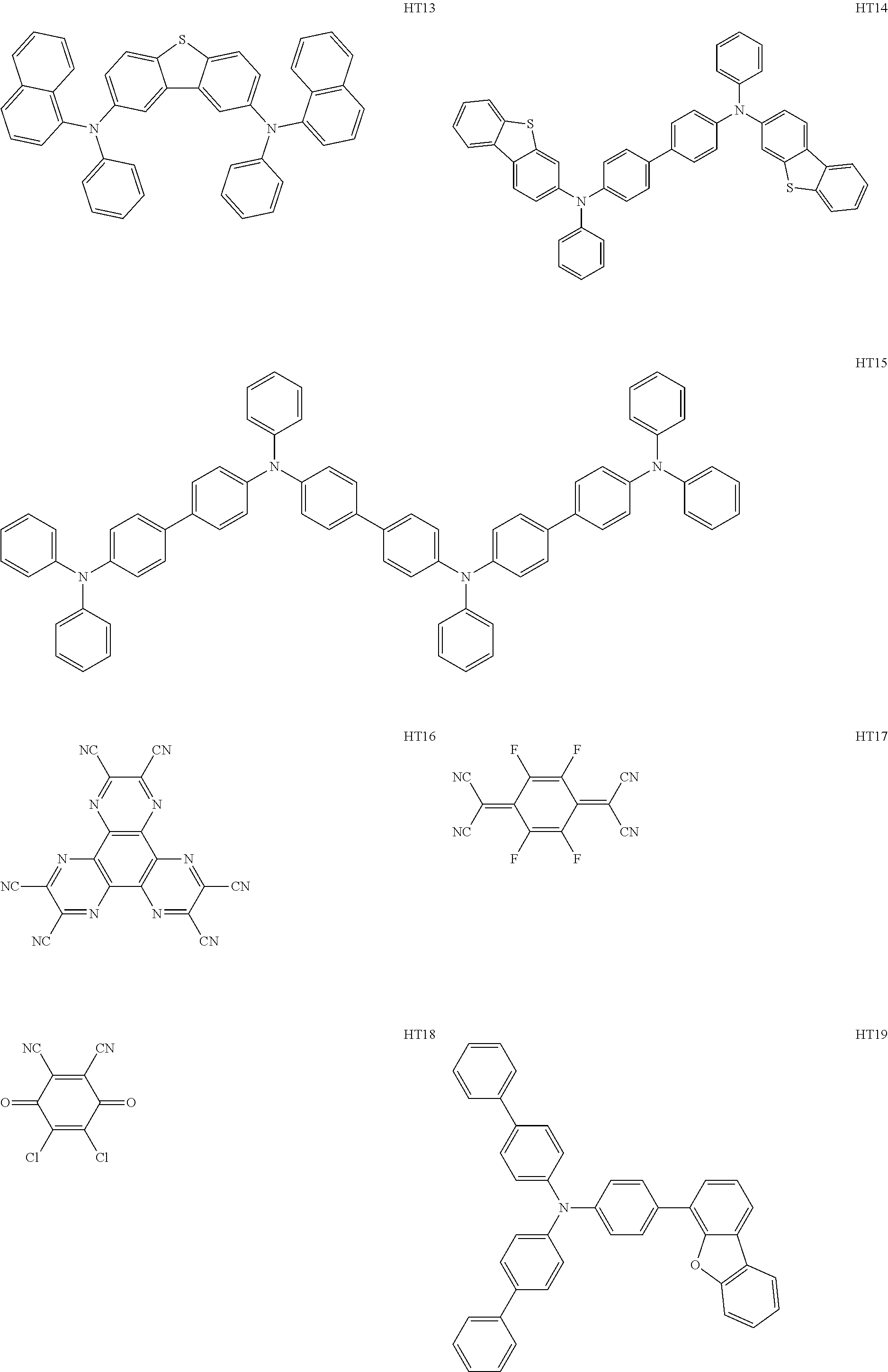

Examples of the light-emitting material mainly related to the light-emitting function include, in addition to the metal complexes represented by general formulae [Ir-1] to [Ir-16], fused-ring compounds, such as fluorene derivatives, naphthalene derivatives, pyrene derivatives, perylene derivatives, tetracene derivatives, anthracene derivatives, and rubrene; quinacridone derivatives; coumarin derivatives; stilbene derivatives; organoaluminum complexes such as tris (8-quinolinolato)aluminum; iridium complexes; platinum complexes; rhenium complexes; copper complexes; europium complexes; ruthenium complexes; and polymer derivatives, such as poly(phenylene vinylene) derivatives, poly(fluorene) derivatives, and poly(phenylene) derivatives.

Specific examples of a compound that can be used as a light-emitting material are illustrated below, but of course the light-emitting material is not limited thereto.

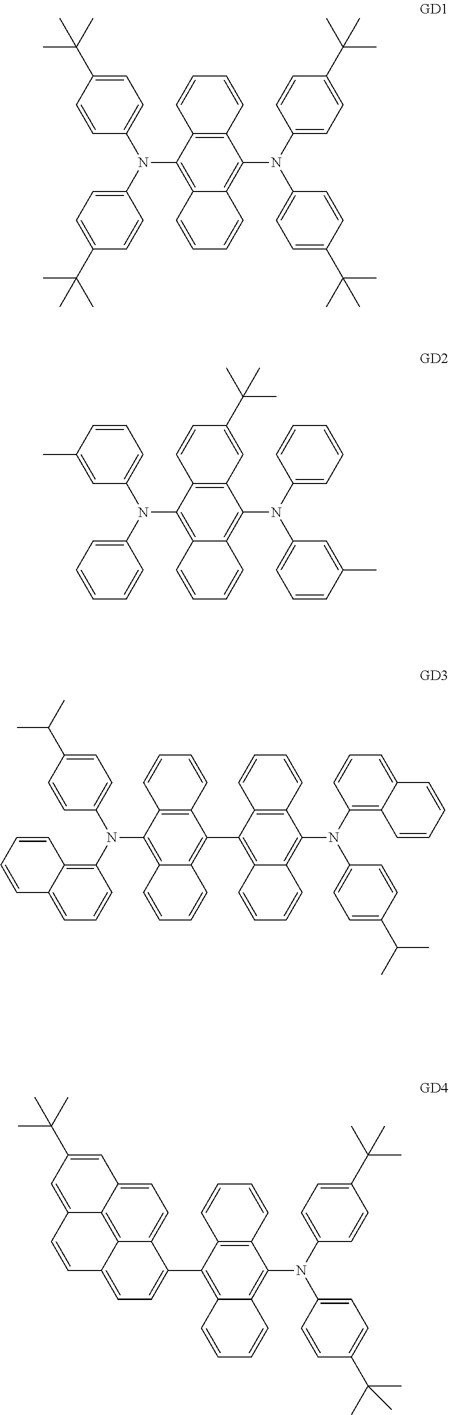

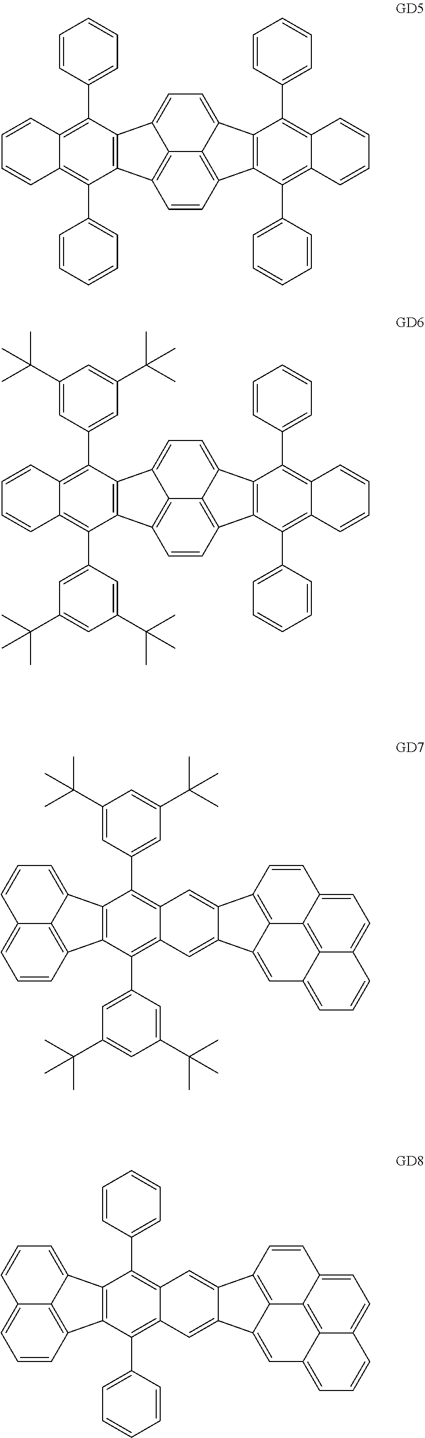

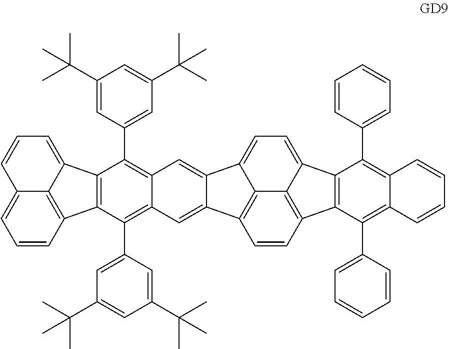

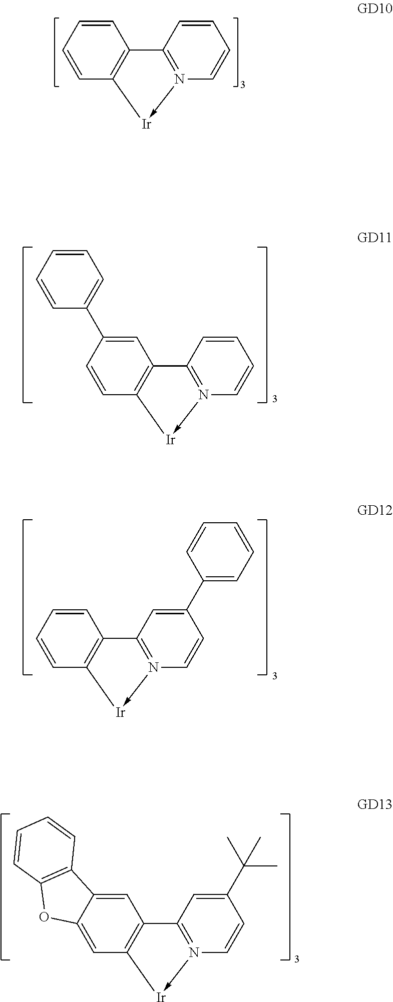

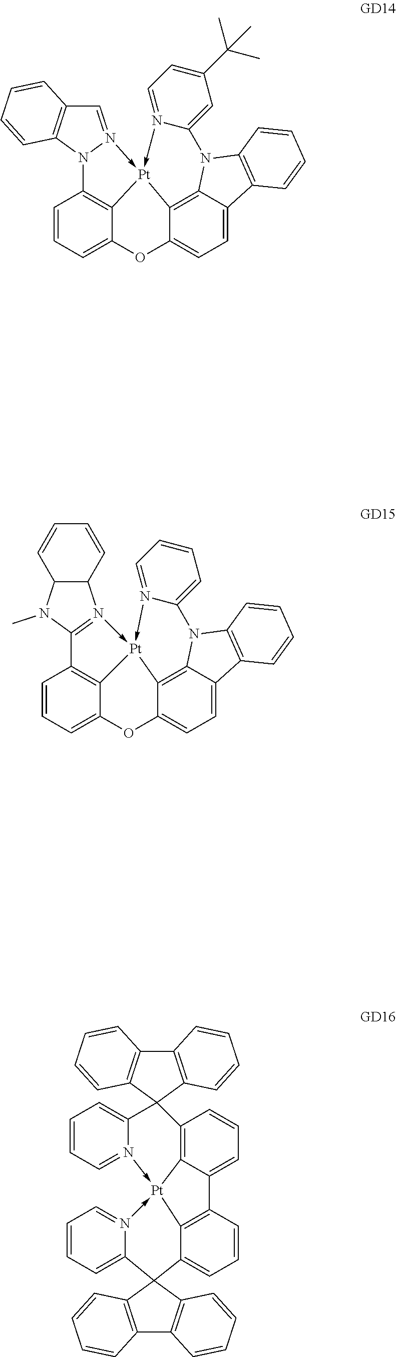

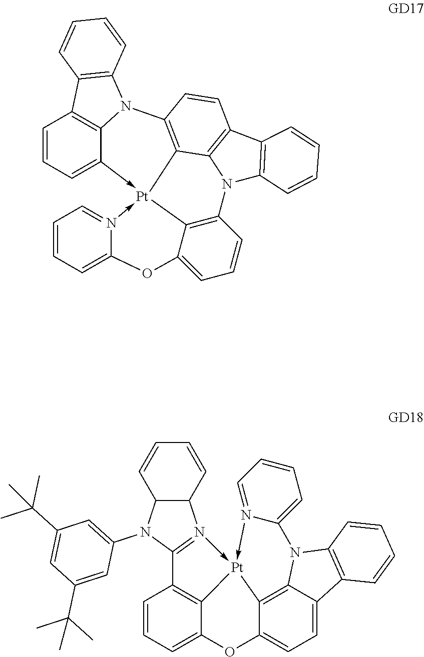

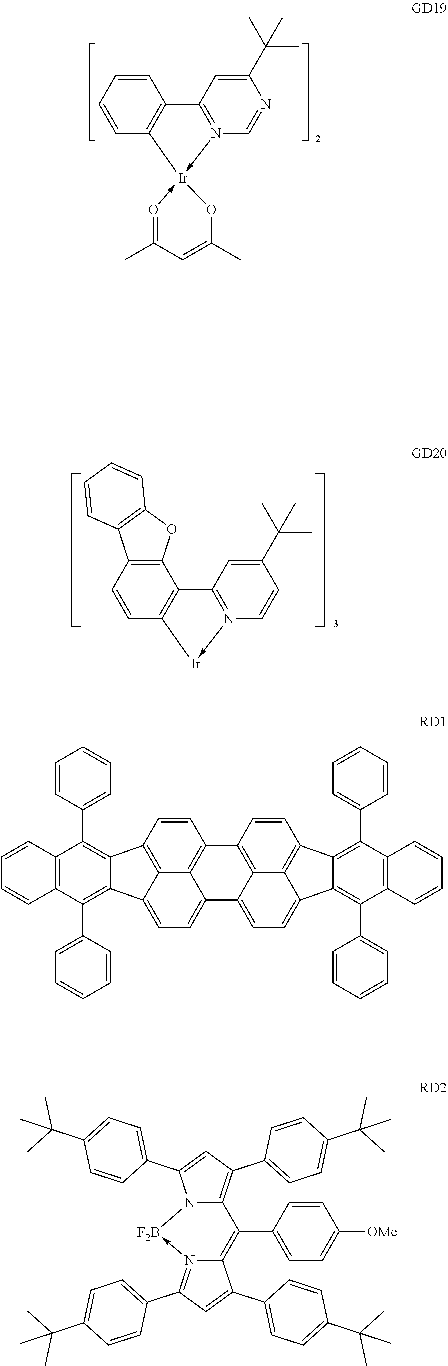

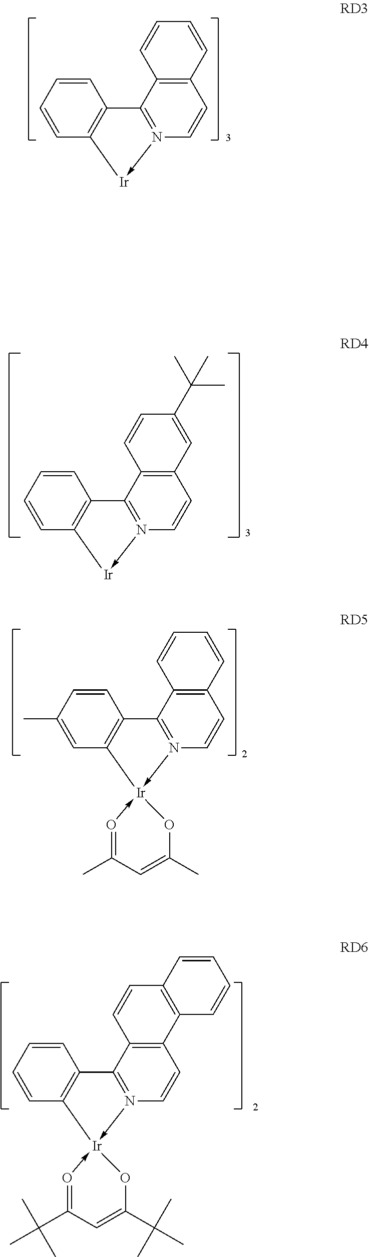

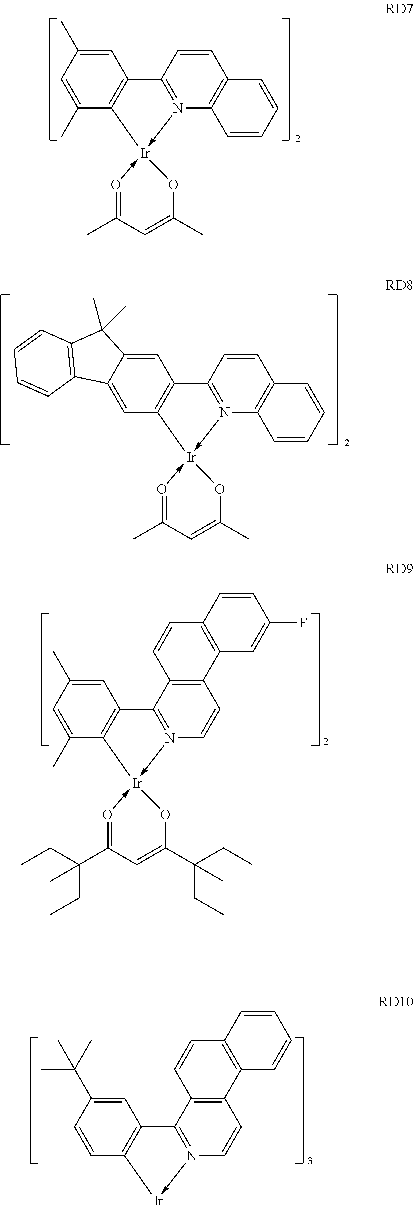

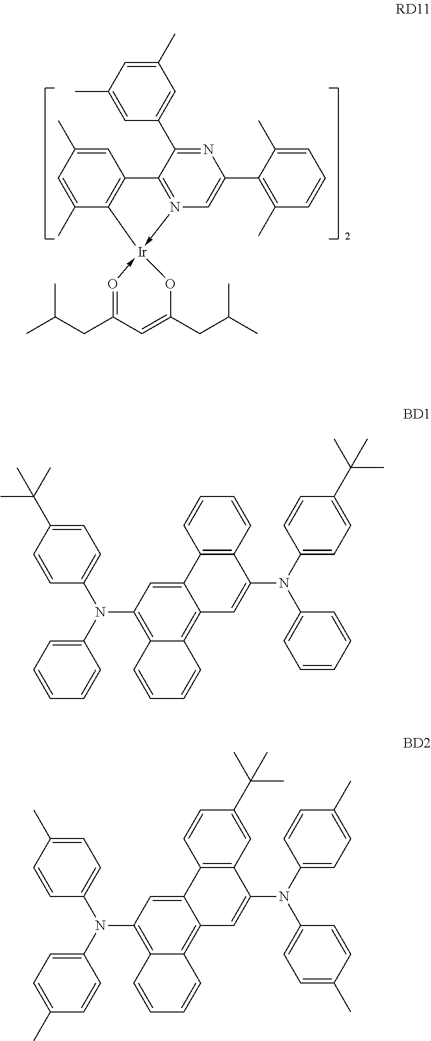

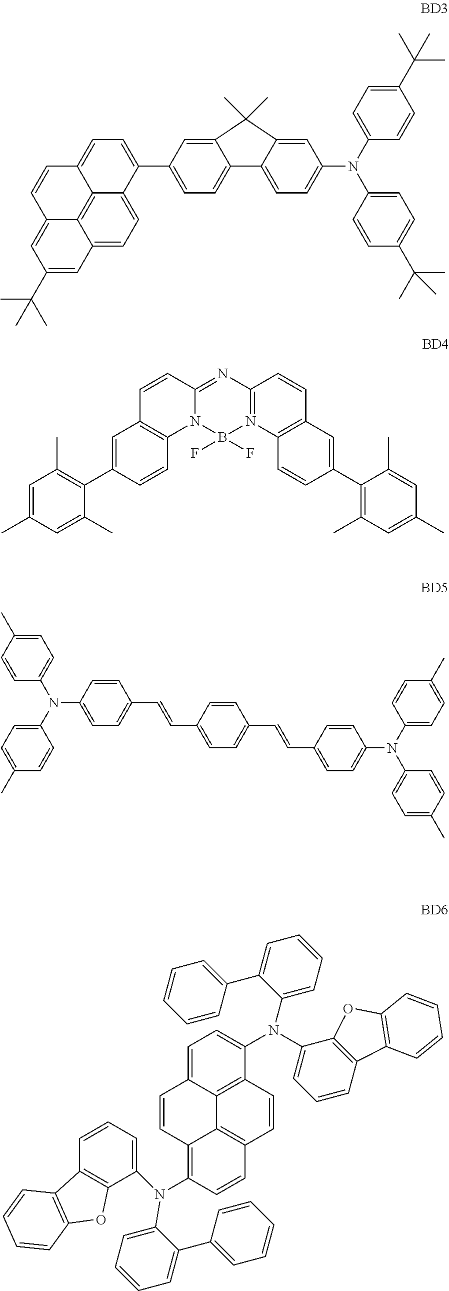

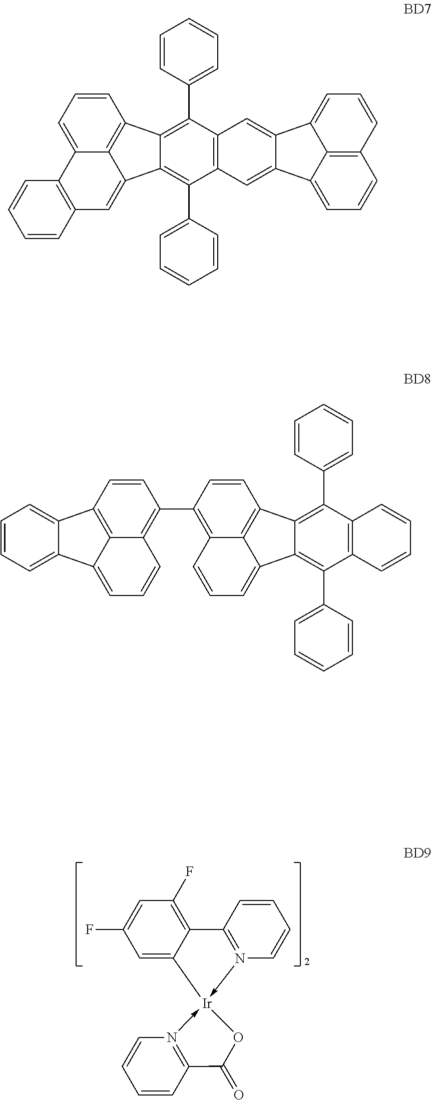

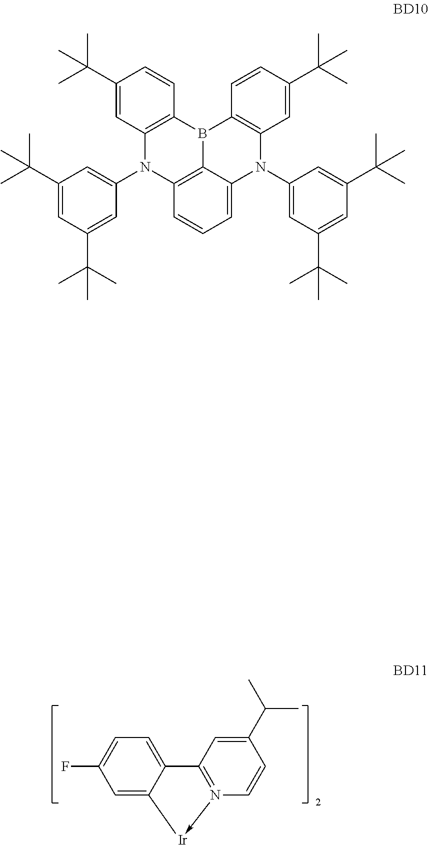

Examples of a host material or an assist material contained in the light-emitting layers include aromatic hydrocarbon compounds and derivatives thereof, carbazole derivatives, dibenzofuran derivatives, dibenzothiophene derivatives, organoaluminum complexes, such as tris(8-quinolinolato)aluminum, and organoberyllium complexes. Specific examples thereof include, but of course not limited to, the compounds represented by EM1 to EM84 described above.

The electron transport material can be freely-selected from materials capable of transporting electrons injected from the cathode to the light-emitting layers and is selected in consideration of, for example, the balance with the hole mobility of the hole transport material. Examples of a material having the ability to transport electrons include oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused-ring compounds, such as fluorene derivatives, naphthalene derivatives, chrysene derivatives, and anthracene derivatives. The above-described electron transport materials are also suitably used for the hole-blocking layer.

Specific examples of a compound used as the electron transport material are illustrated below, but of course the compound is not limited thereto.

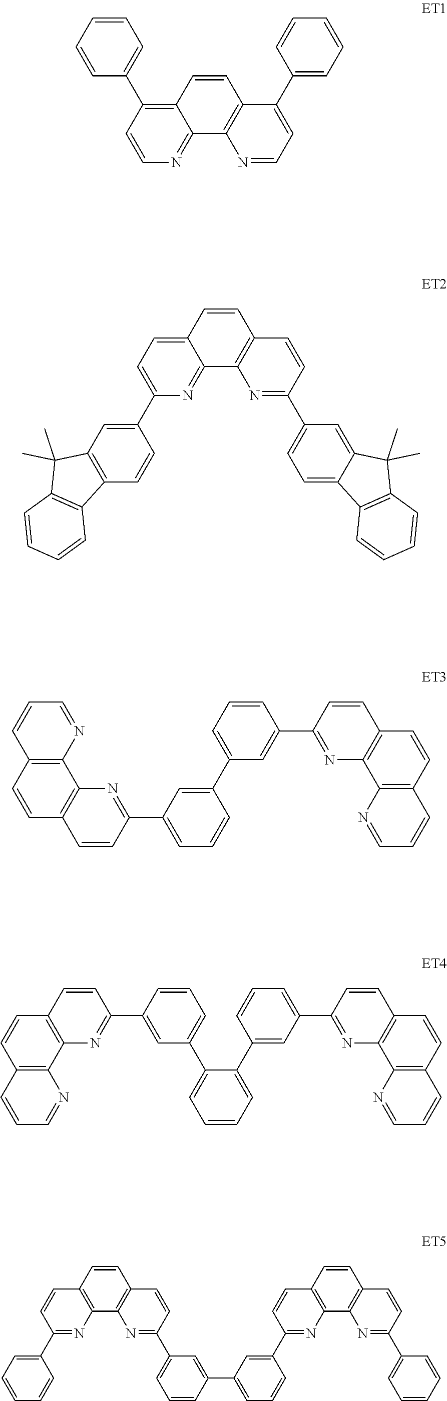

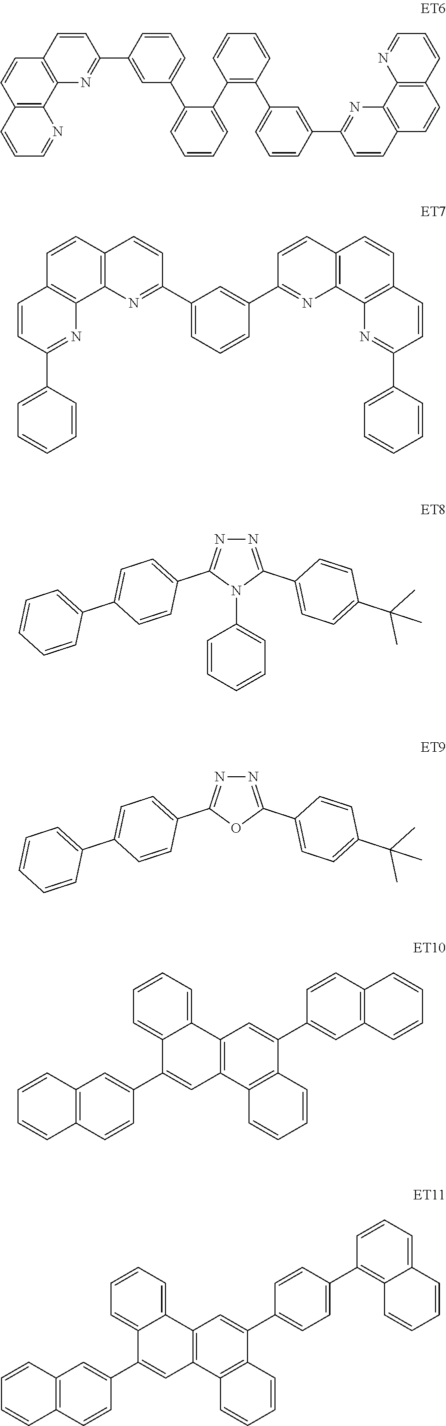

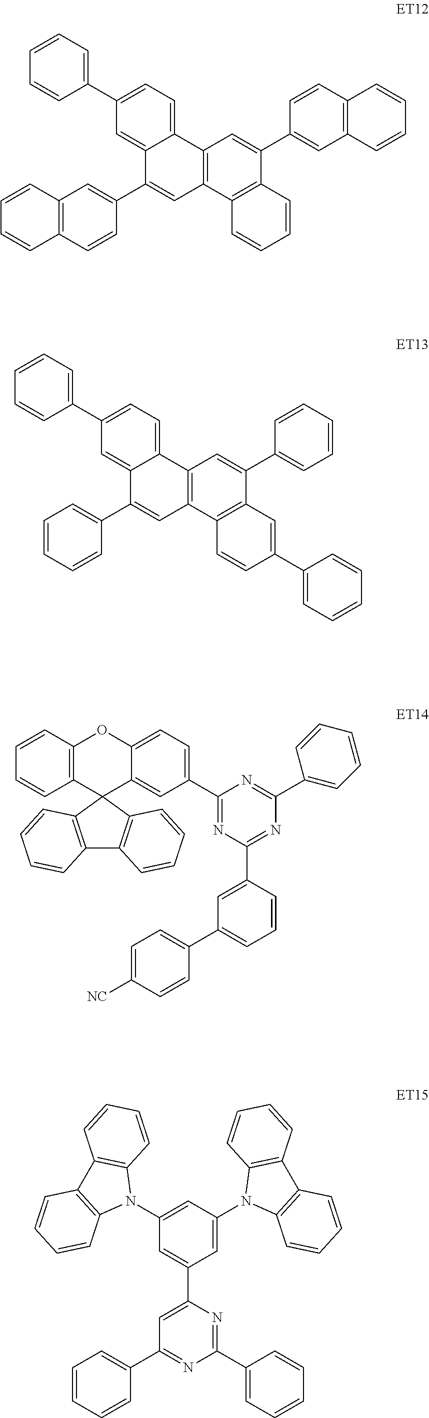

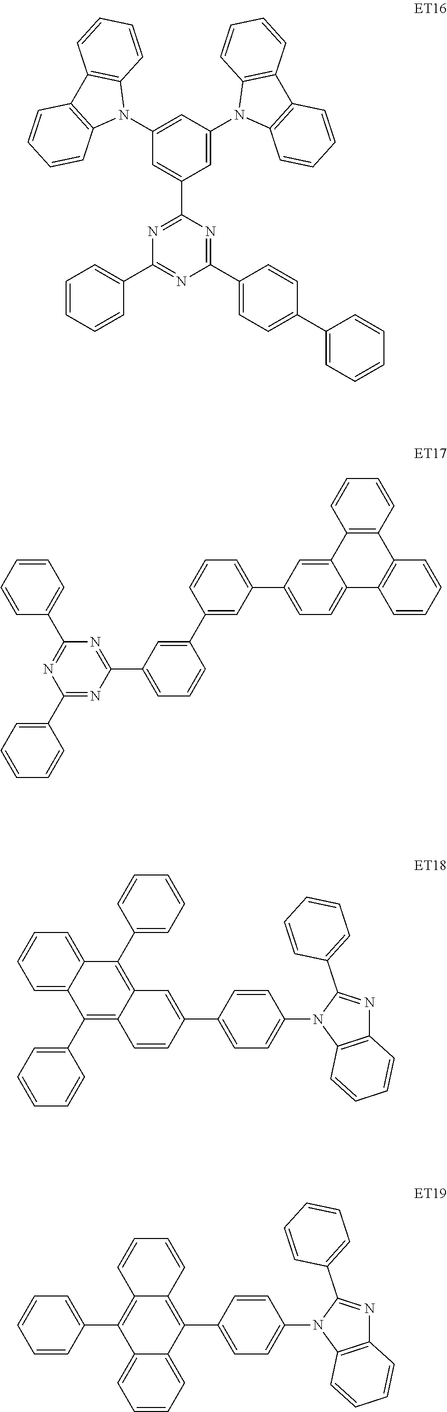 [SMILES: c1ccc(-c2ccc(-c3nc(-c4ccccc4)nc(-c4cc(-n5c6ccccc6c6ccccc65)cc(-n5c6ccccc6c6ccccc65)c4)n3)cc2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2c3ccccc3c(-c3ccccc3)c3cc(-c4ccc(-n5c(-c6ccccc6)nc6ccccc65)cc4)ccc23)cc1 ; c1ccc(-c2c3ccccc3c(-c3ccc(-n4c(-c5ccccc5)nc5ccccc54)cc3)c3ccccc23)cc1]

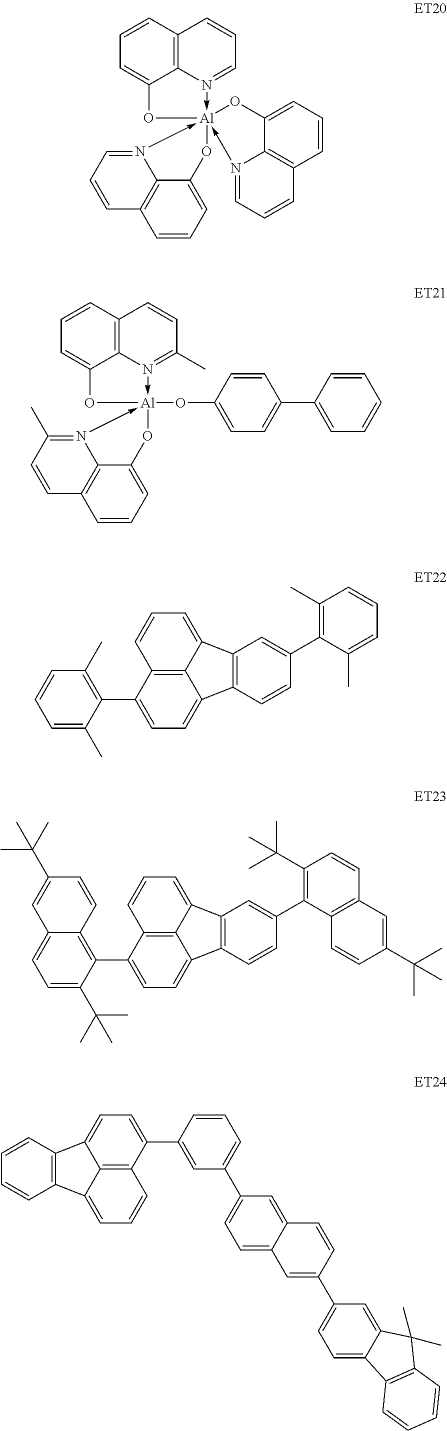

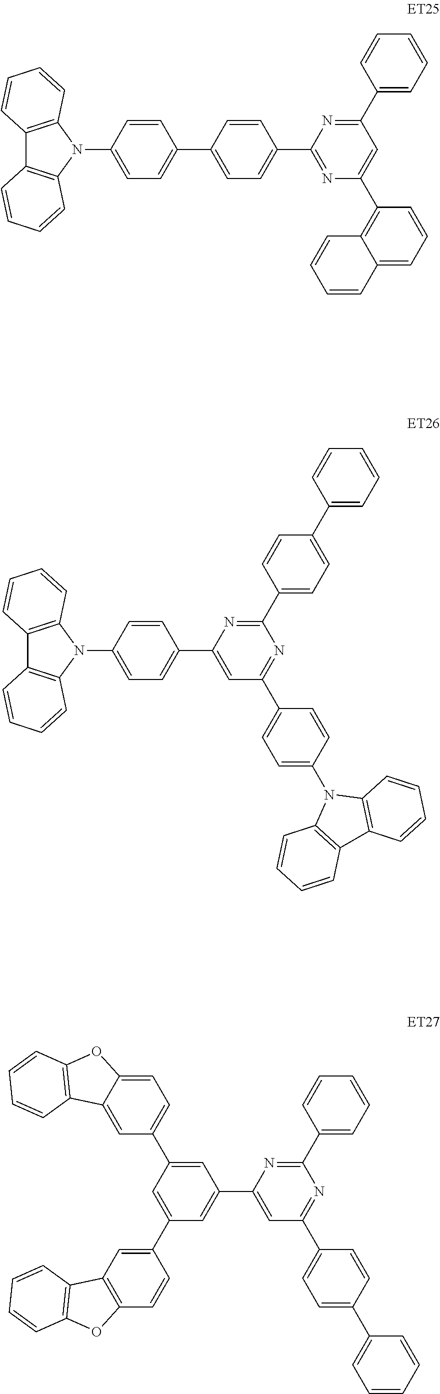 [SMILES: c1ccc(-c2cc(-c3cccc4ccccc34)nc(-c3ccc(-c4ccc(-n5c6ccccc6c6ccccc65)cc4)cc3)n2)cc1 ; c1ccc(-c2ccc(-c3nc(-c4ccc(-n5c6ccccc6c6ccccc65)cc4)cc(-c4ccc(-n5c6ccccc6c6ccccc65)cc4)n3)cc2)cc1 ; c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

### (5) Configuration of Organic Light-Emitting Device

Constituent members, other than the organic compound layer, constituting the organic light-emitting device according to the present embodiment will be described below.

The organic light-emitting device includes an insulating layer, a first electrode, an organic compound layer, and a second electrode over a substrate. A protective layer, a color filter, a microlens, and so forth may be disposed over the second electrode. The color filter may be provided on the protective layer. In this case, a planarization layer may be disposed between the protective layer and the color filter. The planarization layer can be composed of, for example, an acrylic resin. The microlens may be provided on the color filter. The same applies when a planarization layer is provided between the color filter and the microlens.

### Substrate

Examples of the substrate include quartz, glass, silicon wafers, resins, and metals. The substrate may include a switching element, such as a transistor, a line, and an insulating layer thereon. Any material can be used for the insulating layer as long as a contact hole can be formed in such a manner that a line can be coupled to the first electrode and as long as insulation with a non-connected line can be ensured. For example, a resin, such as polyimide, silicon oxide, or silicon nitride, can be used.

### Electrode

As the electrodes, a pair of electrodes can be used. The pair of electrodes may be an anode and a cathode. When an electric field is applied in the direction in which the organic light-emitting device emits light, an electrode having a higher potential is the anode, and the other is the cathode. It can also be said that the electrode that supplies holes to the light-emitting layers is the anode and that the electrode that supplies electrons is the cathode.

As a constituent material of the anode, a material having a work function as large as possible is preferred. Examples of the material that can be used include elemental metals, such as gold, platinum, silver, copper, nickel, palladium, cobalt, selenium, vanadium, and tungsten, mixtures thereof, alloys of combinations thereof, and metal oxides, such as tin oxide, zinc oxide, indium oxide, indium-tin oxide (ITO), and indium-zinc oxide. Additionally, conductive polymers, such as polyaniline, polypyrrole, and polythiophene, can also be used.

These electrode materials may be used alone or in combination of two or more. The anode may be formed of a single layer or multiple layers.

When the anode is used as a reflective electrode, for example, chromium, aluminum, silver, titanium, tungsten, molybdenum, an alloy thereof, or a stack thereof may be used. These materials can also be used to act as a reflective film that does not have the role of an electrode. When the anode is used as a transparent electrode, a transparent conductive oxide layer composed of, for example, indium-tin oxide (ITO) or indium-zinc oxide may be used; however, the anode is not limited thereto. The electrode may be formed by a photolithography technique.

As a constituent material of the cathode, a material having a small work function is preferred. Examples thereof include elemental metals, such as alkali metals, e.g., lithium, alkaline-earth metals, e.g., calcium, aluminum, titanium, manganese, silver, lead, and chromium, and mixtures containing them. Alloys of combinations of these elemental metals can also be used. For example, magnesium-silver, aluminum-lithium, aluminum-magnesium, silver-copper, zinc-silver, and so forth can be used. Metal oxides, such as indium-tin oxide (ITO), can also be used. These electrode materials may be used alone or in combination of two or more. The cathode may have a single-layer structure or a multilayer structure. In particular, silver is preferably used. To reduce the aggregation of silver, a silver alloy is more preferred. Any alloy ratio may be used as long as the aggregation of silver can be reduced. The ratio of silver to another metal may be, for example, 1:1 or 3:1.

A top emission device may be provided using the cathode formed of a conductive oxide layer composed of, for example, ITO. A bottom emission device may be provided using the cathode formed of a reflective electrode composed of, for example, aluminum (Al). The cathode is not particularly limited. A method for forming the cathode is not particularly limited, but a direct-current sputtering method, an alternating-current sputtering method, or the like is more preferably used because good film coverage is obtained and thus the resistance is easily reduced.

### Organic Compound Layer

The organic compound layer may be formed of a single layer or multiple layers. When multiple layers are present, they may be referred to as a hole injection layer, a hole transport layer, an electron-blocking layer, a light-emitting layer, a hole-blocking layer, an electron transport layer, or an electron injection layer in accordance with their functions. The organic compound layer may include multiple light-emitting layers. When multiple light-emitting layers are provided, a charge generation layer may be provided between one of the light-emitting layers and another light-emitting layer. The individual light-emitting layers may be stacked. For example, when the light-emitting layer according to an embodiment of the present invention is provided, a charge generation layer and a third light-emitting layer may be included. That is, the first light-emitting layer, the second light-emitting layer, the charge generation layer, and the third light-emitting layer may be arranged in this order, or the third light-emitting layer, the charge generation layer, the first light-emitting layer, and the second light-emitting layer may be arranged in this order. The organic compound layer is mainly composed of an organic compound, and may contain inorganic atoms and an inorganic compound. For example, each organic compound layer may contain, for example, copper, lithium, magnesium, aluminum, iridium, platinum, molybdenum, or zinc. The organic compound layer may be disposed between the first electrode and the second electrode, or may be disposed in contact with the first electrode and the second electrode.

### Protective Layer

A protective layer may be disposed on the cathode. For example, glass provided with a moisture absorbent can be bonded to the cathode to reduce the entry of, for example, water into the organic compound layer, thereby reducing the occurrence of display defects. In another embodiment, a passivation film composed of, for example, silicon nitride may be disposed on the cathode to reduce the entry of, for example, water into the organic compound layer. For example, after the formation of the cathode, the substrate may be conveyed to another chamber without breaking the vacuum, and a silicon nitride film having a thickness of 2 μm may be formed by a chemical vapor deposition (CVD) method to form a protective layer. After the film deposition by the CVD method, a protective layer may be formed by an atomic layer deposition (ALD) method. Examples of the material of the layer formed by the ALD method may include, but are not limited to, silicon nitride, silicon oxide, and aluminum oxide. Silicon nitride may be deposited by the CVD method on the layer formed by the ALD method. The film formed by the ALD method may have a smaller thickness than the film formed by the CVD method. Specifically, the thickness may be 50% or less, even 10% or less.

### Color Filter

A color filter may be disposed on the protective layer. For example, a color filter may be disposed on another substrate in consideration of the size of the organic light-emitting device and bonded to the substrate provided with the organic light-emitting device. A color filter may be formed by patterning on the protective layer using a photolithography technique. The color filter may be composed of a polymer.

### Planarization Layer

A planarization layer may be disposed between the color filter and the protective layer. The planarization layer is provided for the purpose of reducing the unevenness of the layer underneath. The planarization layer may be referred to as a “material resin layer” without limiting its purpose. The planarization layer may be composed of an organic compound, may have a low-molecular-weight or high-molecular-weight compound, and is preferably a high-molecular-weight compound.

The planarization layers may be disposed above and below the color filter and may be composed of the same or different constituent materials. Specific examples thereof include polyvinyl carbazole resins, polycarbonate resins, polyester resins, ABS resins, acrylic resins, polyimide resins, phenolic resins, epoxy resins, silicone resins, and urea resins.

### Microlens

The organic light-emitting apparatus may include an optical member, such as a microlens, on the outgoing light side. The microlens can be composed of, for example, an acrylic resin or an epoxy resin. The microlens may be used to increase the amount of light emitted from the organic light-emitting apparatus and to control the direction of the light emitted. The microlens may have a hemispherical shape. In the case of a hemispherical shape, among tangents to the hemisphere, there is a tangent parallel to the insulating layer. The point of contact of the tangent with the hemisphere is the vertex of the microlens. The vertex of the microlens can be determined in the same way for any cross-sectional view. That is, among the tangents to the semicircle of the microlens in the cross-sectional view, there is a tangent parallel to the insulating layer, and the point of contact of the tangent with the semicircle is the vertex of the microlens.

The midpoint of the microlens can be defined. In the cross section of the microlens, when a segment is hypothetically drawn from the point where an arc shape ends to the point where another arc shape ends, the midpoint of the segment can be referred to as the midpoint of the microlens. The cross section to determine the vertex and midpoint may be a cross section perpendicular to the insulating layer.

### Opposite Substrate

An opposite substrate may be disposed on the planarization layer. The opposite substrate is disposed at a position corresponding to the substrate described above and thus is called an opposite substrate. The opposite substrate may be composed of the same constituent material as that of the substrate described above. When the above-described substrate is referred to as a first substrate, the opposite substrate may be referred to as a second substrate.

### Organic Compound Layer

The organic compound layer (for example, the hole injection layer, the hole transport layer, the electron-blocking layer, the light-emitting layer, the hole-blocking layer, the electron transport layer, or the electron injection layer) included in the organic light-emitting device according to an embodiment of the present invention is formed by a method described below.

For the organic compound layer included in the organic light-emitting device according to an embodiment of the present invention, a dry process, such as a vacuum evaporation method, an ionized evaporation method, sputtering, or plasma, may be employed. Alternatively, instead of the dry process, it is also possible to employ a wet process in which a material is dissolved in an appropriate solvent and then a film is formed by a known coating method (for example, spin coating, dipping, a casting method, an LB technique, or an ink jet method).

When the layer is formed by, for example, the vacuum evaporation method or the solution coating method, crystallization and so forth are less likely to occur, and good stability with time is obtained. In the case of forming a film by the coating method, the film may be formed in combination with an appropriate binder resin.

Examples of the binder resin include, but are not limited to, polyvinyl carbazole resins, polycarbonate resins, polyester resins, ABS resins, acrylic resins, polyimide resins, phenolic resins, epoxy resins, silicone resins, and urea resins.

These binder resins may be used alone as a homopolymer or copolymer or in combination as a mixture of two or more. Furthermore, additives, such as a known plasticizer, antioxidant, and ultraviolet absorber, may be used, as needed.

### Pixel Circuit

A light-emitting apparatus may include pixel circuits coupled to the light-emitting devices. The pixel circuits may be of an active matrix type in which respective first and second light-emitting devices are independently controlled to emit light. The active matrix type circuit may be voltage programming or current programming. A driving circuit includes the pixel circuit for each pixel. The pixel circuit may include a light-emitting device, a transistor to control the luminance of emission light from the light-emitting device, a transistor to control the timing of the light emission, a capacitor to retain the gate voltage of the transistor to control the luminance of emission light, and a transistor to connect to GND without using the light-emitting device.

The light-emitting apparatus includes a display area and a peripheral area disposed around the display area. The display area includes a pixel circuit, and the peripheral area includes a display control circuit. The mobility of a transistor contained in the pixel circuit may be lower than the mobility of a transistor contained in the display control circuit.

The slope of the current-voltage characteristics of the transistor contained in the pixel circuit may be smaller than the slope of the current-voltage characteristic of the transistor contained in the display control circuit. The slope of the current-voltage characteristics can be measured by what is called Vg-Ig characteristics.

The transistor contained in the pixel circuit is a transistor coupled to a light-emitting device, such as a first light-emitting device.

### Pixel

The organic light-emitting apparatus includes multiple pixels. Each pixel includes subpixels configured to emit different colors from each other. The subpixels may have respective RGB emission colors.

Light emerges from a region of the pixel, also called a pixel aperture. This region is the same as a first region. The pixel aperture may be 15 μm or less, and may be 5 μm or more. More specifically, the pixel aperture may be, for example, 11 μm, 9.5 μm, 7.4 μm, or 6.4 μm.

The distance between subpixels may be 10 μm or less. Specifically, the distance may be 8 μm, 7.4 μm, or 6.4 μm.

The pixels may be arranged in a known configuration in plan view. For example, a stripe pattern, a delta pattern, a Pen Tile matrix pattern, or the Bayer pattern may be used. The shape of each subpixel in plan view may be any known shape. Examples thereof include quadrilaterals, such as rectangles and rhombi, and hexagons. Of course, if the shape is close to a rectangle, rather than an exact shape, it is included in the rectangle. The shape of the subpixel and the pixel arrangement can be used in combination.

### (6) Application of Organic Light-Emitting Device According to Present Embodiment

The organic light-emitting device according to an embodiment of the present invention can be used as component member of a display apparatus or a lighting apparatus. Other applications include exposure light sources for electrophotographic image-forming apparatuses, backlights for liquid crystal displays, and light-emitting apparatuses including white light sources provided with color filters.

The display apparatus may be an image information-processing unit having an image input unit that receives image information from an area CCD, a linear CCD, a memory card, or the like, an information-processing unit that processes the input information, and a display unit that displays the input image.

The display unit of an image pickup apparatus or an ink jet printer may have a touch panel function. The driving mode of the touch panel function may be, but is not particularly limited to, an infrared mode, an electrostatic capacitance mode, a resistive film mode, or an electromagnetic inductive mode. The display apparatus may also be used for a display unit of a multifunction printer.

The following describes a display apparatus according to the present embodiment with reference to the attached drawings.

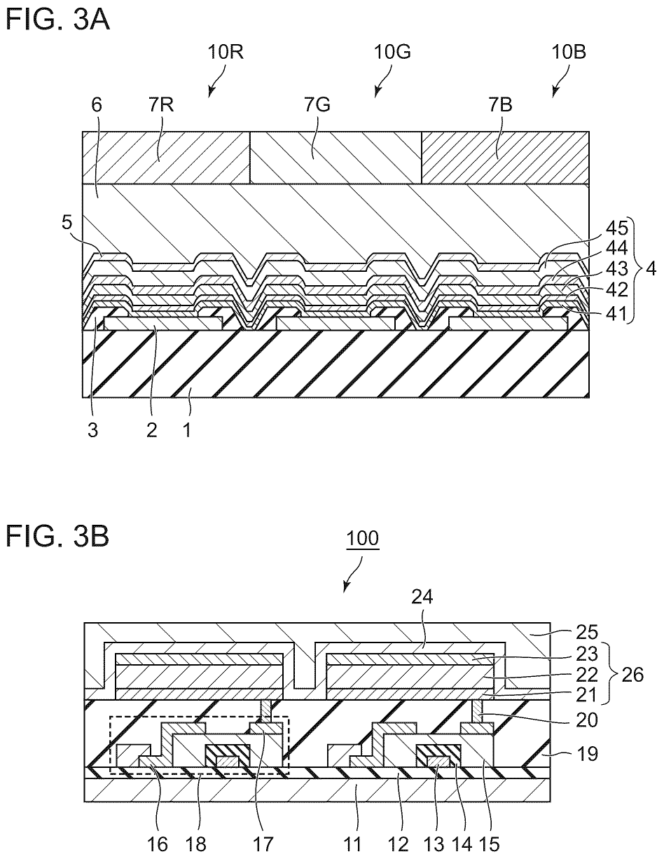

FIGS. 3A and 3B are each a schematic cross-sectional view of an example of a display apparatus including organic light-emitting devices and transistors coupled to the respective organic light-emitting devices. Each of the transistors is an example of an active element. The transistors may be thin-film transistors (TFTs).

FIG. 3A illustrates an example of a pixel that is a component of the display apparatus according to the present embodiment. The pixel includes subpixels 10. The subpixels are divided into 10R, 10G, and 10B according to their light emission. The emission colors may be distinguished by the wavelength of light emitted from the light-emitting layer. Light emitted from the subpixels may be selectively transmitted or color-converted with, for example, a color filter. Each subpixels includes a reflective electrode 2 serving as a first electrode, an insulating layer 3 covering the edge of the reflective electrode 2, an organic compound layer 4 covering the first electrode and the insulating layer, a transparent electrode 5, a protective layer 6, and a color filter 7, over an interlayer insulating layer 1.

The transistors and capacitive elements may be disposed under or in the interlayer insulating layer 1. Each transistor may be electrically coupled to a corresponding one of the first electrodes through, for example, a contact hole (not illustrated).

The insulating layer 3 is also referred to as a bank or pixel separation film. The insulating layer covers the edge of each first electrode and surrounds the first electrode. Portions that are not covered with the insulating layer are in contact with the organic compound layer 4 and serve as light-emitting regions.

The organic compound layer 4 includes a hole injection layer 41, a hole transport layer 42, a first light-emitting layer 43, a second light-emitting layer 44, and an electron transport layer 45.

The second electrode 5 may be a transparent electrode, a reflective electrode, or a semi-transparent electrode.

The protective layer 6 reduces the penetration of moisture into the organic compound layer. Although the protective layer is illustrated as a single layer, the protective layer may be formed of multiple layers. Each layer may be an inorganic compound layer or an organic compound layer.

The color filter 7 is separated into 7R, 7G, and 7B according to their colors. The color filter may be disposed on a planarization film, which is not illustrated. A resin protective layer, which is not illustrated, may be disposed on the color filter. The color filter may also be disposed on the protective layer 6. Alternatively, the color filter may be disposed on an opposite substrate, such as a glass substrate, and then bonded.

A display apparatus 100 illustrated in FIG. 3B includes organic light-emitting devices 26 and TFTs 18 as an example of transistors. A substrate 11 composed of, for example, glass or silicon, is provided, and an insulating layer 12 is disposed thereon. Active elements, such as TFTs 18, are arranged on the insulating layer. A gate electrode 13, a gate insulating film 14, and a semiconductor layer 15 of each of the active elements are arranged. Each TFT 18 includes the semiconductor layer 15, a drain electrode 16, and a source electrode 17. The TFTs 18 are overlaid with an insulating film 19. An anode 21 included in the organic light-emitting devices 26 is coupled to the source electrodes 17 through contact holes 20 provided in the insulating film.

The mode of electrical connection between the electrodes (anode and cathode) included in each organic light-emitting device 26 and the electrodes (source electrode and drain electrode) included in a corresponding one of the TFTs is not limited to the mode illustrated in FIG. 3B. That is, it is sufficient that any one of the anode and the cathode is electrically coupled to any one of the source electrode and the drain electrode of the TFT. The term “TFT” refers to a thin-film transistor.

In the display apparatus 100 illustrated in FIG. 3B, each organic compound layer is illustrated as a single layer; however, the organic compound layer 22 may be formed of multiple layers. To reduce the deterioration of the organic light-emitting devices, a first protective layer 24 and a second protective layer 25 are disposed on the cathodes 23.

Although the transistors are used as switching elements in the display apparatus 100 illustrated in FIG. 3B, other switching elements may be used instead.

The transistors used in the display apparatus 100 illustrated in FIG. 3B are not limited to transistors using a single-crystal silicon wafer, but may also be thin-film transistors including active layers on the insulating surface of a substrate. Examples of the active layer include single-crystal silicon, non-single-crystal silicon materials, such as amorphous silicon and microcrystalline silicon, and non-single-crystal oxide semiconductors, such as indium-zinc oxide and indium-gallium-zinc oxide. Thin-film transistors are also referred to as TFT elements.

The transistors in the display apparatus 100 illustrated in FIG. 3B may be formed in the substrate, such as a Si substrate. The expression “formed in the substrate” indicates that the transistors are produced by processing the substrate, such as a Si substrate. When the transistors are formed in the substrate, the substrate and the transistors can also be deemed to be integrally formed.

In the organic light-emitting device according to the present embodiment, the luminance of emission light is controlled by the TFT elements, which are an example of switching elements; thus, an image can be displayed at respective luminance levels by arranging multiple organic light-emitting devices in the plane. The switching elements according to the present embodiment are not limited to the TFT elements and may be low-temperature polysilicon transistors or active-matrix drivers formed on a substrate, such as a Si substrate. The expression “on a substrate” can also be said to be “in the substrate”. Whether transistors are formed in the substrate or TFT elements are used is selected in accordance with the size of a display unit. For example, when the display unit has a size of about 0.5 inches, organic light-emitting devices are preferably disposed on a Si substrate.

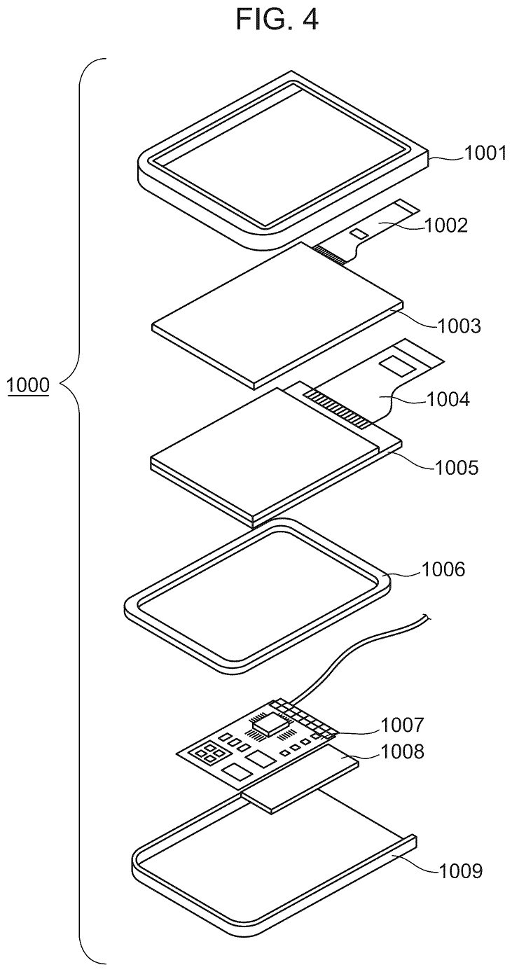

FIG. 4 is a schematic view illustrating an example of a display apparatus according to the present embodiment. A display apparatus 1000 may include, between an upper cover 1001 and a lower cover 1009, a touch panel 1003, a display panel 1005, a frame 1006, a circuit substrate 1007, and a battery 1008. The touch panel 1003 and the display panel 1005 are coupled to flexible printed circuits FPCs 1002 and 1004, respectively. The circuit substrate 1007 includes printed transistors. The battery 1008 need not be provided unless the display apparatus is a portable apparatus, or may be disposed at a different position even if the display apparatus is a portable apparatus.

The display apparatus according to the present embodiment may include a color filter having red, green, and blue portions. In the color filter, the red, green, and blue portions may be arranged in a delta arrangement.

The display apparatus according to the present embodiment may be used for the display unit of a portable terminal. In that case, the display apparatus may have both a display function and an operation function. Examples of the portable terminal include mobile phones, such as smartphones, tablets, and head-mounted displays.

The display apparatus according to the present embodiment may be used for a display unit of an image pickup apparatus including an optical unit including a single or multiple lenses and an image pickup device that receives light passing through the optical unit. The image pickup apparatus may include a display unit that displays information acquired by the image pickup device. The display unit may be a display unit exposed to the outside of the image pickup apparatus or may be a display unit disposed in a finder. The image pickup apparatus may be a digital camera or a digital camcorder.

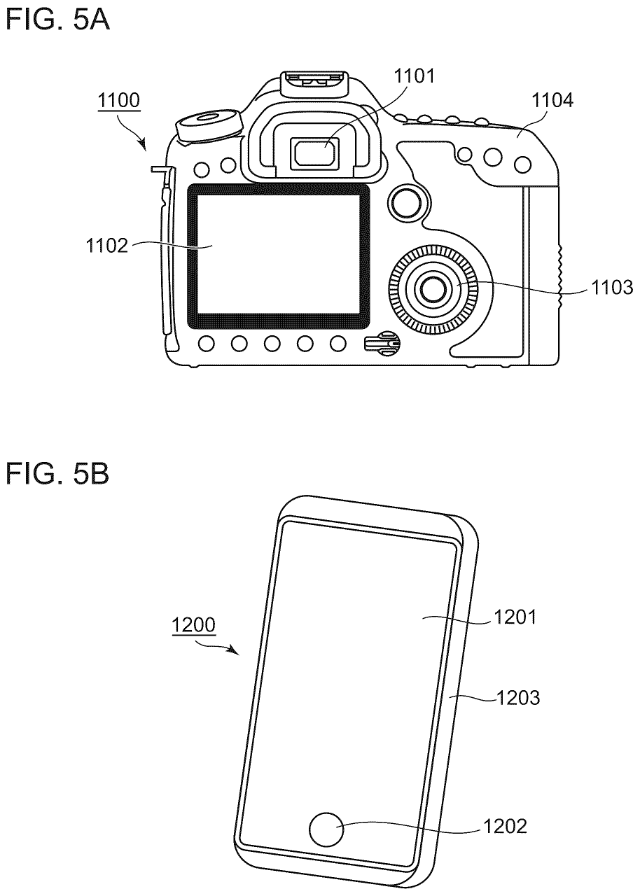

FIG. 5A is a schematic view illustrating an example of an image pickup apparatus according to the present embodiment. An image pickup apparatus 1100 may include a viewfinder 1101, a rear display 1102, an operation unit 1103, and a housing 1104. The viewfinder 1101 may include the display apparatus according to the present embodiment. In this case, the display apparatus may display environmental information, imaging instructions, and so forth in addition to an image to be captured. The environmental information may include, for example, the intensity of external light, the direction of the external light, the moving speed of a subject, and the possibility that a subject is shielded by a shielding material.

The timing suitable for imaging is only for a short time; thus, it is better to display the information as soon as possible. Thus, a display apparatus including the organic light-emitting device according to the present invention is preferably used. This is because organic light-emitting devices have a fast response time. The display apparatus including the organic light-emitting device can be used more suitably than liquid crystal display apparatuses for such apparatuses required to have a high display speed.

The image pickup apparatus 1100 includes an optical unit, which is not illustrated. The optical unit includes a single or multiple lenses and is configured to form an image on an image pickup device in the housing 1104. The relative positions of the single or multiple lenses can be adjusted to adjust the focal point. This operation can also be performed automatically. The image pickup apparatus can also be referred to as a photoelectric conversion apparatus. Examples of an image capturing method employed in the photoelectric conversion apparatus can include a method for detecting a difference from the previous image and a method for cutting out an image from images always recorded, instead of sequentially capturing images.

FIG. 5B is a schematic view illustrating an example of an electronic apparatus according to the present embodiment. An electronic apparatus 1200 includes a display unit 1201, an operation unit 1202, and a housing 1203. The housing 1203 may accommodate a circuit, a printed circuit board including the circuit, a battery, and a communication unit. The operation unit 1202 may be a button or a touch-panel-type reactive unit. The operation unit may be a biometric recognition unit that recognizes a fingerprint to release the lock or the like. An electronic apparatus including a communication unit can also be referred to as a communication apparatus. The electronic apparatus may further have a camera function by being equipped with a lens and an image pickup device. An image captured by the camera function is displayed on the display unit. Examples of the electronic apparatus include smartphones and laptop computers.

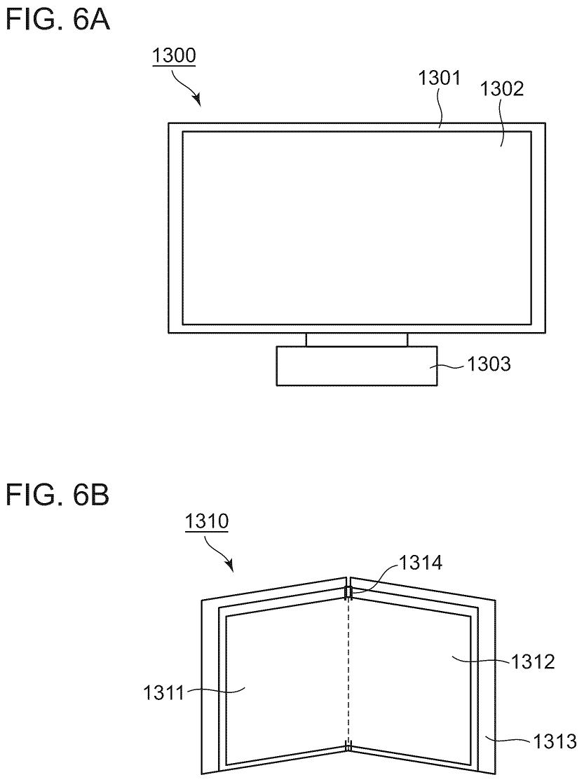

FIG. 6A is a schematic view illustrating an example of a display apparatus according to the present embodiment. FIG. 6A illustrates a display apparatus, such as a television monitor or a PC monitor. A display apparatus 1300 includes a frame 1301 and includes a display unit 1302. The display unit 1302 may include a light-emitting apparatus according to the present embodiment.

A base 1303 that supports the frame 1301 and the display unit 1302 is provided. The base 1303 is not limited to a form illustrated in FIG. 6A. The lower side of the frame 1301 may also serve as a base.

The frame 1301 and the display unit 1302 may be curved. The radius of curvature may be 5,000 mm or more and 6,000 mm or less.

FIG. 6B is a schematic view illustrating another example of a display apparatus according to the present embodiment. A display apparatus 1310 illustrated in FIG. 6B can be folded and is what is called a foldable display apparatus. The display apparatus 1310 includes a first display unit 1311, a second display unit 1312, a housing 1313, and an inflection point 1314. The first display unit 1311 and the second display unit 1312 may include light-emitting apparatuses according to the present embodiment. The first display unit 1311 and the second display unit 1312 may be a single, seamless display apparatus. The first display unit 1311 and the second display unit 1312 can be divided from each other at the inflection point. The first display unit 1311 and the second display unit 1312 may display different images from each other. Alternatively, a single image may be displayed in the first and second display units.

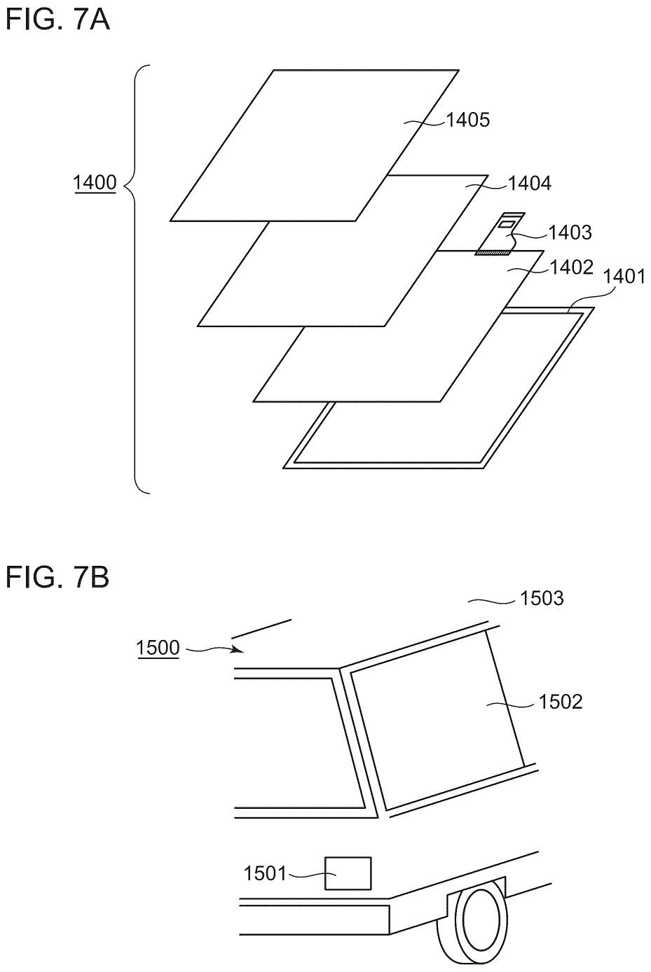

FIG. 7A is a schematic view illustrating an example of a lighting apparatus according to the present embodiment. A lighting apparatus 1400 may include a housing 1401, a light source 1402, a circuit board 1403, an optical film 1404, and a light diffusion unit 1405. The light source may include an organic light-emitting device according to the present embodiment. The optical filter may be a filter that improves the color rendering properties of the light source. The light diffusion unit can effectively diffuse light from the light source to deliver the light to a wide range when used for illumination and so forth. The optical filter and the light diffusion unit are disposed on the light emission side of the lighting apparatus. A cover may be disposed at the outermost portion, as needed.

The lighting apparatus is, for example, an apparatus that lights a room. The lighting apparatus may emit light of white, neutral white, or any color from blue to red. A light control circuit that controls the light may be provided. The lighting apparatus may include the organic light-emitting device of the present invention and a power supply circuit coupled thereto. The power supply circuit is a circuit that converts an AC voltage into a DC voltage. The color temperature of white is 4,200 K, and the color temperature of neutral white is 5,000 K. The lighting apparatus may include a color filter.

The lighting apparatus according to the present embodiment may include a heat dissipation unit. The heat dissipation unit is configured to release heat in the apparatus to the outside of the apparatus and is composed of, for example, a metal having a high specific heat or liquid silicone.

FIG. 7B is a schematic view illustrating an automobile as an example of a moving object according to the present embodiment. The automobile includes a tail lamp, which is an example of lighting units. An automobile 1500 includes a tail lamp 1501 and may be configured to light the tail lamp when an operation, such as breaking, is performed.

The tail lamp 1501 may include an organic light-emitting device according to the present embodiment. The tail lamp may include a protective member that protects the organic EL device. The protective member may be composed of any material as long as it has a certain degree of strength and is transparent. The protective member is preferably composed of, for example, polycarbonate. The polycarbonate may be mixed with, for example, a furandicarboxylic acid derivative or an acrylonitrile derivative.

The automobile 1500 may include an automobile body 1503 and windows 1502 attached thereto. The windows may be transparent displays unless they are windows used to check areas in front of and behind the automobile. The transparent displays may include the organic light-emitting devices according to the present embodiment. In this case, the constituent materials, such as the electrodes, of the organic light-emitting device are formed of transparent members.

The moving object according to the present embodiment may be, for example, an automobile, a ship, an aircraft, or a drone. The moving object may include a body and a lighting unit attached to the body. The lighting unit may emit light to indicate the position of the body. The lighting unit includes the organic light-emitting device according to the present embodiment.

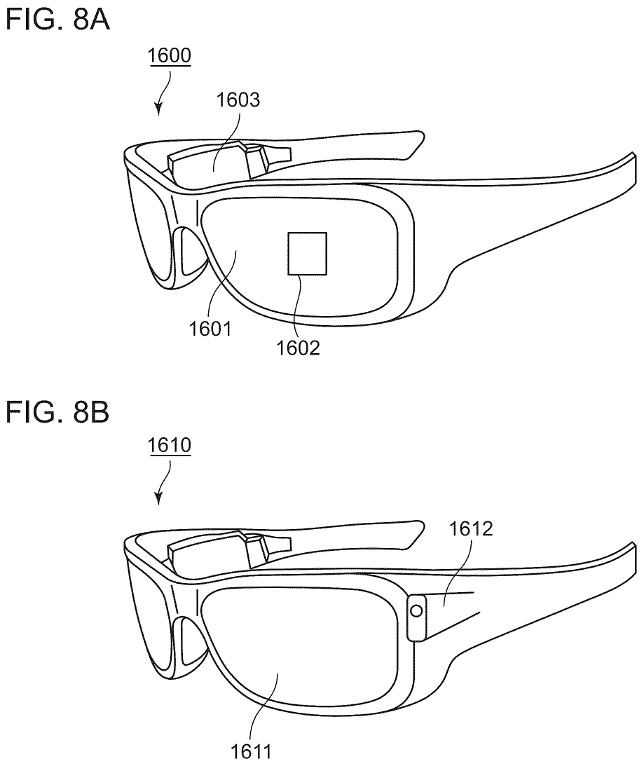

Examples of applications of the display apparatus of the above embodiment will be described with reference to FIGS. 8A and 8B. The display apparatus can be used for systems that can be worn as wearable devices, such as smart glasses, HMDs, and smart contact lenses. An image pickup and display apparatus used in such an application includes an image pickup apparatus that can photoelectrically convert visible light and a display apparatus that can emit visible light.

FIG. 8A illustrates a pair of glasses 1600 (smart glasses) according to one application example. An image pickup apparatus 1602, such as a CMOS sensor or SPAD, is provided on a front side of a lens 1601 of the glasses 1600. The display apparatus according to any of the above-mentioned embodiments is provided on the back side of the lens 1601.

The glasses 1600 further include a control unit 1603. The control unit 1603 functions as a power source that supplies electric power to the image pickup apparatus 1602 and the display apparatus according to any of the embodiments. The control unit 1603 controls the operation of the image pickup apparatus 1602 and the display apparatus. The lens 1601 includes an optical system for focusing light on the image pickup apparatus 1602.

FIG. 8B illustrates a pair of glasses 1610 (smart glasses) according to one application example. The glasses 1610 include a control unit 1612. The control unit 1612 includes an image pickup apparatus corresponding to the image pickup apparatus 1602 and a display apparatus. A lens 1611 is provided with the image pickup apparatus in the control unit 1612 and an optical system that projects light emitted from the display apparatus. An image is projected onto the lens 1611. The control unit 1612 functions as a power source that supplies electric power to the image pickup apparatus and the display apparatus and controls the operation of the image pickup apparatus and the display apparatus. The control unit may include a gaze detection unit that detects the gaze of a wearer. Infrared light may be used for gaze detection. An infrared light-emitting unit emits infrared light to an eyeball of a user who is gazing at a displayed image. An image of the eyeball is captured by detecting the reflected infrared light from the eyeball with an image pickup unit having light-receiving elements. A deterioration in image quality is reduced by providing a reduction unit that reduces light from the infrared light-emitting unit to the display unit when viewed in plan.

The user's gaze at the displayed image is detected from the image of the eyeball captured with the infrared light. Any known method can be used to the gaze detection using the captured image of the eyeball. As an example, a gaze detection method based on a Purkinje image of the reflection of irradiation light on a cornea can be used.

More specifically, the gaze detection process is performed on the basis of a pupil-corneal reflection method. Using the pupil-corneal reflection method, the user's gaze is detected by calculating a gaze vector representing the direction (rotation angle) of the eyeball based on the image of the pupil and the Purkinje image contained in the captured image of the eyeball.

A display apparatus according to an embodiment of the present invention may include an image pickup apparatus including light-receiving elements, and may control an image displayed on the display apparatus based on the gaze information of the user from the image pickup apparatus.

Specifically, in the display apparatus, a first field-of-view area at which the user gazes and a second field-of-view area other than the first field-of-view area are determined on the basis of the gaze information. The first field-of-view area and the second field-of-view area may be determined by the control unit of the display apparatus or may be determined by receiving those determined by an external control unit. In the display area of the display apparatus, the display resolution of the first field-of-view area may be controlled to be higher than the display resolution of the second field-of-view area. That is, the resolution of the second field-of-view area may be lower than that of the first field-of-view area.

The display area includes a first display area and a second display area different from the first display area. Based on the gaze information, an area of higher priority is determined from the first display area and the second display area. The first display area and the second display area may be determined by the control unit of the display apparatus or may be determined by receiving those determined by an external control unit. The resolution of an area of higher priority may be controlled to be higher than the resolution of an area other than the area of higher priority. In other words, the resolution of an area of a relatively low priority may be low.

Artificial intelligence (AI) may be used to determine the first field-of-view area and the high-priority area. The AI may be a model configured to estimate the angle of gaze from the image of the eyeball and the distance to a target object located in the gaze direction, using the image of the eyeball and the actual direction of gaze of the eyeball in the image as teaching data. The AI program may be stored in the display apparatus, the image pickup apparatus, or an external apparatus. When the AI program is stored in the external apparatus, the AI program is transmitted to the display apparatus via communications.

In the case of controlling the display based on visual detection, smart glasses that further include an image pickup apparatus that captures an external image can preferably be used. The smart glasses can display the captured external information in real time.

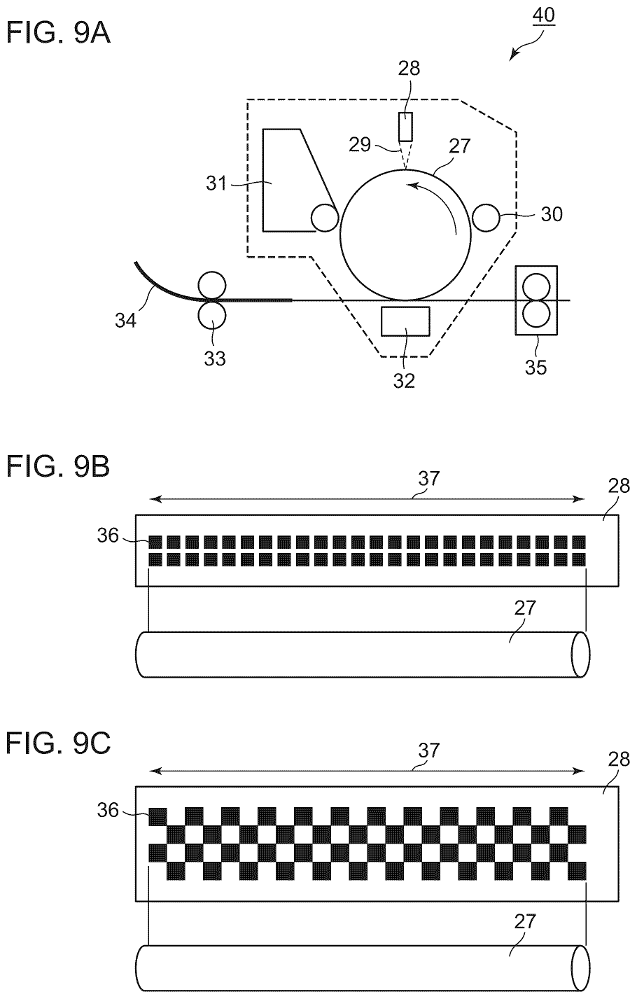

FIG. 9A is a schematic view of an example of an image-forming apparatus according to an embodiment of the present invention. An image-forming apparatus 40 is an electrophotographic image-forming apparatus and includes a photoconductor 27, an exposure light source 28, a charging unit 30, a developing unit 31, a transfer unit 32, a conveying roller 33, and a fixing unit 35. The irradiation of light 29 is performed from the exposure light source 28 to form an electrostatic latent image on the surface of the photoconductor 27. The exposure light source 28 includes the organic light-emitting device according to the present embodiment. The developing unit 31 contains, for example, a toner. The charging unit 30 charges the photoconductor 27. The transfer unit 32 transfers the developed image to a recording medium 34. The conveying roller 33 transports the recording medium 34. The recording medium 34 is paper, for example. The fixing unit 35 fixes the image formed on the recording medium 34.

FIGS. 9B and 9C each illustrate the exposure light source 28 and are each a schematic view illustrating multiple light-emitting portions 36 arranged on a long substrate. Arrows 37 each represent the row direction in which the organic light-emitting devices are arranged. The row direction is the same as the direction of the axis about which the photoconductor 27 rotates. This direction can also be referred to as the long-axis direction of the photoconductor 27. FIG. 9B illustrates a configuration in which the light-emitting portions 36 are arranged in the long-axis direction of the photoconductor 27. FIG. 9C is different from FIG. 9B in that the light-emitting portions 36 are arranged alternately in the row direction in a first row and a second row. The first row and the second row are located at different positions in the column direction. In the first row, the multiple light-emitting portions 36 are spaced apart. The second row has the light-emitting portions 36 at positions corresponding to the positions between the light-emitting portions 36 in the first row. In other words, the multiple light-emitting portions 36 are also spaced apart in the column direction. The arrangement in FIG. 9C can be rephrased as, for example, a lattice arrangement, a staggered arrangement, or a checkered pattern.

As described above, the use of an apparatus including the organic light-emitting device according to the present embodiment enables a stable display with good image quality even for a long time.

### EXAMPLES

While the present invention will be described below by examples, the present invention is not limited thereto.

### Example 1

### Evaluation of HOMO Level and LUMO Level

The HOMO levels and the LUMO levels of the first to third organic compounds and the first to third metal complexes were evaluated by the following methods. Table 1 presents the results.

### A) Method for Evaluating HOMO Level

Under a vacuum of 5×10⁻⁴ Pa or less, a vapor-deposited film having a thickness of 30 nm was formed on an aluminum substrate. The ionization potential of the vapor-deposited film was measured with AC-3 (manufactured by Riken Keiki Co., Ltd.), and the resulting value was defined as the HOMO level.

### B) Method for Evaluating LUMO Level

Under a vacuum of 5×10⁻⁴ Pa or less, a vapor-deposited film having a thickness of 30 nm was formed on a quartz substrate, and the optical band gap (absorption edge) of the resulting vapor-deposited film thus formed was determined using a spectrophotometer (V-560, manufactured by JASCO Corporation). The sum of the obtained optical band gap value and the above-mentioned HOMO level was defined as the LUMO level.

TABLE 1
Table 1

| Compound | HOMO(eV) | LUMO(eV) | Compound | HOMO(eV) | LUMO(eV) |
|---|---|---|---|---|---|
| AA1 | −5.7 | −3.4 | JJ17 | −5.5 | −3.2 |
| AA2 | −5.6 | −3.3 | JJ19 | −5.6 | −3.2 |
| AA21 | −5.7 | −3.4 | JJ20 | −5.3 | −2.9 |
| AA22 | −5.4 | −3.1 | GD10 | −5.5 | −3.1 |
| BB2 | −5.4 | −3.1 | GD11 | −5.5 | −3.1 |
| BB3 | −5.4 | −3.1 | GD12 | −5.4 | −3.1 |
| BB21 | −5.5 | −3.2 | GD13 | −5.2 | −2.8 |
| CC1 | −5.6 | −3.3 | GD20 | −5.2 | −2.8 |
| CC2 | −5.5 | −3.2 | RD3 | −5.5 | −3.6 |
| CC21 | −5.6 | −3.3 | RD7 | −5.4 | −3.5 |
| CC22 | −5.5 | −3.2 | RD10 | −5.5 | −3.5 |
| DD1 | −5.6 | −3.4 | BD9 | −6.2 | −3.5 |
| DD2 | −5.4 | −3.1 | EM10 | −6.3 | −2.8 |
| DD7 | −5.3 | −3.0 | EM11 | −6.3 | −2.8 |
| DD8 | −5.5 | −3.3 | EM13 | −6.4 | −2.9 |
| DD23 | −5.4 | −3.1 | EM14 | −6.4 | −2.9 |
| DD30 | −5.4 | −2.8 | EM28 | −6.5 | −3.3 |
| DD31 | −5.4 | −2.8 | EM29 | −6.4 | −3.2 |
| EE1 | −5.5 | −3.2 | EM30 | −6.6 | −3.4 |
| FF11 | −5.3 | −3.2 | EM31 | −6.5 | −3.3 |
| HH1 | −5.4 | −3.4 | EM33 | −6.2 | −2.7 |
| HH19 | −5.4 | −3.5 | EM34 | −6.2 | −2.7 |
| II1 | −5.4 | −3.5 | EM35 | −5.9 | −3.0 |
| II7 | −5.4 | −3.5 | EM37 | −5.9 | −2.9 |
| II8 | −5.4 | −3.5 | EM39 | −6.3 | −2.8 |
| II9 | −5.4 | −3.5 | EM41 | −6.3 | −2.8 |
| JJ1 | −5.6 | −3.4 | EM42 | −6.4 | −2.9 |
| JJ2 | −5.5 | −3.1 | EM43 | −5.7 | −2.7 |
| JJ4 | −5.4 | −3.1 | EM45 | −5.8 | −2.6 |
| JJ14 | −5.2 | −2.8 | EM46 | −5.9 | −3.1 |
| JJ16 | −5.6 | −3.4 | EM47 | −6.3 | −2.7 |

### Example 2

An anode, a hole injection layer, a hole transport layer, an electron-blocking layer, light-emitting layers, a hole-blocking layer, an electron transport layer, an electron injection layer, and a cathode were sequentially formed over a substrate to produce an organic light-emitting device having a bottom-emission structure.

An ITO film was formed on a glass substrate and subjected to desired patterning to form an ITO electrode (anode). At this time, the thickness of the ITO electrode was 100 nm. The substrate on which the ITO electrode had been formed in this way was used as an ITO substrate in the following steps. Next, vacuum deposition was performed by resistance heating in a vacuum chamber at 1.33×10⁻⁴ Pa to successively form organic compound layers and an electrode layer presented in Table 2 on the ITO substrate. Here, the opposite electrode (metal electrode layer, cathode) had an electrode area of 3 mm².

TABLE 2
Table 2

| | | | | Thickness |
|---|---|---|---|---|
| | Material | | | (nm) |
| Cathode | Al | | | 100 |
| Electron injection layer (EIL) | LiF | | | 1 |
| Electron transport layer (ETL) | ET2 | | | 20 |
| Hole-blocking layer (HBL) | ET11 | | | 20 |
| Second light-emitting | Second organic compound | EM14 | Ratio by weight | 15 |
| layer (EML) | Third organic compound | EM31 | EM14:EM31:AA2 = | |
| | Second metal complex | AA2 | 55:30:15 | |
| First light-emitting | First organic compound | EM13 | Ratio by weight | 5 |
| layer (EML) | Third metal complex | AA1 | EM13:AA1:HH1 = | |
| | First metal complex | HH1 | 78:20:2 | |

| | | |
|---|---|---|
| Electron-blocking layer (EBL) | HT19 | 15 |
| Hole transport layer (HTL) | HT3 | 30 |
| Hole injection layer (HIL) | HT16 | 5 |

Thereafter, the substrate was transferred to a glove box and sealed with a glass cap containing a drying agent in a nitrogen atmosphere to provide an organic light-emitting device.

The characteristics of the resulting organic light-emitting device were measured and evaluated. The emission color of the organic light-emitting device was yellow, and the maximum external quantum efficiency (E.Q.E.) was 18%.

The device was subjected to a continuous operation test at a current density of 100 mA/cm². The time when the percentage of luminance degradation reached 5% was measured. When the time at which the percentage of luminance degradation of Comparative Example 1 reached 5% was defined as 1.0, the luminance degradation ratio in this example was 2.3.

In this example, the current-voltage characteristics were measured using a microammeter 4140B manufactured by Hewlett-Packard, and the luminance of emission light was measured using a BM7 manufactured by Topcon.

### Examples 3 to 21 and Comparative Examples 1 to 6

Organic light-emitting devices of Examples 3 to 21 and Comparative Examples 1 to 6 were produced in the same manner as in Example 2, except that the compounds were appropriately changed to those given in Tables 3-1 and 3-2. The characteristics of the resulting organic light-emitting devices were measured and evaluated as in Example 2. Tables 3-1 and 3-2 present the measurement results. The luminance degradation ratio indicates a value when the time at which the percentage of luminance degradation of Comparative Example 1 reaches 5% is defined as 1.0.

When the first light-emitting layer did not contain the third metal complex, the ratio by weight of the first organic compound to the first metal complex was adjusted to 98:2. When the second light-emitting layer did not contain the third organic compound, the ratio by weight of the second organic compound to the second metal complex was adjusted to 85:15.

TABLE 3-1
Table 3-1

| | | First light-emitting layer | | | Second light-emitting layer | | | | | |
|---|---|---|---|---|---|---|---|---|---|---|
| | | First | Third | First | Second | Third | Second | | | Luminance |
| | | organic | metal | metal | organic | organic | metal | | E.Q.E | degradation |
| | EBL | compound | complex | complex | compound | compound | complex | HBL | [%] | ratio |
| Example | HT19 | EM14 | JJ19 | HH1 | EM14 | EM31 | JJ19 | ET12 | 22 | 2.8 |
| 3 | | | | | | | | | | |
| Example | HT15 | EM13 | JJ19 | HH19 | EM14 | EM31 | JJ19 | ET12 | 23 | 2.6 |
| 4 | | | | | | | | | | |
| Example | HT15 | EM13 | JJ4 | HH1 | EM14 | EM31 | CC2 | ET11 | 19 | 2.3 |
| 5 | | | | | | | | | | |
| Example | HT19 | EM14 | JJ4 | HH1 | EM14 | EM31 | CC22 | ET11 | 19 | 2.3 |
| 6 | | | | | | | | | | |
| Example | HT19 | EM14 | AA1 | HH19 | EM13 | EM31 | DD2 | ET11 | 19 | 2.2 |
| 7 | | | | | | | | | | |
| Example | HT19 | EM13 | AA21 | HH19 | EM13 | EM30 | DD23 | ET11 | 19 | 1.8 |
| 8 | | | | | | | | | | |
| Example | HT19 | EM14 | CC1 | II7 | EM14 | EM28 | DD7 | ET12 | 22 | 2.4 |
| 9 | | | | | | | | | | |
| Example | HT15 | EM14 | CC21 | II8 | EM14 | EM30 | DD30 | ET12 | 23 | 2.5 |
| 10 | | | | | | | | | | |
| Example | HT19 | EM10 | JJ4 | II9 | EM14 | EM30 | JJ2 | ET12 | 20 | 2.2 |
| 11 | | | | | | | | | | |
| Example | HT15 | EM11 | JJ4 | II7 | EM14 | EM28 | JJ14 | ET11 | 20 | 2.2 |
| 12 | | | | | | | | | | |
| Example | HT19 | EM13 | FF11 | II8 | EM14 | EM30 | JJ17 | ET12 | 20 | 2.4 |
| 13 | | | | | | | | | | |
| Example | HT15 | EM39 | AA21 | RD3 | EM14 | EM30 | JJ20 | ET12 | 16 | 2.8 |
| 14 | | | | | | | | | | |
| Example | HT15 | EM34 | CC1 | RD7 | EM14 | EM35 | GD13 | ET11 | 18 | 1.6 |
| 15 | | | | | | | | | | |
| Example | HT19 | EM39 | BB21 | RD7 | EM35 | EM29 | GD11 | ET12 | 18 | 1.8 |
| 16 | | | | | | | | | | |
| Example | HT19 | EM34 | CC21 | RD10 | EM37 | EM35 | GD20 | ET12 | 18 | 1.7 |
| 17 | | | | | | | | | | |
| Example | HT19 | EM13 | JJ19 | II7 | EM39 | EM30 | AA2 | ET11 | 19 | 1.9 |
| 18 | | | | | | | | | | |
| Example | HT19 | EM34 | JJ19 | II8 | EM39 | EM30 | GD20 | ET12 | 22 | 1.8 |
| 19 | | | | | | | | | | |
| Example | HT19 | EM43 | GD12 | II9 | EM39 | EM29 | GD11 | ET11 | 19 | 1.7 |
| 20 | | | | | | | | | | |
| Example | HT19 | EM14 | none | II9 | EM13 | EM78 | GD11 | ET11 | 17 | 1.5 |
| 21 | | | | | | | | | | |

TABLE 3-2
Table 3-2

| | | First light-emitting layer | | | Second light-emitting layer | | | | | |
|---|---|---|---|---|---|---|---|---|---|---|
| | | First | Third | First | Second | Third | Second | | | Luminance |
| | | organic | metal | metal | organic | organic | metal | | E.Q.E | degradation |
| | EBL | compound | complex | complex | compound | compound | complex | HBL | [%] | ratio |
| Comparative | HT19 | EM42 | EM43 | GD10 | EM35 | EM43 | RD7 | ET11 | 18 | 1.0 |
| Example 1 | | | | | | | | | | |
| Comparative | HT19 | EM45 | None | GD10 | EM46 | None | GD10 | ET11 | 7 | 0.3 |
| Example 2 | | | | | | | | | | |
| Comparative | HT19 | EM47 | None | GD10 | EM45 | BD9 | GD10 | ET11 | 12 | 0.8 |
| Example 3 | | | | | | | | | | |
| Comparative | HT19 | EM14 | None | HH1 | EM14 | None | AA2 | ET12 | 16 | 1.3 |
| Example 4 | | | | | | | | | | |
| Comparative | HT19 | EM45 | BD9 | II9 | EM45 | EM30 | JJ1 | ET11 | 15 | 1.1 |
| Example 5 | | | | | | | | | | |
| Comparative | HT19 | EM45 | None | BD9 | EM39 | EM43 | GD20 | ET11 | 13 | 1.4 |
| Example 6 | | | | | | | | | | |

As presented in Tables 3-1 and 3-2, the E. Q. E. values of Comparative Examples 1 to 6 were 18%, 7%, 12%, 16%, 15%, and 13%. The luminance degradation ratios of Comparative Examples 1 to 6 were 1.0, 0.3, 0.4, 1.3, 1.1, and 1.4. The device configurations in Comparative Examples 1, 2, and 3 are the same as those of the organic light-emitting devices described in Patent Literature 1, 2, and 3. In Comparative Example 1, the relationship (b) is not satisfied, and thus the second light-emitting layer does not easily trap electrons. In Comparative Examples 2 and 4, the relationship (b) is not satisfied because the third organic compound is not contained. Therefore, as in Comparative Example 1, the second light-emitting layer does not easily trap electrons. In Comparative Example 3, the third organic compound is a metal complex, and the relationship (c) is not satisfied, thus resulting in insufficient adjustment of the carrier balance in the light-emitting layers. In Comparative Example 5, the third organic compound is an organic compound, but the relationship (c) is not satisfied, thus resulting in insufficient adjustment of the carrier balance in the light-emitting layers. In Comparative Example 6, the relationships (a) to (c) are not satisfied, thus resulting in insufficient adjustment of the carrier balance in the light-emitting layers. For the above reasons, the organic light-emitting devices described in Comparative Examples 1 to 6 are organic light-emitting devices having inferior durability.

In contrast, the organic light-emitting devices according to the present invention have superior luminance degradation ratios. In other words, the organic light-emitting devices according to the present invention have superior durability. This is because the light-emitting layers of the organic light-emitting devices according to the present invention trap holes and electrons in a well-balanced manner, making it easy to adjust the carrier balance in the light-emitting layers. In addition, the E.Q.E. values of the organic light-emitting devices according to the present invention are higher than those of the organic light-emitting devices described in the comparative examples. In other words, the organic light-emitting devices according to the present invention are organic light-emitting devices that also have superior luminous efficiency.

Furthermore, by selecting the first to third metal complexes and the first to third organic compounds suitable for the light-emitting layers of the organic light-emitting devices according to the present invention, it was possible to provide the organic light-emitting devices having superior luminous efficiency and durability.

### Example 22

An organic light-emitting device was produced in the same manner as in Example 2, except that the thickness of the first light-emitting layer was changed to 10 nm. The characteristics of the resulting organic light-emitting device were measured and evaluated in the same manner as in Example 2. The E. Q.E. was 188, and the luminance degradation ratio was 2.5.

### Example 23

An organic light-emitting device was produced in the same manner as in Example 2, except that the thickness of the first light-emitting layer was changed to 10 nm, and the thickness of the second light-emitting layer was changed to 10 nm. The characteristics of the resulting organic light-emitting device were measured and evaluated in the same manner as in Example 2. The E.Q.E. was 18%, and the luminance degradation ratio was 2.0.

### Example 24

An organic light-emitting device was produced in the same manner as in Example 2, except that the ratio by weight in the first light-emitting layer was changed to EM13:AA1:HH1=66:30:4, and the ratio by weight in the second light-emitting layer was changed to EM14:EM31:AA2=70:20:10. The characteristics of the resulting organic light-emitting device were measured and evaluated in the same manner as in Example 2. The E.Q.E. was 18%, and the luminance degradation ratio was 2.1.

### Example 25

An organic light-emitting device was produced in the same manner as in Example 2, except that the ratio by weight in the first light-emitting layer was changed to EM13:AA1:HH1=76:20:4, and the ratio by weight in the second light-emitting layer was changed to EM14:EM31:AA2=70:20:30. The characteristics of the resulting organic light-emitting device were measured and evaluated in the same manner as in Example 2. The E.Q.E. was 188, and the luminance degradation ratio was 1.6.

As described above, the organic light-emitting devices having excellent luminous efficiency and durability can be provided by using the organic compounds according to the present invention.

The present invention can also include the following configurations.

### Configuration 1

An organic light-emitting device includes, in sequence:
an anode, a first light-emitting layer, a second light-emitting layer, and a cathode,
in which the first light-emitting layer and the second light-emitting layer are in contact with each other,
the first light-emitting layer contains a first organic compound and a first metal complex,
the second light-emitting layer contains a second organic compound, a third organic compound, and a second metal complex,
the third organic compound is not a metal complex, and
the following relationships (a) to (c) satisfy:

$$HOMO ( D 1 ) > HOMO ( H 1 ) \qquad ( a )$$

$$LUMO ( H 2 ) > LUMO ( H 3 ) \qquad ( b )$$

$$HOMO ( D 1 ) - HOMO ( H 1 ) > LUMO ( H 2 ) - LUMO ( H 3 ) . \qquad ( c )$$

Here, HOMO (D1), HOMO (H1), LUMO (H2), and LUMO (H3) represent the HOMO energy level of the first metal complex, the HOMO energy level of the first organic compound, the LUMO energy level of the second organic compound, and the LUMO energy level of the third organic compound, respectively.

### Configuration 2

In the organic light-emitting device described in configuration 1, the following relationship (d) satisfies:

$$C 2 ( H 3 ) > C 1 ( D 1 ) . \qquad ( d )$$

C1 (D1) and C2 (H3) represent the concentration of the first metal complex in the first light-emitting layer and the concentration of the third organic compound in the second light-emitting layer, respectively.

### Configuration 3

In the organic light-emitting device described in configuration 1 or 2, the following relationship (n) satisfies:

$$HOMO ( D 1 ) - HOMO ( H 1 ) > LUMO ( H 2 ) - LUMO ( H 3 ) \geq 0.1 eV . \qquad ( n )$$

### Configuration 4

In the organic light-emitting device described in any one of configurations 1 to 3, the following relationship (e) satisfies:

$$HOMO ( H 2 ) > HOMO ( H 3 ) . \qquad ( e )$$

Here, HOMO (H2) and HOMO (H3) represent the HOMO energy level of the second organic compound and the HOMO energy level of the third organic compound, respectively.

### Configuration 5

In the organic light-emitting device described in any one of configurations 1 to 4, the following relationship (f) satisfies:

$$LUMO ( D 2 ) > LUMO ( H 3 ) . \qquad ( f )$$

Here, LUMO (D2) represents the LUMO energy level of the second metal complex.

### Configuration 6

In the organic light-emitting device described in configuration 5, the following relationship (g) satisfies:

$$C 2 ( H 3 ) > C 2 ( D 2 ) . \qquad ( g )$$

Here, C2 (D2) represents the concentration of the second metal complex in the second light-emitting layer.

### Configuration 7

In the organic light-emitting device described in any one of configurations 1 to 6, the first light-emitting layer further contains a third metal complex, and at least one ligand contained in the third metal complex is identical to a ligand contained in the second metal complex.

### Configuration 8

In the organic light-emitting device described in configuration 7, the following relationship (h) satisfies:

$$C 1 ( D 3 ) > C 1 ( D 1 ) . \qquad ( h )$$

Here, C1 (D3) represents the concentration of the third metal complex in the first light-emitting layer.

### Configuration 9

In the organic light-emitting device described in configuration 7 or 8, the following relationships (i) and (j) satisfy:

$$\vert LUMO ( D 3 ) - LUMO ( D 2 ) \vert \leq 0.2 eV \qquad ( i )$$

$$\vert HUMO ( D 3 ) - H O MO ( D 2 ) \vert \leq 0.2 eV . \qquad ( j )$$

Here, LUMO (D3), HOMO (D3), and HOMO (D2) represent the LUMO energy level of the third metal complex, the HOMO energy level of the third metal complex, and the HOMO energy level of the second metal complex, respectively.

### Configuration 10

In the organic light-emitting device described in any one of configurations 7 to 9, the following relationship (k) satisfies:

$$HOMO ( D 3 ) > HOMO ( H 1 ) . \qquad ( k )$$

### Configuration 11

In the organic light-emitting device described in any one of configurations 1 to 10, each of the first metal complex and the second metal complex has a structure represented by any of general formulae [Ir-1] to [Ir-16].

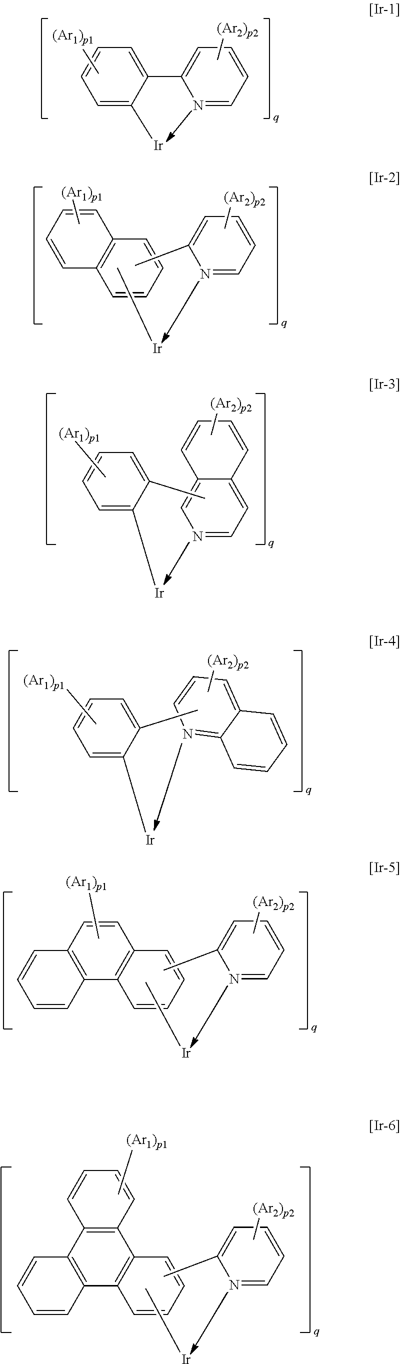

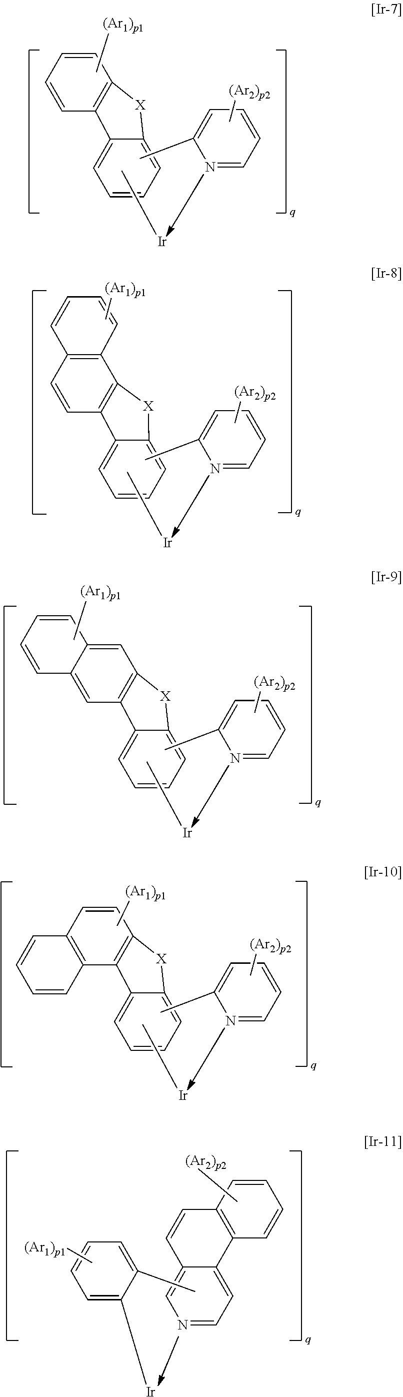

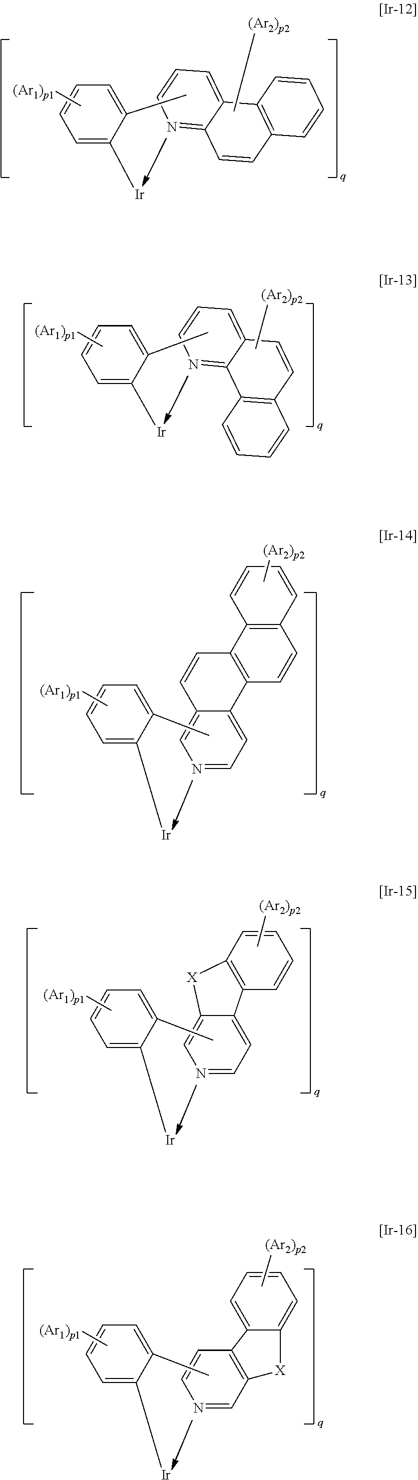

In each of general formulae [Ir-1] to [Ir-16], Ar₁ and Ar₂ are each independently selected from a deuterium atom, a halogen atom, a substituted or unsubstituted alkyl group, a substituted or unsubstituted alkoxy group, a substituted or unsubstituted aryl group, a substituted or unsubstituted heterocyclic group, a substituted or unsubstituted silyl group, and a cyano group, when a plurality of Ar₁ or Ar₂ are present, the plurality of Ar₁ or Ar₂ are optionally the same substituent or different substituents, X is selected from an oxygen atom, a sulfur atom, C(R₁) (R₂), and NR₃, R₁ to R₃ are each independently selected from a hydrogen atom, a deuterium atom, a halogen atom, a substituted or unsubstituted alkyl group, a substituted or unsubstituted alkoxy group, a substituted or unsubstituted amino group, a substituted or unsubstituted aryloxy group, a substituted or unsubstituted aryl group, a substituted or unsubstituted heterocyclic group, a substituted or unsubstituted silyl group, and a cyano group, R₁ and R₂ are optionally bonded together to form a ring, p₁ and p₂ are each an integer of 0 to 4, and q is an integer of 1 to 3.

### Configuration 12

In the organic light-emitting device described in any one of configurations 7 to 10, the third metal complex is a metal complex represented by any of general formulae [Ir-1] to [Ir-16].

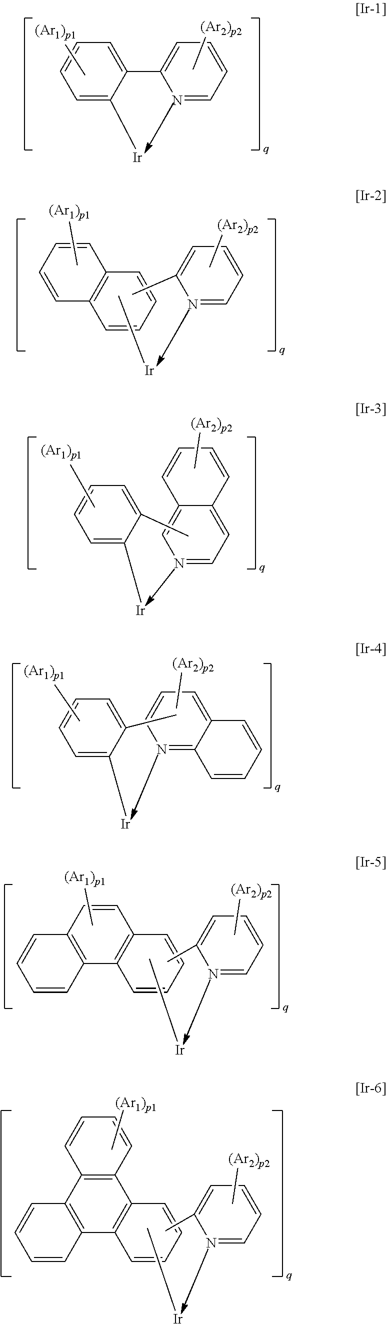

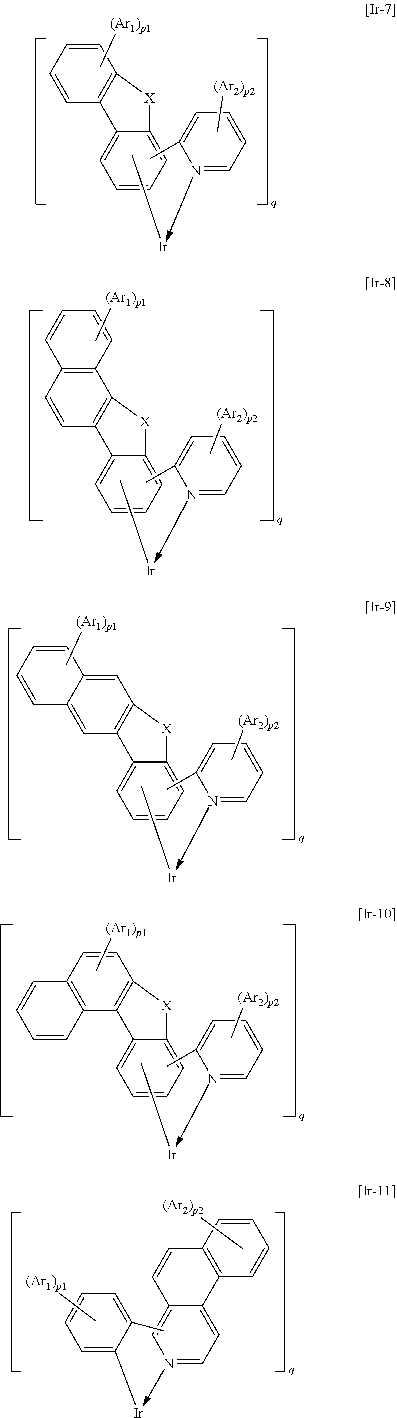

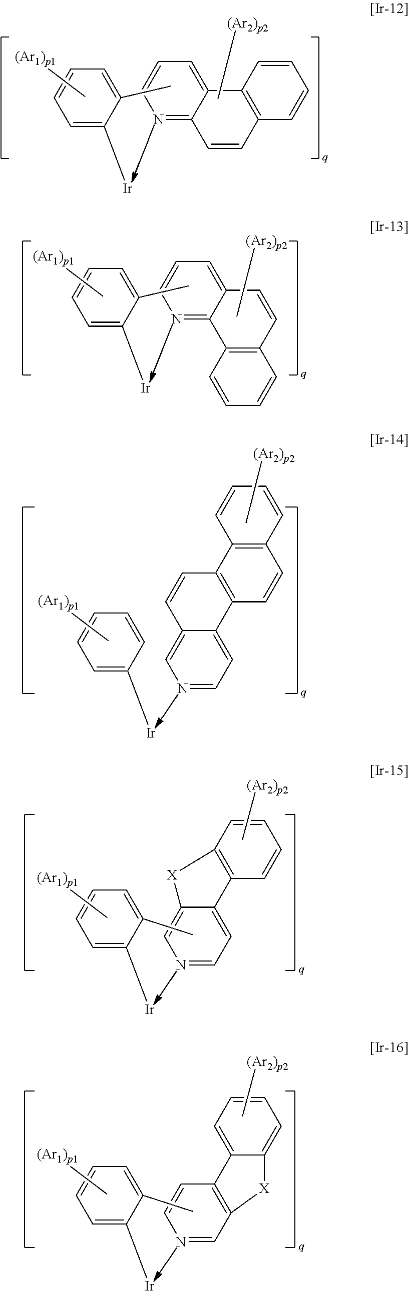

In each of general formulae [Ir-1] to [Ir-16], Ar₁ and Ar₂ are each independently selected from a deuterium atom, a halogen atom, a substituted or unsubstituted alkyl group, a substituted or unsubstituted alkoxy group, a substituted or unsubstituted aryl group, a substituted or unsubstituted heterocyclic group, a substituted or unsubstituted silyl group, and a cyano group, when a plurality of Ar₁ or Ar₂ are present, the plurality of Ar₁ or Ar₂ are optionally the same substituent or different substituents, X is selected from an oxygen atom, a sulfur atom, C(R₁) (R₂), and NR₃, R₁ to R₃ are each independently selected from a hydrogen atom, a deuterium atom, a halogen atom, a substituted or unsubstituted alkyl group, a substituted or unsubstituted alkoxy group, a substituted or unsubstituted amino group, a substituted or unsubstituted aryloxy group, a substituted or unsubstituted aryl group, a substituted or unsubstituted heterocyclic group, a substituted or unsubstituted silyl group, and a cyano group, R₁ and R₂ are optionally bonded together to form a ring, p₁ and p₂ are each an integer of 0 to 4, and q is an integer of 1 to 3.

### Configuration 13

In the organic light-emitting device described in configuration 11 or 12, in each of general formulae [Ir-1] to [Ir-16], Ar₁ and Ar₂ are each an alkyl group having 1 to 4 carbon atoms or an aryl group having 6 to 10 carbon atoms.

### Configuration 14

In the organic light-emitting device described in any one of configurations 1 to 13, each of the first organic compound and the second organic compound has any one of a benzothiophene skeleton, a dibenzofuran skeleton, a triphenylene skeleton, and a phenanthrene skeleton.

### Configuration 15

In the organic light-emitting device described in any one of configurations 1 to 14, the third organic compound has an azine skeleton, a xanthone skeleton, or a thioxanthone skeleton.

### Configuration 16

In the organic light-emitting device described in any one of configurations 1 to 15, the emission wavelength of the first metal complex is longer than the emission wavelength of the second metal complex.

### Configuration 17

In the organic light-emitting device described in any one of configurations 7 to 16, the second metal complex and the third metal complex are the same compound.

### Configuration 18

In the organic light-emitting device described in any one of configurations 1 to 17, the first organic compound and the second organic compound are the same compound.

### Configuration 19

A display apparatus includes multiple pixels, at least one of the multiple pixels including the organic light-emitting device described in any one of configurations 1 to 18 and a transistor coupled to the organic light-emitting device.

### Configuration 20

An image pickup apparatus includes an optical unit including a lens, an image pickup device configured to receive light passing through the optical unit, and a display unit configured to display an image captured by the image pickup device,
in which the display unit includes the organic light-emitting device described in any one of configurations 1 to 18.

### Configuration 21

An electronic apparatus includes a display unit including the organic light-emitting device described in any one of configurations 1 to 18, a housing provided with the display unit, and a communication unit disposed in the housing and configured to communicate with an outside.

### Configuration 22

A lighting apparatus includes a light source including the organic light-emitting device described in any one of configurations 1 to 18, and a light diffusion unit or an optical film configured to transmit light emitted from the light source.

### Configuration 23

A moving object includes a lighting unit including the organic light-emitting device described in any one of configurations 1 to 18, and a body provided with the lighting unit.

### Configuration 24

An image-forming apparatus includes a photoconductor and an exposure light source configured to expose the photoconductor, in which the exposure light source includes the organic light-emitting device described in any one of configurations 1 to 18.

According to the present invention, it is possible to provide an organic light-emitting device having excellent durability.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

The invention claimed is:

1. An organic light-emitting device, comprising, in sequence:
an anode, a first light-emitting layer, a second light-emitting layer, and a cathode,
wherein the first light-emitting layer and the second light-emitting layer are in contact with each other,
the first light-emitting layer contains a first organic compound and a first metal complex,
the second light-emitting layer contains a second organic compound, a third organic compound, and a second metal complex,
the third organic compound is not a metal complex, and
the following relationships (a) to (c) satisfy:
$$HOMO ( D 1 ) > HOMO ( H 1 ) \qquad ( a )$$
$$LUMO ( H 2 ) > LUMO ( H 3 ) \qquad ( b )$$
$$HOMO ( D 1 ) - HOMO ( H 1 ) > LUMO ( H 2 ) - LUMO ( H 3 ) \qquad ( c )$$
where HOMO (D1), HOMO (H1), LUMO (H2), and LUMO (H3) represent a HOMO energy level of the first metal complex, a HOMO energy level of the first organic compound, a LUMO energy level of the second organic compound, and a LUMO energy level of the third organic compound, respectively.

2. The organic light-emitting device according to claim 1, wherein the following relationship (d) satisfies:
$$C 2 ( H 3 ) > C 1 ( D 1 ) \qquad ( d )$$
where C1 (D1) and C2 (H3) represent a concentration of the first metal complex in the first light-emitting layer and a concentration of the third organic compound in the second light-emitting layer, respectively.

3. The organic light-emitting device according to claim 1, wherein the following relationship (n) satisfies:
$$HOMO ( D 1 ) - HOMO ( H 1 ) > LUMO ( H 2 ) - LUMO ( H 3 ) \geq 0.1 eV . \qquad ( n )$$

4. The organic light-emitting device according to claim 1, wherein the following relationship (e) satisfies:
$$HOMO ( H 2 ) > HOMO ( H 3 ) \qquad ( e )$$
where HOMO (H2) and HOMO (H3) represent a HOMO energy level of the second organic compound and a HOMO energy level of the third organic compound, respectively.

5. The organic light-emitting device according to claim 1, wherein the following relationship (f) satisfies:
$$LUMO ( D 2 ) > LUMO ( H 3 ) . \qquad ( f )$$
where LUMO (D2) represents a LUMO energy level of the second metal complex.

6. The organic light-emitting device according to claim 5, wherein the following relationship (g) satisfies:
$$C 2 ( H 3 ) > C 2 ( D 2 ) \qquad ( g )$$
where C2 (D2) represents a concentration of the second metal complex in the second light-emitting layer.

7. The organic light-emitting device according to claim 1, wherein the first light-emitting layer further contains a third metal complex, and
at least one ligand contained in the third metal complex is identical to a ligand contained in the second metal complex.

8. The organic light-emitting device according to claim 7, wherein the following relationship (h) satisfies:
$$C 1 ( D 3 ) > C 1 ( D 1 ) \qquad ( h )$$
where C1 (D3) represents a concentration of the third metal complex in the first light-emitting layer.

9. The organic light-emitting device according to claim 7, wherein the following relationships (i) and (j) satisfy:
$$\vert LUMO ( D 3 ) - LUMO ( D 2 ) \vert \leq 0.2 eV \qquad ( i )$$
$$\vert HUMO ( D 3 ) - H O MO ( D 2 ) \vert \leq 0.2 eV \qquad ( j )$$
where LUMO (D3), HOMO (D3), and HOMO (D2) represent a LUMO energy level of the third metal complex, a HOMO energy level of the third metal complex, and a HOMO energy level of the second metal complex, respectively.

10. The organic light-emitting device according to claim 7, the following relationship (k) satisfies:
$$HOMO ( D 3 ) > HOMO ( H 1 ) . \qquad ( k )$$

11. The organic light-emitting device according to claim 1, wherein each of the first metal complex and the second metal complex has a structure represented by any of general formulae [Ir-1] to [Ir-16]: 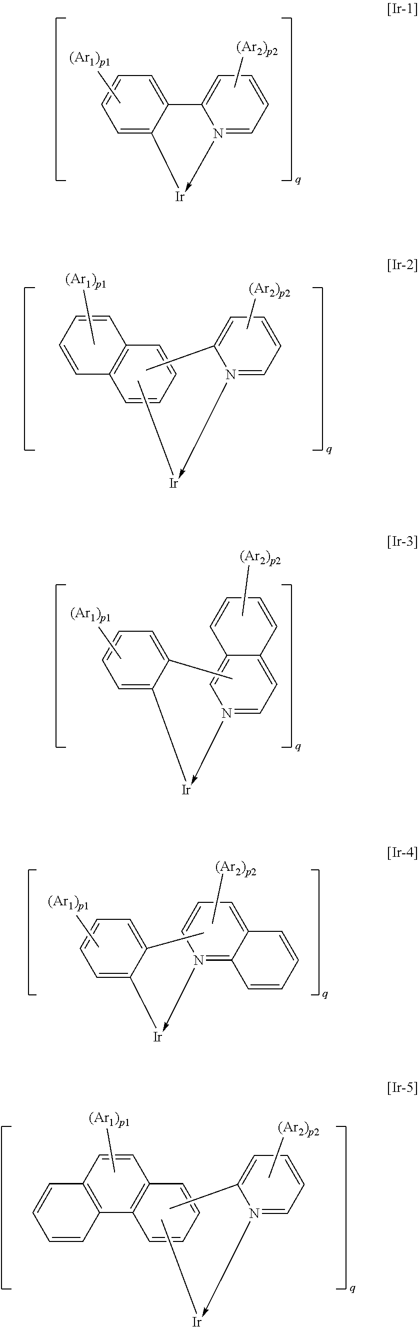 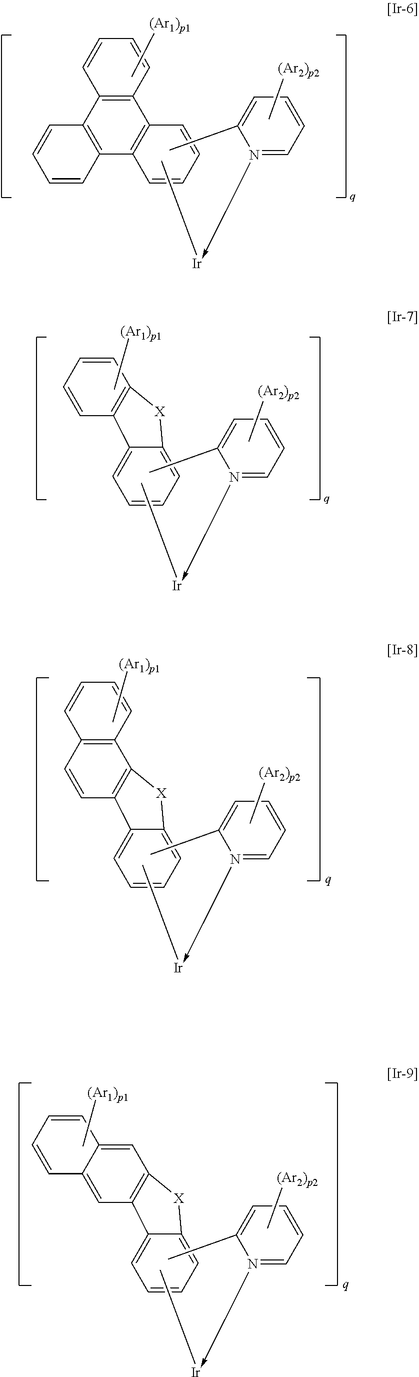 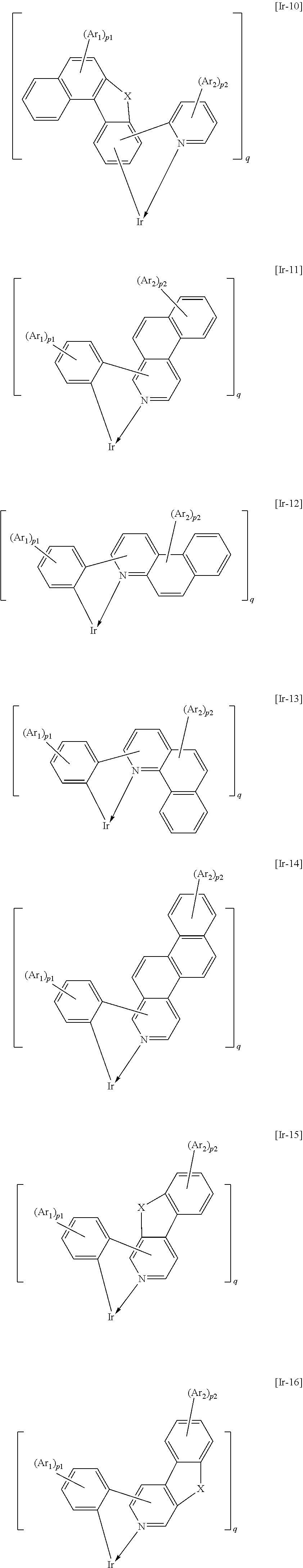
where in each of general formulae [Ir-1] to [Ir-16], Ar₁ and Ar₂ are each independently selected from the group consisting of a deuterium atom, a halogen atom, a substituted or unsubstituted alkyl group, a substituted or unsubstituted alkoxy group, a substituted or unsubstituted aryl group, a substituted or unsubstituted heterocyclic group, a substituted or unsubstituted silyl group, and a cyano group, when a plurality of Ar₁ or Ar₂ are present, the plurality of Ar₁ or Ar₂ are optionally the same substituent or different substituents, X is selected from the group consisting of an oxygen atom, a sulfur atom, C(R₁) (R₂), and NR₃, R₁ to R₃ are each independently selected from the group consisting of a hydrogen atom, a deuterium atom, a halogen atom, a substituted or unsubstituted alkyl group, a substituted or unsubstituted alkoxy group, a substituted or unsubstituted amino group, a substituted or unsubstituted aryloxy group, a substituted or unsubstituted aryl group, a substituted or unsubstituted heterocyclic group, a substituted or unsubstituted silyl group, and a cyano group, R₁ and R₂ are optionally bonded together to form a ring, p₁ and p₂ are each an integer of 0 to 4, and q is an integer of 1 to 3.

12. The organic light-emitting device according to claim 7, wherein the third metal complex is a metal complex represented by any of general formulae [Ir-1] to [Ir-16]: 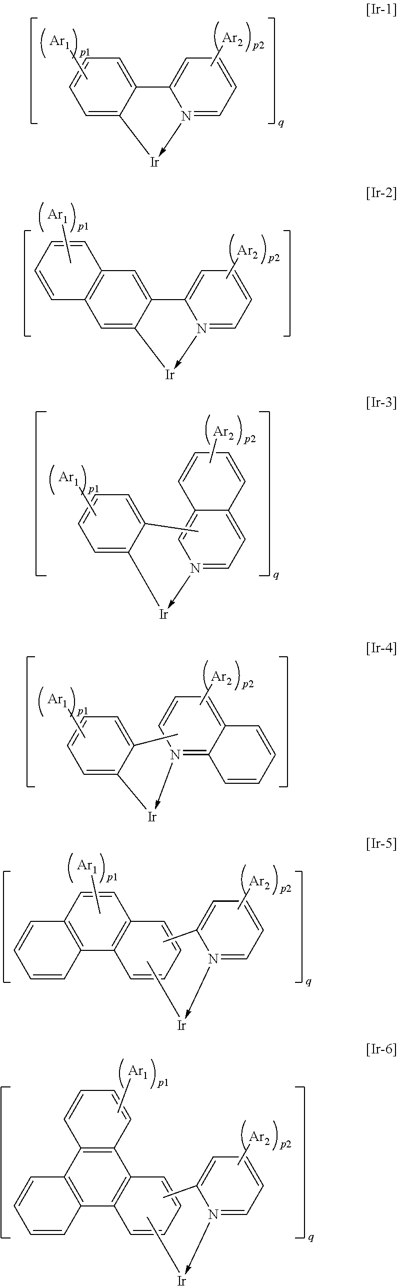 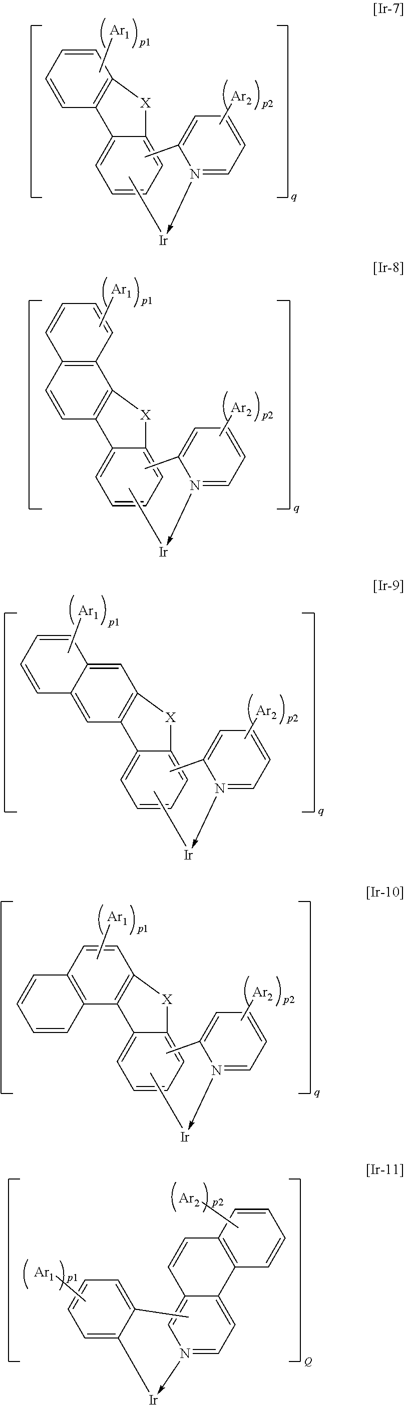 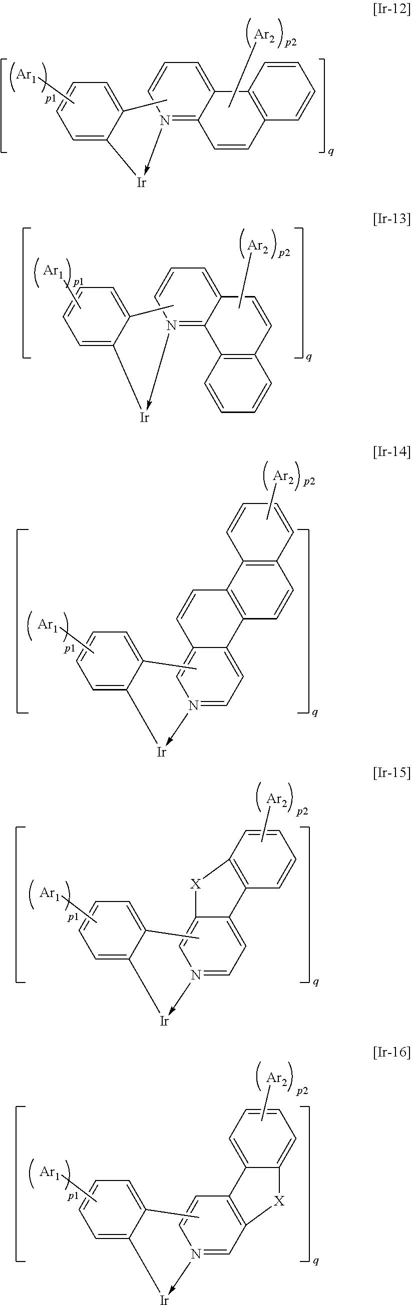
where in each of general formulae [Ir-1] to [Ir-16], Ar₁ and Ar₂ are each independently selected from the group consisting of a deuterium atom, a halogen atom, a substituted or unsubstituted alkyl group, a substituted or unsubstituted alkoxy group, a substituted or unsubstituted aryl group, a substituted or unsubstituted heterocyclic group, a substituted or unsubstituted silyl group, and a cyano group, when a plurality of Ar₁ or Ar₂ are present, the plurality of Ar₁ or Ar₂ are optionally the same substituent or different substituents, X is selected from the group consisting of an oxygen atom, a sulfur atom, C(R₁) (R₂), and NR₃, R₁ to R₃ are each independently selected from the group consisting of a hydrogen atom, a deuterium atom, a halogen atom, a substituted or unsubstituted alkyl group, a substituted or unsubstituted alkoxy group, a substituted or unsubstituted amino group, a substituted or unsubstituted aryloxy group, a substituted or unsubstituted aryl group, a substituted or unsubstituted heterocyclic group, a substituted or unsubstituted silyl group, and a cyano group, R₁ and R₂ are optionally bonded together to form a ring, p₁ and p₂ are each an integer of 0 to 4, and q is an integer of 1 to 3.

13. The organic light-emitting device according to claim 11, wherein in each of general formulae [Ir-1] to [Ir-16], Ar₁ and Ar₂ are each an alkyl group having 1 to 4 carbon atoms or an aryl group having 6 to 10 carbon atoms.

14. The organic light-emitting device according to claim 12, wherein in each of general formulae [Ir-1] to [Ir-16], Ar₁ and Ar₂ are each an alkyl group having 1 to 4 carbon atoms or an aryl group having 6 to 10 carbon atoms.

15. The organic light-emitting device according to claim 1, wherein each of the first organic compound and the second organic compound has any one of a benzothiophene skeleton, a dibenzofuran skeleton, a triphenylene skeleton, and a phenanthrene skeleton.

16. The organic light-emitting device according to claim 1, wherein the third organic compound has an azine skeleton, a xanthone skeleton, or a thioxanthone skeleton.

17. The organic light-emitting device according to claim 1, wherein an emission wavelength of the first metal complex is longer than an emission wavelength of the second metal complex.

18. The organic light-emitting device according to claim 7, wherein the second metal complex and the third metal complex are the same compound.

19. The organic light-emitting device according to claim 1, wherein the first organic compound and the second organic compound are the same compound.

20. A display apparatus, comprising multiple pixels, at least one of the multiple pixels including the organic light-emitting device according to claim 1 and a transistor coupled to the organic light-emitting device.

21. An image pickup apparatus, comprising an optical unit including a lens, an image pickup device configured to receive light passing through the optical unit, and a display unit configured to display an image captured by the image pickup device,
wherein the display unit includes the organic light-emitting device according to claim 1.

22. An electronic apparatus, comprising a display unit including the organic light-emitting device according to claim 1, a housing provided with the display unit, and a communication unit disposed in the housing and configured to communicate with an outside.

23. A lighting apparatus, comprising a light source including the organic light-emitting device according to claim 1, and a light diffusion unit or an optical film configured to transmit light emitted from the light source.

24. A moving object, comprising a lighting unit including the organic light-emitting device according to claim 1, and a body provided with the lighting unit.

25. An image-forming apparatus, comprising a photoconductor and an exposure light source configured to expose the photoconductor,
wherein the exposure light source includes the organic light-emitting device according to claim 1.
